(19) United States
(12) Patent Application Publication
(10) Pub. No.: US 2010/0028803 A1
(43) Pub. Date: Feb. 4, 2010

(54) SURFACE TREATING AGENT FOR RESIST PATTERN FORMATION, RESIST COMPOSITION, METHOD OF TREATING SURFACE OF RESIST PATTERN THEREWITH AND METHOD OF FORMING RESIST PATTERN

(75) Inventors: Naoya SUGIMOTO, Haibara-gun (JP); Shinji Tarutani, Haibara-gun (JP); Sou Kamimura, Haibara-gun (JP); Kazuto Shimada, Haibara-gun (JP); Naoyuki Nishikawa, Haibara-gun (JP); Tomotaka Tsuchimura, Haibara-gun (JP); Yuko Tada, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/533,635

(22) Filed: Jul. 31, 2009

Related U.S. Application Data
(60) Provisional application No. 61/086,278, filed on Aug. 5, 2008.
(60) Provisional application No. 61/086,307, filed on Aug. 5, 2008.

(30) Foreign Application Priority Data
Aug. 1, 2008 (JP) 2008-199430
Aug. 1, 2008 (JP) 2008-199431

(51) Int. Cl. G03F 7/20; G03F 7/004

(52) U.S. Cl. 430/270.1; 430/331; 430/401; 430/325

(57) ABSTRACT

A surface treating agent for resist pattern formation comprises a compound having two or more nucleophilic functional groups in each of the molecules thereof, or its salt, and a solvent.

### CROSS-REFERENCE TO RELATED APPLICATIONS

This application claims the benefit of U.S. Provisional Applications No. 61/086,278, filed Aug. 5, 2008; and No. 61/086,307, filed Aug. 5, 2008.

This application is based upon and claims the benefit of priority from prior Japanese Patent Applications No. 2008-199430, filed Aug. 1, 2008; and No. 2008-199431, filed Aug. 1, 2008, the entire contents of both of which are incorporated herein by reference.

### BACKGROUND OF THE INVENTION

1. Field of the Invention

The present invention relates to a surface treating agent for resist pattern formation employed in a semiconductor production process for an IC or the like, a circuit board production process for a liquid crystal, thermal head or the like and other photofabrication lithography processes, and also relates to a method of forming a pattern by use thereof.

More particularly, the present invention relates to a surface treating agent for resist pattern formation that is suitable for exposure by means of a liquid immersion projection exposure apparatus using far ultraviolet rays of 200 nm or shorter wavelength as a light source, and to a method of forming a pattern by use thereof.

2. Description of the Related Art

Since the wavelength shortening of the exposure light source to 248 nm using a KrF excimer laser, it has been of common practice to, in order to compensate for any sensitivity deterioration caused by light absorption, employ an image forming method through chemical amplification as a resist image forming method and employ a resist suitable for the same. Brief description of an image forming method through positive chemical amplification is given below by way of example. Upon exposure, an acid generator will be decomposed at exposed areas to thereby generate an acid. At bake after the exposure (PEB: Post-Exposure Bake), the generated acid is used as a reaction catalyst so that an alkali-insoluble group is converted to an alkali-soluble group. Thereafter, alkali development is carried out to thereby remove the exposed areas. Thus, the relevant image forming method is provided.

In accordance with the miniaturization of semiconductor elements, the wavelength shortening of the exposure light source and the realization of high numerical apertures (high NA) for projector lenses have advanced. Up to now, an exposure machine using an ArF excimer laser of 193 nm wavelength as a light source has been developed. The degree of attainment of semiconductor element miniaturization can be expressed by the resolving power. As is commonly known, the resolving power can be expressed by the following formula.

(Resolving power)=k₁·(λ/NA)

In the formula, λ is the wavelength of the exposure light source; NA is the numerical aperture of the projector lens; and k₁ is a factor relating to the process.

Heretofore, a method of filling an interspace between a projector lens and a sample with a liquid of high refractive index (hereinafter also referred to as a “liquid for liquid immersion”), known as a liquid immersion method, is recommended as a technology for enhancing the resolving power.

With respect to the “effect of liquid immersion,” taking λ₀ as the wavelength of exposure light in air, n as the refractive index of liquid for liquid immersion to air and θ as the convergent half angle of light beam, where NA₀=sin θ, the above-mentioned resolving power and the relevant focal depth in the event of liquid immersion can be expressed by the following formula.

(Resolving power)=k₁·(λ₀/n)/NA₀

That is, the effect of liquid immersion is equivalent to the use of a 1/n exposure wavelength. In other words, in projection optic systems of identical NA, the liquid immersion would enable the focal depth to be n-fold.

As another technology for enhancing the resolving power, pattern forming methods using a special process have been proposed. These correspond to lowering of the value of k₁ in the above formula of resolving power. One of the methods is a freezing process (see, for example, patent references 1 to 3 and non-patent references 1 to 4).

The freezing process refers to the process wherein, in the double patterning technique involving formation of a first resist pattern on a first resist film, formation of a second resist film on the first resist pattern and formation of a second resist pattern thereon, the properties of the first resist pattern are changed by chemical or physical treatment thereof so that the first resist pattern becomes essentially insoluble in the second applied resist solvent and developer, as described in the non-patent reference 3 and non-patent reference 4. By the employment of this freezing process, etching can be performed after carrying out the lithography process from exposure to development twice, so that the first post-exposure etching operation can be avoided. Herein, the expression “essentially insoluble” in the second applied resist solvent and developer means that, regarding the insolubility in the second applied resist solvent by way of example, when a second resist solution is applied on the first resist pattern having undergone the freezing treatment, the thickness of the first resist film having decreased within the application time (typically within 60 seconds) is within 5% of the initial film thickness.

Patent reference 1 proposes a technology in which a freezing treatment agent containing a specified metal compound is applied onto a first resist pattern so as to form a metal oxide coating, thereby insolubilizing the resist pattern in the solvent of a second applied resist and also a thereafter applied developer.

However, in this technology, as the second resist pattern is not provided with any metal oxide coating, a difference would occur in the etching resistance between the first resist pattern and the second resist pattern, thereby causing the control of pattern dimension after etching to be difficult. It would be conceivable to apply the surface treating agent to the second resist pattern for avoiding this problem. However, this would invite a problem of increasing the number of operations.

Patent reference 2 and non-patent references 1 and 2 propose methods in which a freezing treatment agent containing a specified resin and crosslinking agent is caused to act on the first resist pattern so as to form a coating consisting of the resin composition of the treatment agent, thereby insolubilizing the first resist pattern in the second applied resist solvent and developer. However, for example, the proposal of the non-patent references 1 and 2 has the problem that the line width roughness (LWR) of the resist pattern after the freezing is deteriorated.

Moreover, patent reference 3 proposes a method in which the first resist pattern is exposed to ultraviolet rays in vacuum so as to modify the first resist pattern, thereby insolubilizing the first resist pattern in the second applied resist solvent and developer. This proposal has the problem that the first resist pattern comes to have a reduced dimension.

[Patent reference 1] Jpn. Pat. Appln. KOKAI Publication No. (hereinafter referred to as JP-A-) 2008-33174

[Patent reference 2] JP-A-2008-83537

[Patent reference 3] JP-A-2006-18095

[Non-patent reference 1] Proceedings of SPIE, Vol. 6153, 615301 (2006)

[Non-patent reference 2] Proceedings of SPIE, Vol. 6923, 69230H (2008)

[Non-patent reference 3] Proceedings of SPIE, Vol. 6924, 69240R (2008)

[Non-patent reference 4] Proceedings of SPIE, Vol. 6520, 65200F (2007)

### BRIEF SUMMARY OF THE INVENTION

The present invention has been made in view of the above background of the art. It is an object of the present invention to provide a resist composition and a surface treating agent for freezing process that satisfy the requirement that the line width and LWR of the first resist pattern suffer no change by the freezing treatment and the formation of the second resist pattern in the freezing process performed on the first resist pattern in the double patterning technique. It is another object of the present invention to provide a method of forming a pattern by use thereof.

The inventors have conducted extensive and intensive studies with a view toward solving the above problem, and have arrived at the following invention.

(1) A surface treating agent for resist pattern formation comprising a compound having two or more nucleophilic functional groups in each of the molecules thereof, or its salt, and a solvent.

(2) The surface treating agent for resist pattern formation according to item (1), wherein the nucleophilic functional groups are connected to an optionally substituted alkylene group, an optionally substituted cycloalkylene group or an optionally substituted aromatic group.

(3) The surface treating agent for resist pattern formation according to item (2), wherein the compound having two or more nucleophilic functional groups is any of the compounds of general formula (I) below:

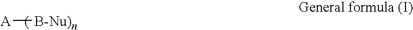

wherein A represents a single bond or an n-valent connecting group; B represents a single bond, an alkylene group, a cycloalkylene group or an aromatic group, the alkylene group, cycloalkylene group or aromatic group optionally having a substituent; Nu represents a nucleophilic functional group; n is an integer of 2 to 8; and two or more B's and Nu's may be identical to or different from each other, provided that in no event A and B simultaneously represent single bonds.

(4) The surface treating agent for resist pattern formation according to item (2), wherein at least one of the nucleophilic functional groups is any one selected from among a primary amino group, a secondary amino group, a hydroxyl group, a thiol group and —(C═O)CH₂(C═O)—.

(5) The surface treating agent for resist pattern formation according to item (2), wherein the solvent is water, an alcoholic solvent or a mixture containing water and an alcoholic solvent.

(6) The surface treating agent for resist pattern formation according to item (2), wherein a surfactant is further contained.

(7) The surface treating agent for resist pattern formation according to item (1), wherein the compound having two or more nucleophilic functional groups is a polymer and/or oligomer.

(8) The surface treating agent for resist pattern formation according to item (7), wherein the polymer and/or oligomer having nucleophilic functional groups has a weight average molecular weight of 500 or greater.

(9) The surface treating agent for resist pattern formation according to item (8), wherein the weight average molecular weight is in the range of 500 to 5000.

(10) The surface treating agent for resist pattern formation according to item (7), wherein at least one of the nucleophilic functional groups is any one selected from among a primary or secondary amino group, a hydroxyl group or its conjugate base, a thiol or its conjugate base, a conjugate base of carboxyl group and a conjugate base of —(C═O)CH₂(C═O)—.

(11) The surface treating agent for resist pattern formation according to item (10), wherein the polymer and/or oligomer further has at least one of the groups of formulae (3), (4) and (5) below:

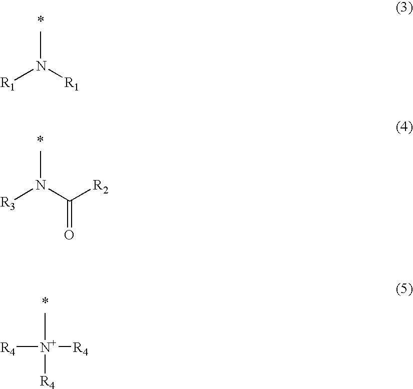

in the formulae (3), (4) and (5),

each of R₁s independently represents an optionally substituted alkyl group or an optionally substituted cycloalkyl group, provided that the two R₁s may be bonded to each other to thereby form a ring,

R₂ represents an alkyl group, a cycloalkyl group, an aromatic group, an alkoxy group or an alkenyl group, in which a substituent may be introduced,

R₃ represents a hydrogen atom, an optionally substituted alkyl group, an optionally substituted cycloalkyl group or an optionally substituted alkenyl group, provided that R₂ and R₃ may be bonded to each other to thereby form a ring,

each of R₄s independently represents a hydrogen atom, an optionally substituted alkyl group or an optionally substituted cycloalkyl group, provided that two or more R₄s may be bonded to each other to thereby form a ring, and

* represents a site of linkage with a polymer and/or oligomer residue.

(12) The surface treating agent for resist pattern formation according to item (7), wherein the solvent is water, an alcoholic solvent or a mixture of water and alcoholic solvent.

(13) The surface treating agent for resist pattern formation according to item (7), wherein a surfactant is further contained.

(14) The surface treating agent for resist pattern formation according to item (1), wherein a polymer or oligomer being inactive to both of the compound having nucleophilic functional groups or its salt and the solvent is further contained.

(15) The surface treating agent for resist pattern formation according to item (1), which, when the resist pattern consists of a first resist pattern obtained by exposing a first resist film and developing the exposed film and, a second resist pattern obtained by exposing a second resist film provided on the first resist pattern and developing the exposed film, is a surface treating agent for the first resist pattern formation.

(16) The surface treating agent for resist pattern formation according to item (1), which is substantially free from changing a line width of resist pattern.

(17) A resist composition for use in the formation of a pattern whose surface is treated with the surface treating agent for resist pattern formation according to item (1), which resist composition comprises a resin with a cyclic unit so that at the surface treatment, the cyclic unit and the nucleophilic functional groups contained in the surface treating agent are bonded to each other through a chemical reaction.

(18) The resist composition according to item (17), wherein the cyclic unit is a lactone unit or a cyclic acid anhydride unit.

(19) The resist composition according to item (18), wherein the lactone unit is a lactone unit having an electron withdrawing group or a sugar lactone unit.

(20) A method of treating the surface of a resist pattern, comprising the steps of applying a surface treating agent, which comprises a compound having two or more nucleophilic functional groups in each of the molecules thereof, or its salt and a solvent, onto a resist pattern formed by use of the resist composition according to item (17) to thereby form a surface treating agent film and cause the resin contained in the resist pattern to react with the surface treating agent and removing any unreacted portion of the surface treating agent.

(21) The surface treating method according to item (20), wherein the step of causing the resin contained in the resist pattern to react with the surface treating agent includes an operation of baking the resist pattern after the formation of the surface treating agent film.

(22) The surface treating method according to item (20), wherein the resist pattern suffers substantially no change of its line width.

(23) A method of treating the surface of a resist pattern, comprising the steps of immersing a resist pattern formed by use of the resist composition according to item (17) in a surface treating agent, which comprises a compound having two or more nucleophilic functional groups in each of the molecules thereof, or its salt and a solvent, to thereby cause the resin contained in the resist pattern to react with the surface treating agent and removing any unreacted portion of the surface treating agent.

(24) The surface treating method according to item (23), wherein the step of causing the resin contained in the resist pattern to react with the surface treating agent includes an operation of baking the resist pattern after the immersion of the resist pattern in the surface treating agent.

(25) The surface treating method according to item (23), wherein the resist pattern suffers substantially no change of its line width.

(26) A method of forming a pattern, comprising the steps of applying the resist composition according to item (17) onto a substrate to thereby form a first resist film, exposing the first resist film and developing the exposed film so that a first resist pattern is obtained; treating the surface of the thus obtained first resist pattern in accordance with the surface treating method according to item (20); and applying a second resist composition onto the first resist pattern after the surface treatment to thereby form a second resist film, exposing the second resist film and developing the exposed film so that a second resist pattern is obtained.

The present invention has made it feasible to provide a freezing process that satisfies the requirement that the line width and LWR of the first resist pattern suffer no change by the freezing treatment and the formation of the second resist pattern in the double patterning technique.

### BRIEF DESCRIPTION OF THE SEVERAL VIEWS OF THE DRAWING

FIG. 1 is a schematic process chart explaining one mode of the method of forming a pattern as employed in Working Examples.

FIG. 2 is a schematic process chart explaining another mode of the method of forming a pattern as employed in Working Examples.

### DETAILED DESCRIPTION OF THE INVENTION

Now, the treating agent of the present invention will be described in detail.

With respect to the expression of group (atomic group) used in this specification, the expression even when there is no mention of “substituted and unsubstituted” encompasses groups not only having no substituent but also having substituents. For example, the expression “alkyl groups” encompasses not only alkyls having no substituent (unsubstituted alkyls) but also alkyls having substituents (substituted alkyls).

<Compound having two or more Nucleophilic Functional Groups in each of the Molecules thereof>

The surface treating agent for resist pattern formation according to the present invention is characterized by containing a compound having two or more nucleophilic functional groups in each of the molecules thereof or its salt (hereinafter also referred to as “chemical species of the present invention,” “chemical species” or the like). The present invention is characterized in that by causing the surface treating agent for resist pattern formation according to the present invention to act on the first pattern, a chemical reaction is induced between the chemical species of the present invention and the cyclic unit (for example, a lactone unit or a cyclic acid anhydride unit) of the resin constituting the resist film forming the first pattern to thereby effect bonding and crosslinking therebetween, so that the first pattern is essentially insolubilized in the solvent of the second resist.

In the present invention, the nucleophilic functional group refers to a substituent capable of reaction with an atom of low electron density to thereby form a bond thereto, generally meaning a substituent capable of performing a nucleophilic substitution reaction. In particular, there can be mentioned a primary amino group, a secondary amino group, a hydroxyl group, a thiol group or the like. A primary amino group and a secondary amino group are especially preferred. In the present invention, the secondary amino groups include groups having a secondary amino group, such as a hydrazido group and a guanidino group, and cyclic secondary amino groups, such as a pyrrolidino group, a piperidino group, a piperazino group and a hexahydrotriazino group. These can be mentioned as preferred examples thereof.

Further, in the present invention, groups capable of easily forming anions (including a carbanion) are included in the nucleophilic functional groups. As such substituents, there can be mentioned groups having a pKa value in water of less than 18. Groups having a pKa value in water of less than 16 are preferred. Substituents having a pKa value in water of less than 13 are more preferred. In particular, there can be mentioned a —COCH₂CO— group, a —COCH₂CN group, a —COCH₂SO₂— group, a —SO₂CH₂SO₂— group and the like. A —COCH₂CO— group and a —COCH₂CN group can be mentioned as preferred examples.

The compound having two or more nucleophilic functional groups in each of the molecules thereof may be a low-molecular compound or a polymer compound (polymer and/or oligomer).

First, the low-molecular compound will be described below.

The chemical species of the present invention has two or more nucleophilic functional groups in each of the molecules thereof, preferably two to eight nucleophilic functional groups in each of the molecules thereof.

It is preferred for the chemical species of the present invention to have a structure consisting of any of alkylene, cycloalkylene and aromatic groups having two or more nucleophilic functional groups linked thereto. The alkylene group preferably has 1 to 20 carbon atoms, more preferably 2 to 12 carbon atoms. The alkylene group may be linear or branched, and may have a substituent. The cycloalkylene group preferably has 3 to 20 carbon atoms, more preferably 5 to 12 carbon atoms. The cycloalkylene group may be monocyclic or polycyclic. A substituent may be introduced in the ring. Herein, the “alkylene groups” and “cycloalkylene groups” as apparent from optionally having a substituent are not limited to bivalent connecting groups and include trivalent or higher valency connecting groups resulting from further removal of a hydrogen atom.

The aromatic groups may be monocyclic or polycyclic and include nonbenzene aromatic groups. As monocyclic aromatic groups, there can be mentioned, for example, a benzene residue, a pyrrole residue, a furan residue, a thiophene residue, an indole residue and the like. As polycyclic aromatic groups, there can be mentioned, for example, a naphthalene residue, an anthracene residue, a tetracene residue, a benzofuran residue, a benzothiophene residue and like. The aromatic groups may have substituents.

The substituents that can be introduced in the alkylene groups, cycloalkylene groups and aromatic groups are not particularly limited. For example, there can be mentioned an alkyl group, an alkoxy group, an alkylcarbonyl group, an alkylcarbonyloxy group, an alkyloxycarbonyl group, an alkenyl group, an alkenyloxy group, an alkenylcarbonyl group, an alkenylcarbonyloxy group, an alkenyloxycarbonyl group, an alkynyl group, an alkynyleneoxy group, an alkynylenecarbonyl group, an alkynylenecarbonyloxy group, an alkynyleneoxycarbonyl group, an aralkyl group, an aralkyloxy group, an aralkylcarbonyl group, an aralkylcarbonyloxy group, an aralkyloxycarbonyl group, a hydroxyl group, an amido group, a carboxyl group, a cyano group, a fluorine atom and the like.

More particularly, as preferred examples of the compounds having nucleophilic functional groups according to the present invention, there can be mentioned the structures of general formula (I) below.

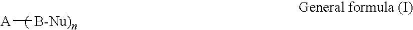

In the general formula (I), A represents a single bond or an n-valent connecting group. B represents a single bond, an alkylene group, a cycloalkylene group or an aromatic group. The alkylene group, cycloalkylene group or aromatic group may have a substituent, and n is an integer of 2 to 8. Two or more B's and Nu's may be identical to or different from each other, provided that in no event A and B simultaneously represent single bonds.

In particular, A preferably represents a single bond, a group of formula (1A) below, a group of formula (1B) below,

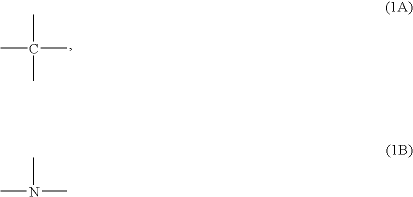

—NH—, —NR—, —O—, —S—, a carbonyl group, an alkylene group, an alkenylene group, an alkynylene group, a cycloalkylene group, an aromatic group, a heterocyclic group or an n-valent organic group consisting of a combination thereof. In the formulae, R represents an organic group, which is preferably an alkyl group, an alkylcarbonyl group or an alkylsulfonyl group. In the above combination, heteroatoms are in no event linked to each other.

Nu represents a nucleophilic functional group. The description and particular examples of nucleophilic functional groups are as given hereinbefore.

The n-valent organic groups may have a substituent. The substituent is the same as the above-mentioned substituent that can be introduced in the alkylene group, cycloalkylene group or aromatic group.

Each of the alkylene group, alkenylene group and alkynylene group preferably has 1 to 20 carbon atoms, more preferably 2 to 12 carbon atoms. The alkylene group may be linear or branched, and may have a substituent. The cycloalkylene group preferably has 3 to 20 carbon atoms, more preferably 5 to 12 carbon atoms. The cycloalkylene group may be monocyclic or polycyclic. A substituent may be introduced in the ring.

B represents a single bond, an alkylene group, a cycloalkylene group or an aromatic group. Each of the alkylene group, cycloalkylene group and aromatic group may have a substituent. The alkylene group, cycloalkylene group and aromatic group are as described above. In the formula, n is an integer of 2 to 8, preferably an integer of 3 to 8.

Preferred examples of the chemical species of the present invention will be shown below, which however in no way limit the scope of the present invention.

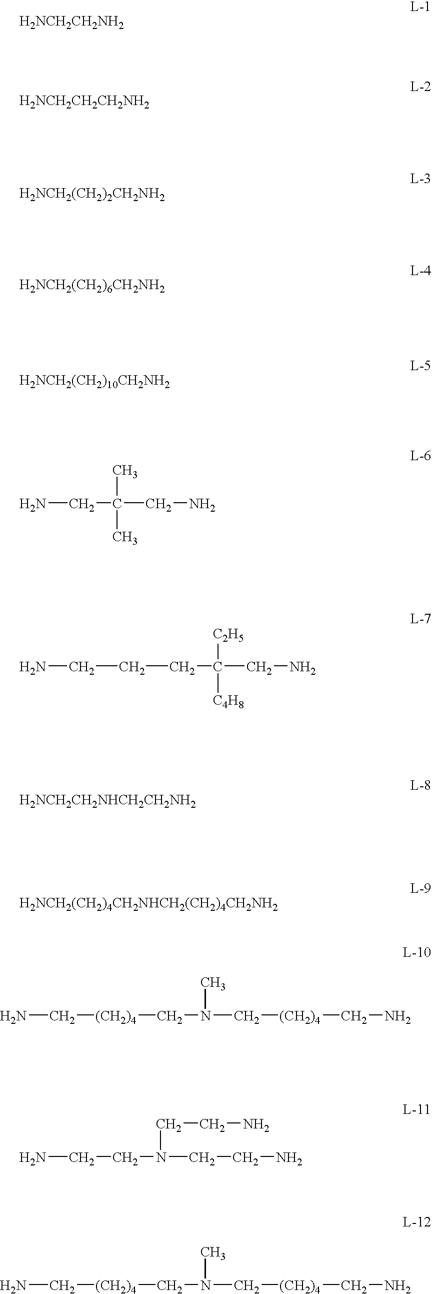

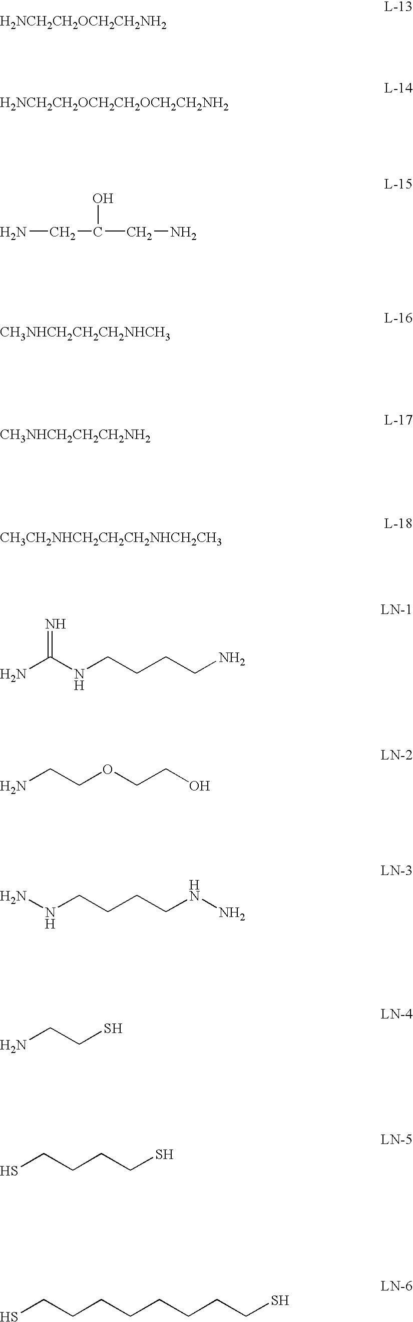

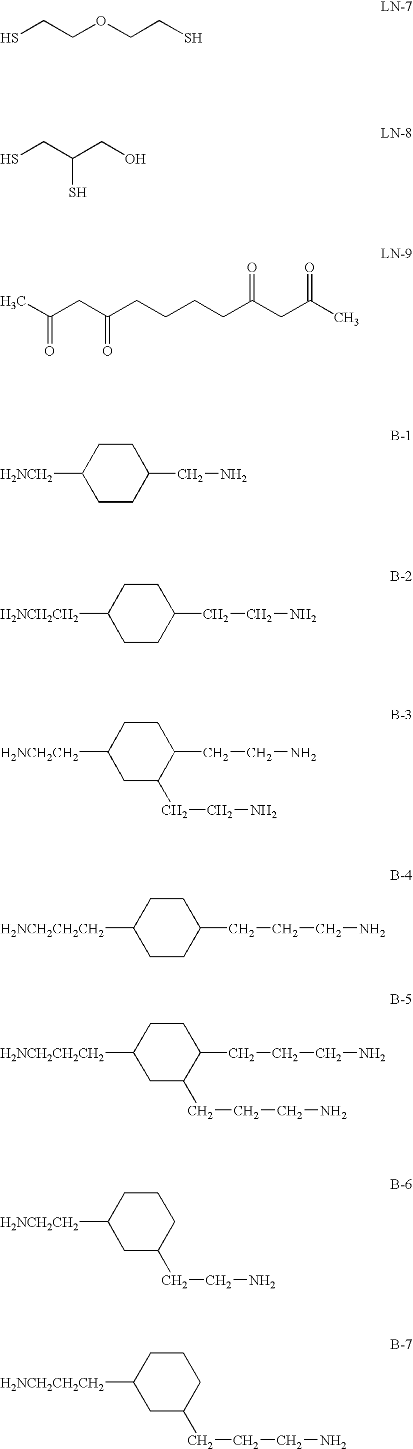

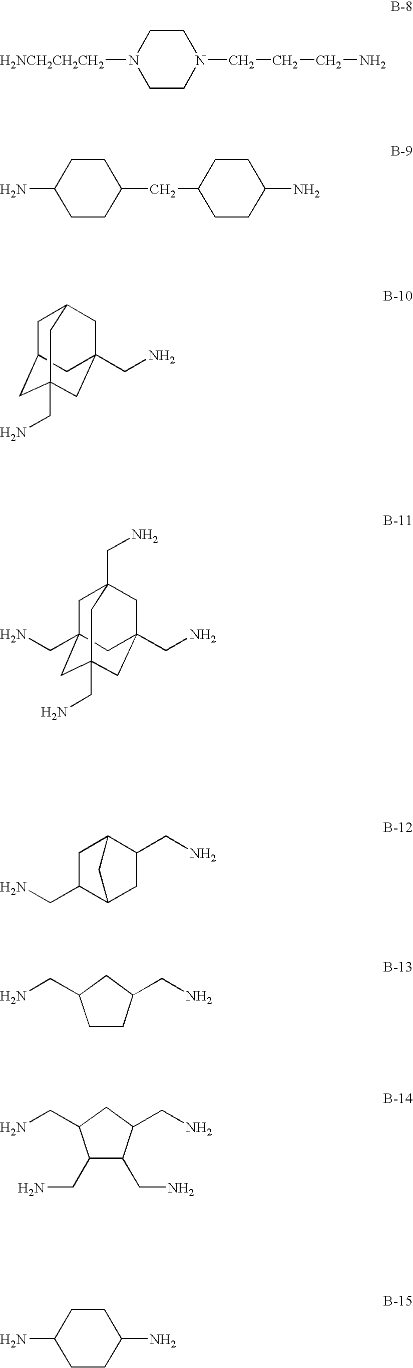

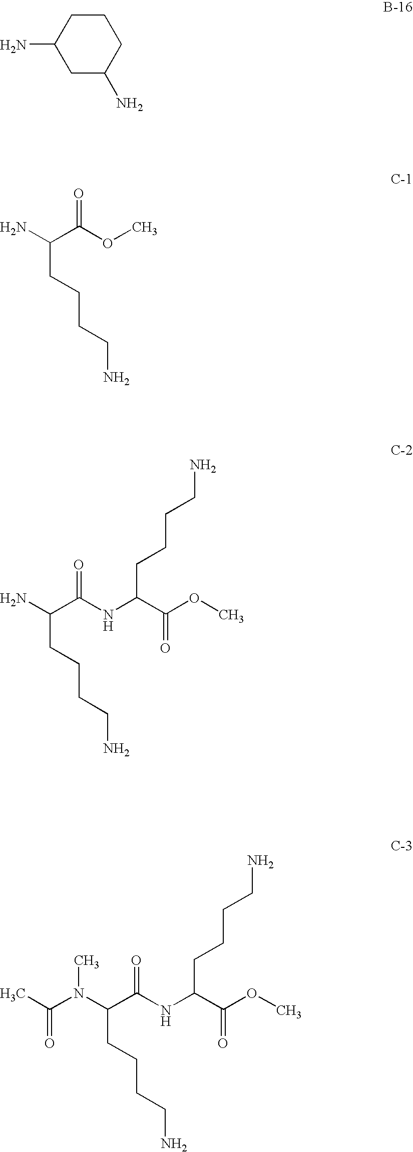

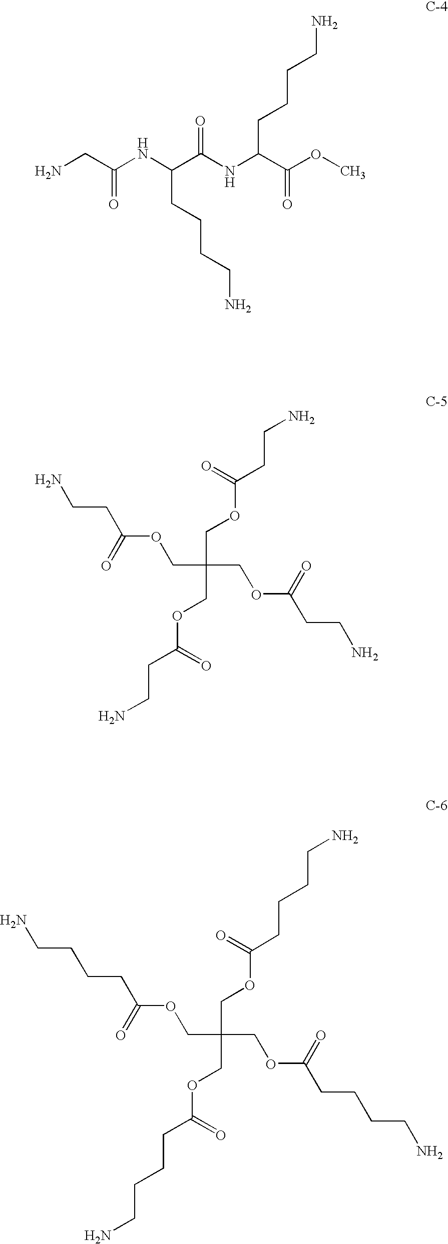

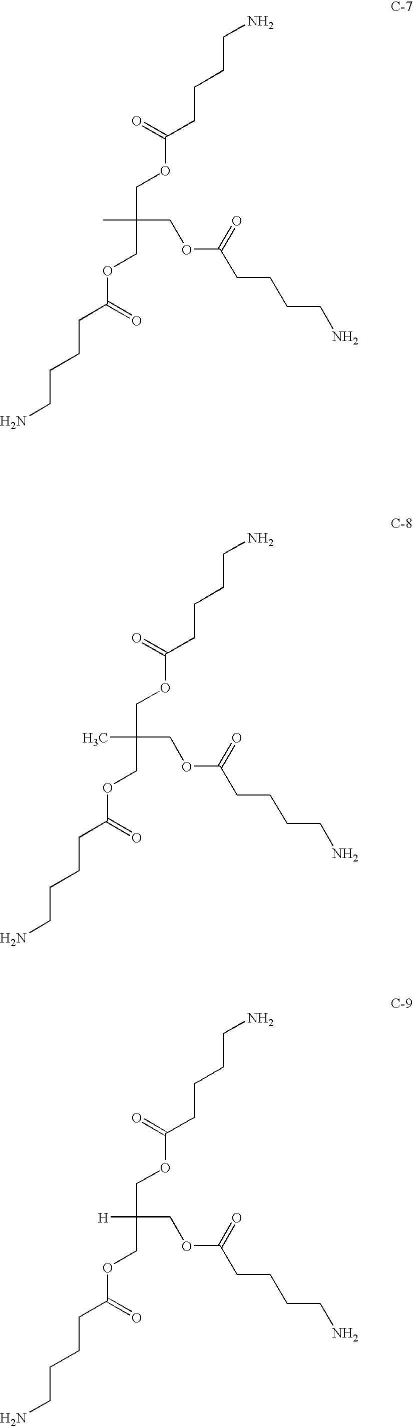

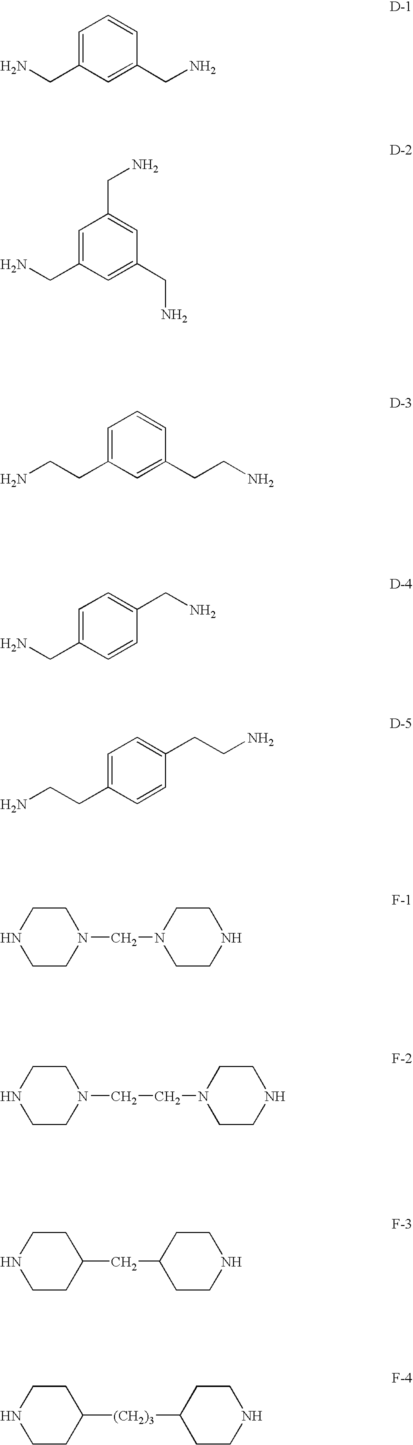

The molecular weight of the low-molecular compound having nucleophilic functional groups according to the present invention is preferably in the range of 50 to 2000, more preferably 50 to 500.

In the surface treating agent of the present invention, the concentration of all solid contents including the chemical species of the present invention (ratio of all the components excluding the solvent in the treating agent) is preferably in the range of 50 to 0.01 mass %, more preferably 30 to 0.1 mass % and further preferably 20 to 0.5 mass %.

The ratio of the chemical species of the present invention contained in the treating agent, based on all the solid contents, is preferably in the range of 100 to 1 mass %, more preferably 100 to 3 mass % and further preferably 100 to 5 mass %.

Both commercially available products and those synthesized by the methods known in the art can be used as the compounds of the formula (I).

The compound having nucleophilic functional groups according to the present invention may be formed into a salt. When the nucleophilic functional group is any of primary amino groups and secondary amino groups (including a hydrazido group, a guanidino group and the like) or the like, it can form a salt in cooperation with an acid component. The formation of a salt is advantageous from the viewpoint of storage stability. The acid component of the salt would neutralize any components remaining in the developer in the stage of the formation of the first resist pattern and would react with the above-mentioned cyclic group to thereby form a bond. As preferred examples of the salts formed with the acid component, there can be mentioned salts of low molecular acids, such as a carboxylic acid salt and a sulfonic acid salt. An aryl sulfonate is preferred. This aryl group may be substituted with an alkyl group, an alkoxy group, a halogen atom or the like. As the salts, there can be mentioned, for example, an acetic acid salt, a trifluorobutanesulfonic acid salt, a heptafluoropropanesulfonic acid salt, a benzenesulfonic acid salt, a p-toluenesulfonic acid salt and the like. When the nucleophilic functional group is a hydroxyl group, a thiol group, a —COCH₂CO— group, a —COCH₂CN group or the like, it can form a salt in cooperation with a base component. The formation of a salt is advantageous for acceleration of the reaction with the cyclic group. Both an inorganic base and an organic base can be employed as the base component in the stage of the salt formation. However, an organic base is preferred. In particular, various amines can be employed.

In these salts, all the nucleophilic functional groups of each molecule may be formed into salts, or only some thereof may be formed into salts. With respect to the acid component or base component for salt formation, an acid or a base may be separately added to the treating agent of the present invention to thereby form a salt.

Now, the polymer and/or oligomer as the compound having two or more nucleophilic functional groups in each of the molecules thereof will be described below.

The nucleophilic functional group contained in the chemical species of the present invention is one capable of reacting with the cyclic unit, such as a lactone or a cyclic acid anhydride, lying on a resist pattern and/or in a resist pattern to thereby form a bond. The nucleophilic functional group is preferably a primary or secondary amino group, a hydroxyl group or its conjugate base, a thiol or its conjugate base, a conjugate base of carboxyl group or a conjugate base of —(C═O)CH₂(C═O)—. The nucleophilic functional group is more preferably a primary or secondary amino group, a conjugate base of hydroxyl group or a conjugate base of thiol. A primary or secondary amino group is most preferred.

In the present invention, it is preferred to employ a polymer and/or oligomer having at least one of the structures of formulae (1) and (2) below as the primary or secondary amino group.

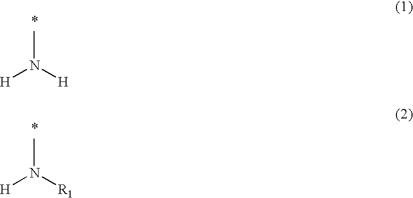

In the formulae (1) and (2),

* represents a site of linkage with a polymer and/or oligomer residue.

In the formula (2), R₁ represents an alkyl group or a cycloalkyl group.

The alkyl group represented by R₁ is, for example, a linear or branched alkyl group having 1 to 10 carbon atoms. The cycloalkyl group is, for example, a monocyclic or polycyclic alkyl group having 1 to 12 carbon atoms. These may have a substituent. As the substituent, there can be mentioned a hydroxyl group, a halogen atom, a cyano group, an alkoxy group, an alkylthio group or the like.

In the chemical species of the present invention, the primary amino group and/or secondary amino group is bonded to a polymer and/or oligomer residue. The primary amino group and/or secondary amino group of the formula (1) and/or (2) may be directly bonded to the principal chain or an end of a polymer and/or oligomer. The bonding may be effected via a connecting group.

Any bivalent connecting group without restriction can be used as the connecting group. There can be mentioned, for example, a bivalent connecting group consisting of an alkylene group, a cycloalkylene group, an alkenylene group, an alkynylene group, a carbonyl group, an ether group, a thioether group, an imino group, an alkylimino group or a combination of these, provided that any bond between heteroatoms is excluded.

Particular examples of the nucleophilic functional groups and nucleophilic functional groups having connecting groups bonded thereto will be shown below, which are however nonlimiting. * represents a site of linkage with a polymer and/or oligomer residue.

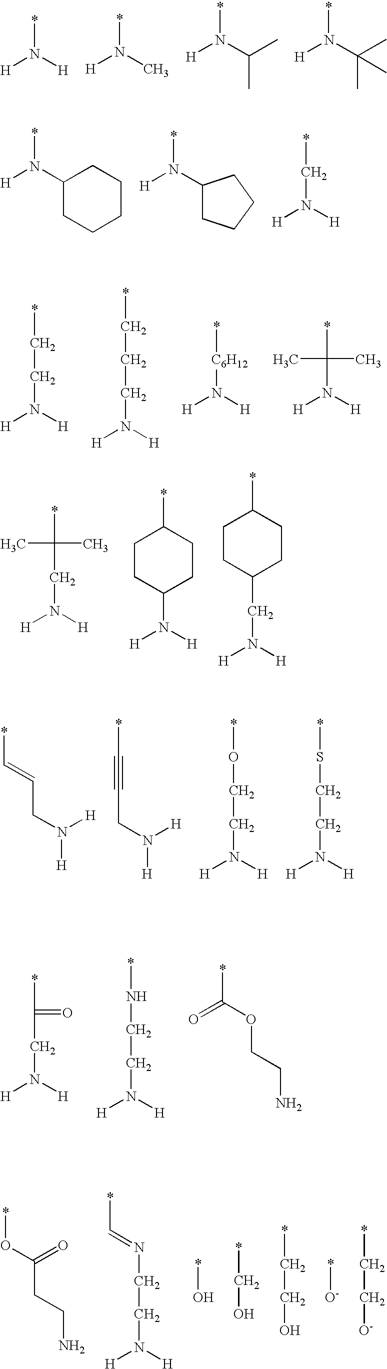

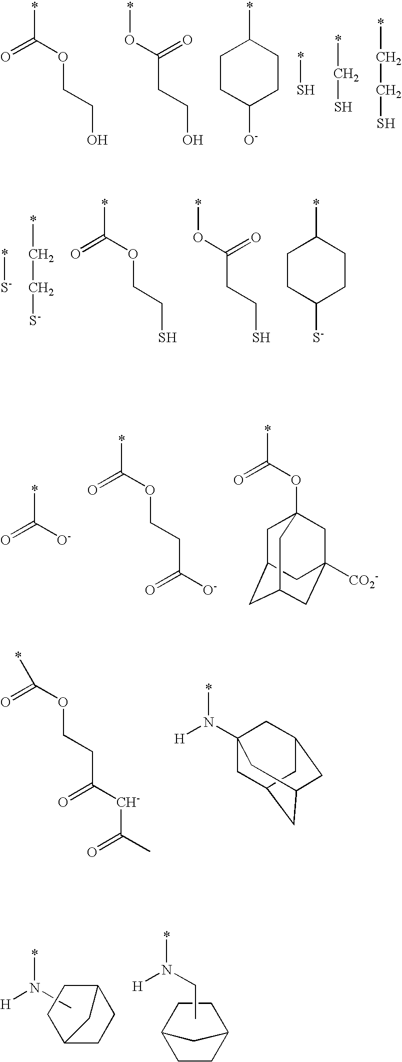

The chemical species of the present invention may further contain at least one structure selected from the group of formulae (3), (4) and (5) below.

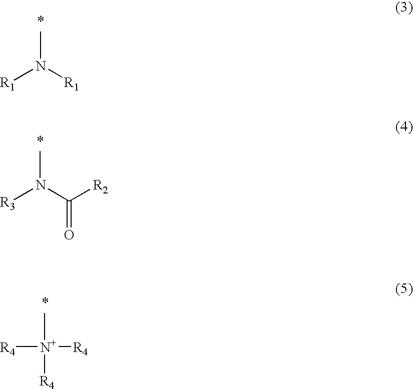

In the formulae (3), (4) and (5),

* represents a site of linkage with a polymer and/or oligomer residue.

In the formula (3), each of R₁s independently represents an optionally substituted alkyl group or an optionally substituted cycloalkyl group, provided that the two R₁s may be bonded to each other to thereby form a ring.

In the formula (4), R₂ represents an alkyl group, a cycloalkyl group, an aromatic group, an alkoxy group or an alkenyl group, in which a substituent may be introduced.

R₃ represents a hydrogen atom, an optionally substituted alkyl group, an optionally substituted cycloalkyl group or an optionally substituted alkenyl group, provided that R₂ and R₃ may be bonded to each other to thereby form a ring.

In the formula (5), each of R₄s independently represents a hydrogen atom, an optionally substituted alkyl group or an optionally substituted cycloalkyl group, provided that two or more R₄s may be bonded to each other to thereby form a ring.

The formulae (3) to (5) will be described in detail below.

In the formula (3), preferably, each of R₁s independently represents a linear or branched alkyl group having 1 to 4 carbon atoms, such as a methyl group, an ethyl group, an n-propyl group, an isopropyl group, an n-butyl group, an isobutyl group or a t-butyl group, or a cycloalkyl group, such as a cyclopropyl group, a cyclobutyl group, a cyclopentyl group or a cyclohexyl group. A methyl group, an ethyl group and a cyclopropyl group are especially preferred. As a substituent that can be introduced in the alkyl group or cycloalkyl group represented by R₁, there can be mentioned a halogen atom, a hydroxyl group, a nitro group, a cyano group, a carboxyl group, an alkoxy group or the like.

In the formula (4), preferably, R₂ represents a linear or branched alkyl group having 1 to 4 carbon atoms, such as a methyl group, an ethyl group, an n-propyl group, an isopropyl group, an n-butyl group, an isobutyl group or a t-butyl group; a cycloalkyl group, such as a cyclopropyl group, a cyclobutyl group, a cyclopentyl group, a cyclohexyl group or an adamantyl group; a linear or branched alkoxy group having 1 to 4 carbon atoms, such as a methoxy group, an ethoxy group, an n-propyloxy group, an isopropyloxy group, an n-butoxy group, an isobutoxy group or a t-butoxy group; a cycloalkoxy group, such as a cyclopropyloxy group, a cyclobutyloxy group, a cyclopentyloxy group or a cyclohexyloxy group; an aromatic group, such as a phenyl group or a naphthyl group; or an alkenyl group, such as a vinyl group, an allyl group, a 1-butenyl group or a 2-butenyl group. A methyl group, an ethyl group, a cyclopropyl group, a methoxy group, an ethoxy group and a cyclopropyloxy group are especially preferred. As a substituent that can be introduced in the alkyl group, cycloalkyl group, aromatic group or alkenyl group represented by R₂, there can be mentioned a halogen atom, a hydroxyl group, a nitro group, a cyano group, a carboxyl group, an alkylcarbonyl group, an alkoxy group or the like.

R₃ preferably represents a hydrogen atom, a linear or branched alkyl group having 1 to 4 carbon atoms, such as a methyl group, an ethyl group, an n-propyl group, an isopropyl group, an n-butyl group, an isobutyl group or a t-butyl group, or a cycloalkyl group, such as a cyclopropyl group, a cyclobutyl group, a cyclopentyl group or a cyclohexyl group. A hydrogen atom, a methyl group, an ethyl group and a cyclopropyl group are especially preferred. As a substituent that can be introduced in the alkyl group or cycloalkyl group represented by R₃, there can be mentioned a halogen atom, a hydroxyl group, a nitro group, a cyano group, a carboxyl group, an alkylcarbonyl group, an alkoxy group or the like.

In the formula (5), R₄ preferably represents a hydrogen atom, a linear or branched alkyl group having 1 to 4 carbon atoms, such as a methyl group, an ethyl group, an n-propyl group, an isopropyl group, an n-butyl group, an isobutyl group or a t-butyl group, or a cycloalkyl group, such as a cyclopropyl group, a cyclobutyl group, a cyclopentyl group or a cyclohexyl group. A hydrogen atom, a methyl group, an ethyl group and a cyclopropyl group are especially preferred. As a substituent that can be introduced in the alkyl group or cycloalkyl group represented by R₄, there can be mentioned a halogen atom, a hydroxyl group, a nitro group, a cyano group, a carboxyl group, an alkylcarbonyl group, an alkoxy group or the like.

Any of the groups of the formulae (3) to (5) is bonded to a polymer and/or oligomer residue. The groups may be directly bonded to the principal chain or an end of a polymer and/or oligomer. The bonding may be effected via a connecting group. Particular examples of the connecting groups are as mentioned above.

Particular examples of the structures of formulae (3) to (5) above and the structures having a connecting group bonded thereto will be shown below, which are however nonlimiting. * represents a site of linkage with a polymer and/or oligomer residue.

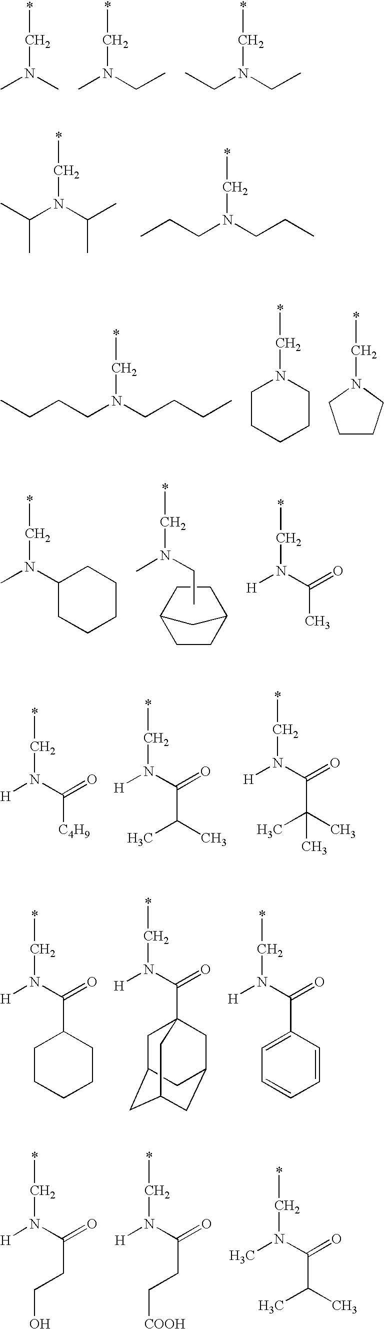

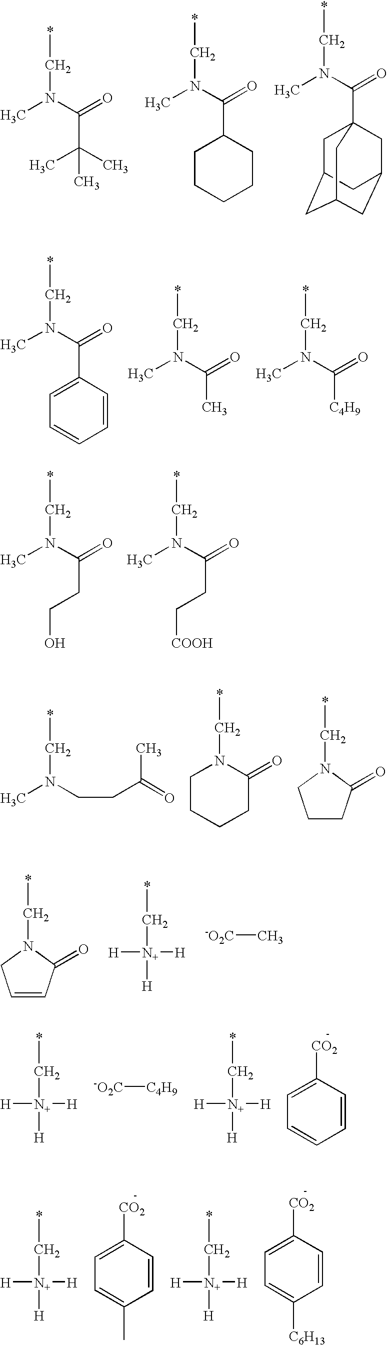

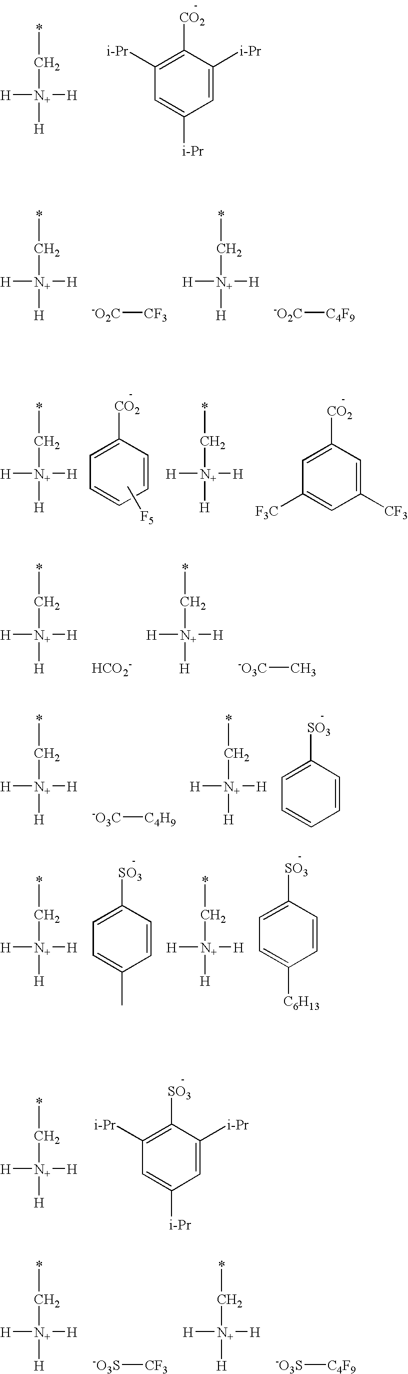

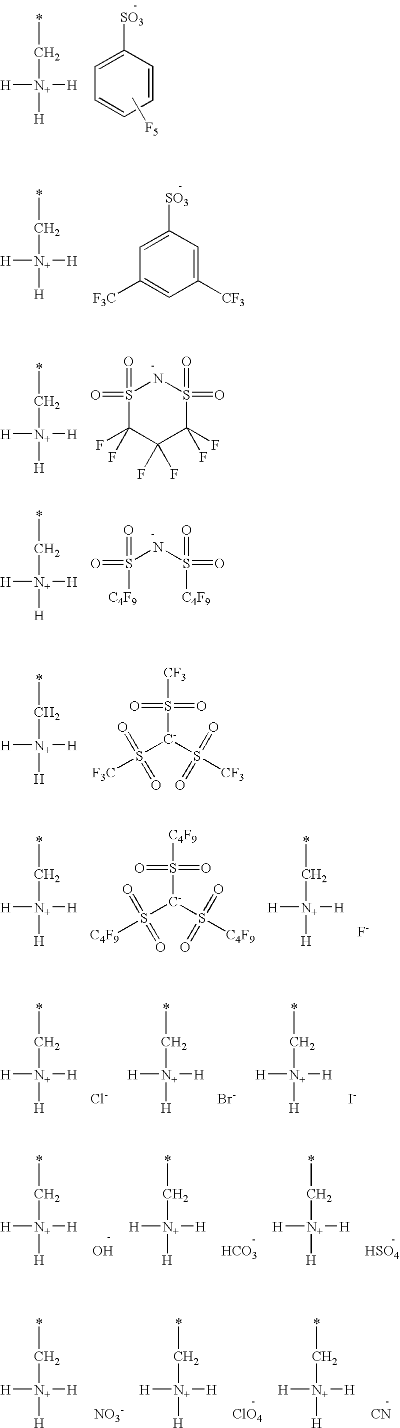

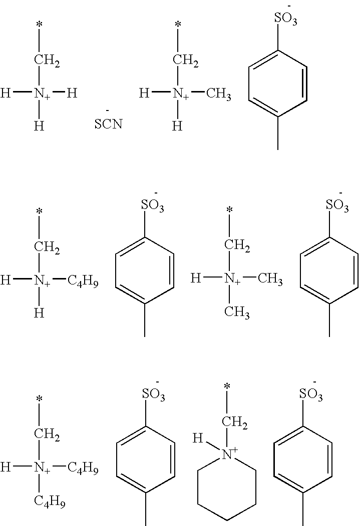

The polymer and/or oligomer as the chemical species of the present invention has preferably a weight average molecular weight in terms of polyethylene oxide as measured by GPC of 500 to 100,000, more preferably 500 to 20,000, still more preferably 500 to 15,000 and especially preferably 500 to 5000.

As the polymer and/or oligomer having a primary amino group and/or a secondary amino group suitable as the chemical species of the present invention, there can be mentioned a polyallylamine, an oligoallylamine, any of poly- or oligoallylamine derivatives, a poly- or oligoallylamine copolymer, a polypeptide, an oligopeptide, a poly- or oligomethacrylate having an amino group at its side chain, a poly-/oligoethylene oxide having an amino group at its chain terminal, a poly-/oligopropylene oxide having an amino group at its chain terminal, or the like.

These can be produced by use of the processes known in the art. For example, as the polyallylamine, use can be made of one produced by use of the process described in Example 1 of JP-A-58-201811. Further, commercially available products can be used. For example, as commercially available products for a poly- or oligoallylamine, there can be mentioned PAA-HCL-01, PAA-HCL-03, PAA-HCL-05, PAA-HCL-10L, PAA-H-HCL, PAA-SA, PAA-01, PAA-03, PAA-05, PAA-08, PAA-15, PAA-15C, PAA-25, PAA-H-10C, PAA-D19A, PAA-1112CL, PAA-1112, PAA-U5000, PAA-HCL-3S, PAA-HCL-10S, PAA-03-E, PAA-D11-HCL, PAA-D41-HCL and PAA-D19-HCL (produced by Nitto Boseki Co., Ltd.). As the polypeptide, there can be mentioned polylysine (produced by Chisso Corporation).

Examples of the polymers and/or oligomers having at least one primary amino group and/or secondary amino group for use in the present invention will be shown below, which are however nonlimiting.

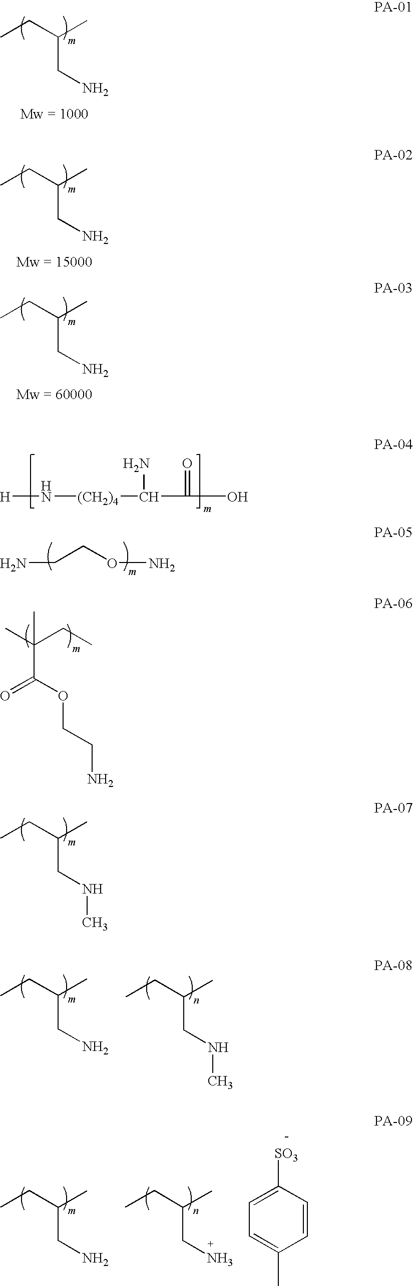

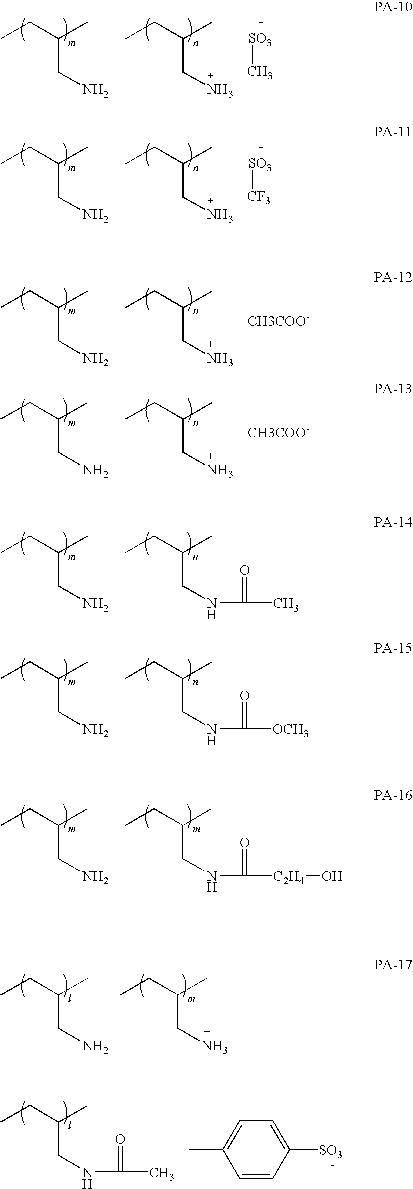

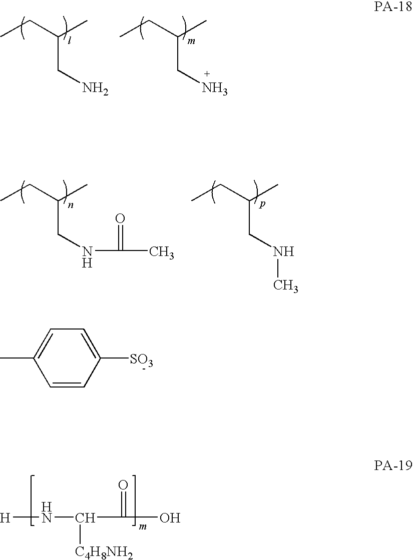

In the surface treating agent of the present invention, the concentration of all solid contents including the chemical species of the present invention (ratio of all the components of the treating agent excluding the solvent) is preferably in the range of 50 to 0.01 mass %, more preferably 30 to 0.1 mass % and further preferably 20 to 0.5 mass %.

The ratio of the chemical species of the present invention contained in the treating agent, based on all the solid contents, is preferably in the range of 100 to 1 mass %, more preferably 100 to 3 mass % and further preferably 100 to 5 mass %.

<Solvent>

Any solvent that does not dissolve the first resist pattern but is capable of dissolving the chemical species of the present invention can be used as the solvent to be contained in the surface treating agent for resist pattern formation according to the present invention. Herein, not dissolving the first resist pattern refers to that, when at 23° C. a 200 nm line-and-space pattern of 0.2 μm height is formed and immersed in a solvent for 10 min, both a pattern width change and a pattern height change fall within ±5%. As such a solvent, there can be mentioned water, an alcoholic solvent, a fluorinated solvent, a saturated hydrocarbon solvent or the like. Especially, water, an alcoholic solvent and a mixture containing water and an alcoholic solvent are preferred from the viewpoint of solubility of the chemical species of the present invention.

It is preferred for the alcoholic solvent to be a monohydric alcohol from the viewpoint of environmental safety, storage stability and human safety. Alcohols can be used either individually or in a mixture.

As specific examples of the monohydric alcohols, there can be mentioned methanol, ethanol, n-propanol, isopropanol, n-butanol, sec-butanol, tert-butanol, isobutanol, tert-pentanol, n-hexanol, n-heptanol, 2-heptanol, n-octanol, n-decanol, 3-methyl-3-pentanol, 2,3-dimethyl-2-pentanol, 4-phenyl-2-methyl-2-hexanol, 1-phenyl-2-methyl-2-propanol, s-amyl alcohol, t-amyl alcohol, isoamyl alcohol, 2-ethyl-1-butanol, n-undecanol and the like. Of these, alcohols having 3 to 11 carbon atoms are preferred. Alcohols having 3 to 7 carbon atoms are more preferred. From the viewpoint of suppression of solvent evaporation, the number of carbon atoms is preferably 3 or greater.

As the fluorinated solvent, use can be made of perfluoro-2-butyltetrahydrofuran, perfluorotetrahydrofuran, perfluorohexane, perfluoroheptane, perfluorotributylamine, perfluorotetrapentylamine, perfluorotetrahexylamine or the like. These organic solvents can be used either individually or in a mixture. The content of fluorine in each molecule is preferably in the range of 40 to 80 mass %, more preferably 50 to 80 mass %.

In particular, the fluorinated solvent has preferably 7 to 12 carbon atoms, more preferably 9 to 12 carbon atoms. From the viewpoint of suppression of solvent evaporation, the number of carbon atoms is preferably 7 or greater, more preferably 9 or greater.

As the saturated hydrocarbon solvent, there can be mentioned a linear or branched alkane or a cycloalkane. Specifically, use can be made of pentane, 2-methylbutane, 3-methylpentane, hexane, 2,2-dimethylbutane, 2,3-dimethylbutane, heptane, octane, 2,2,4-trimethylpentane, 2,2,3-trimethylhexane, nonane, decane, undecane, dodecane, 2,2,4,6,6-pentamethylheptane, tridecane, pentadecane, tetradecane, hexadecane, cyclopentane, cyclohexane, cycloheptane, cyclooctane or the like. These organic solvents can be used either individually or in a mixture. Further, a terpenic saturated hydrocarbon can be used as a solvent. As a preferred example, there can be mentioned a cyclic saturated terpene, such as pinane, bornane, carane, fencane, thujane, o-menthane, m-menthane or p-menthane.

These saturated hydrocarbon solvents each have preferably 6 to 10 carbon atoms, more preferably 7 to 9 carbon atoms. From the viewpoint of suppression of solvent evaporation, the number of carbon atoms is preferably 6 or greater, more preferably 7 or greater.

Any of organic solvents can be used as long as it essentially does not dissolve the first resist pattern but is capable of essentially dissolving the chemical species of the present invention. However, it is preferred for the employed solvent to contain any one of water, an alcoholic solvent, a fluorinated solvent and a saturated hydrocarbon solvent in an amount of 80 mass % or more, especially 100 mass %.

As other organic solvents, use can be made of at least any one appropriately selected from among ester, ether, ketone, amide, aromatic hydrocarbon and cycloketone solvents.

<Surfactant for Treating Agent>

The treating agent of the present invention preferably contains any of various surfactants.

The amount of surfactant used is preferably in the range of 0.0001 to 2 mass %, more preferably 0.001 to 1 mass % based on the total amount of the treating agent. The surfactants may be used individually or in combination. The applicability of the treating agent can be enhanced by the addition of a surfactant to the treating agent.

It is desired to select an appropriate surfactant in conformity with the type of the solvent used.

As the surfactant suitable for the fluorinated solvent and saturated hydrocarbon solvent, there can be mentioned those used for the “first resist” to be described hereinafter.

As the surfactant suitable for the alcoholic solvent, water and mixed solvent consisting of water and the alcoholic solvent, there can be mentioned the following nonionic, anionic, cationic and amphoteric surfactants.

As the nonionic surfactant, use can be made of, for example, any of Plufarac LE400, Plufarac LE221, Plufarac LP101, Plufarac P104, Plufarac P105, Plufarac P123, Pluronic PE10300, Pluronic PE6200, Pluronic RPE2520 and Tetronic RED9040 (all produced by BASF); ELEBASE BA-100, ELEBASE BA-200, ELEBASE BCP-2, ELEBASE BUB-3, ELEBASE BUB-4, ELEBASE CP-800K, ELEBASE EDP-475, ELEBASE HEB-5, Finesurf 270, Finesurf 7045, Finesurf 7085, Brownon DSP-12.5, Brownon DT-03, Brownon L-205, Brownon LPE-1007, Brownon MXDA EO-4, Brownon O-205, Brownon S-202, Brownon S-204, Brownon S-207 and Brownon S-205T (all produced by Aoki Oil Industrial Co., Ltd.); Adeka Pluronic P-103 (produced by Asahi Denka Co., Ltd.); Emargen A-500, Emargen PP-290, Emargen 104P, Emargen 108, Emargen 404, Emargen 408, Emargen A-60, Emargen B-66, Emargen LS-106, Emargen LS-114, Amiet 102, Amiet 105, Amiet 302, Amiet 320, Aminon PK-02S, Emanon CH-25, Reodol 430V, Reodol 440V, Reodol 460V, Reodol TW-S106, Reodol TW-S120V and Reodol Super TW-L120 (all produced by Kao Corporation); Surfron S-141 (produced by AGC Seimi Chemical Co., Ltd.); Neugen EA-177 and Neugen EA-137 (produced by Daiichi Kogyo Seiyaku Co., Ltd.); Newcargen 3000S, Newcargen 500, Newcargen FS-3PG, Newcargen FS-7PG and Pionin D-6414 (all produced by Takemoto Oil&Fat Co., Ltd.); DYNOL 604, EnviroGem AD01, Olfin EXP. 4001, Olfin EXP. 4036, Olfin EXP. 4051, Olfin PD-002W, Surfinol 2502, Surfinol 440, Surfinol 465, Surfinol 485 and Surfinol 61 (all produced by Nisshin Chemical Industry Co., Ltd.); Phthagent 300 (available from Ryoko Chemical Co., ltd.); Poem C-250, Poem J-0021, Poem 0081HV, Rikemal L-250A and Rikemal O-852 (all produced by Riken Vitamin Co., ltd.); and Acetylenol E00, Acetylenol E13T, Acetylenol E40, Acetylenol E81, Acetylenol E100, Acetylenol E37T, Acetylenol E80T, Acetylenol E150, Acetylenol E200, Acetylenol E300, Acetylenol E00P, Acetylenol E00F24, Acetylenol E00E, Acetylenol E00H and Acetylenol E00D (produced by Kawaken Fine Chemical Co., Ltd.).

As the anionic surfactant, use can be made of, for example, any of Emal 20T and Poise 532A (both produced by Kao Corporation); Phosphanol ML-200 (produced by Toho Chemical Industry Co., Ltd.); EMULSOGEN COL-020, EMULSOGEN COA-070 and EMULSOGEN COL-080 (all produced by Clariant Japan Co., Ltd.); Surfron S-111N and Surfron S-211 (both produced by AGC Seimi Chemical Co., Ltd.); Plysurf A208B, Plysurf A210B, Plysurf A210G, Plysurf A212C, Plysurf A219B, Plysurf AL and Lavelin FC-45 (all produced by Daiichi Kogyo Seiyaku Co., Ltd.); Pionin A-29-M and Pionin A-44TW (produced by Takemoto Oil&Fat Co., Ltd.); Olfin PD-201 and Olfin PD-202 (produced by Nisshin Chemical Industry Co., Ltd.); AKYPO RLM45, ECT-3 (produced by Nihon Surfactant Kogyo K.K.); Lipon LH-200 (produced by Lion Corporation); and Poem K-30 and Poem K-37V (produced by Riken Vitamin Co., ltd.).

As the cationic surfactant, use can be made of, for example, Acetamin 24 or Acetamin 86 (produced by Kao Corporation).

As the amphoteric surfactant, use can be made of, for example, any of Surfron S-131 (produced by AGC Seimi Chemical Co., Ltd.) and Enagicol C-40H and Lipomin LA (produced by Lion Corporation).

Of the surfactants, the anionic surfactants and nonionic surfactants are preferably employed. It is also appropriate to use a mixture of two or more types of surfactants.

<Acid>

The treating agent of the present invention may further contain an acid or a base according to necessity.

As the optionally added acids, there can be mentioned low molecular acids, such as a carboxylic acid and a sulfonic acid. In particular, there can be mentioned acetic acid, trifluorobutanesulfonic acid, heptafluoropropanesulfonic acid, benzenesulfonic acid, p-toluenesulfonic acid, perfluorobenzenesulfonic acid and the like. As the optionally added bases, there can be mentioned various organic bases. In particular, amines can be mentioned.

<Thermal Acid Generator>

The treating agent of the present invention may further contain a thermal acid generator.

In the present invention, the thermal acid generator refers to a compound that generates an acid by the action of heat. The compound generally has a thermal decomposition point of 60° to 200° C., preferably 90° to 150° C. For example, it is a compound that when heated, generates an acid of low nucleophilicity, such as a sulfonic acid, a carboxylic acid or a disulfonylimide.

The generated acid is preferably, for example, any of a sulfonic acid, an alkyl- or arylcarboxylic acid substituted with an electron withdrawing group and a disulfonylimide substituted with an electron withdrawing group, all exhibiting a high acidity of 2 or below pKa. As the electron withdrawing group, there can be mentioned a halogen atom such as an F atom, a haloalkyl group such as a trifluoromethyl group, a nitro group or a cyano group.

As the thermal acid generator, there can be mentioned a sulfonic ester or an ammonium sulfonate.

The amount of thermal acid generator used, based on the total mass of the treating agent, is preferably in the range of 0.001 to 99 mass %, more preferably 0.01 to 50 mass %. The thermal acid generators may be used individually or in combination.

Examples of the thermal acid generators that can be used in the present invention will be shown below, which are however nonlimiting.

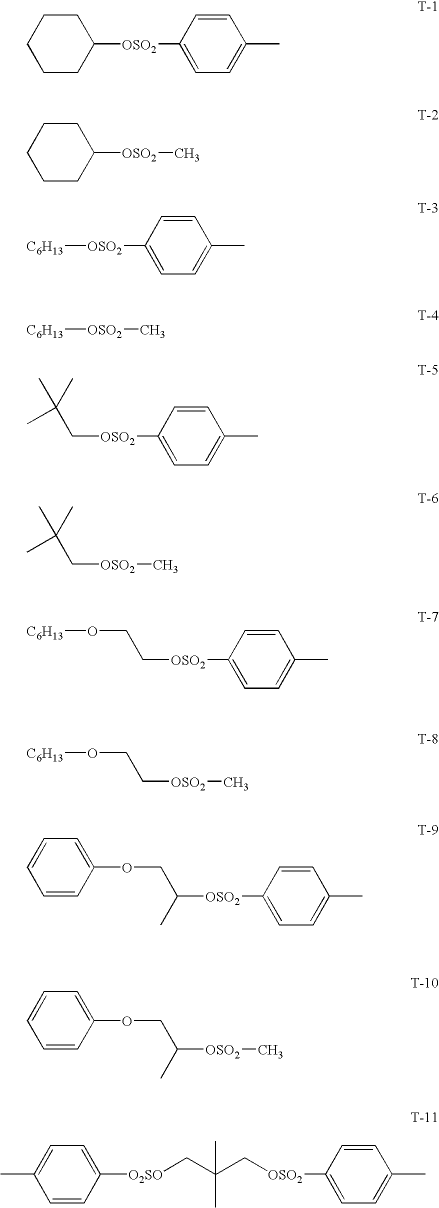

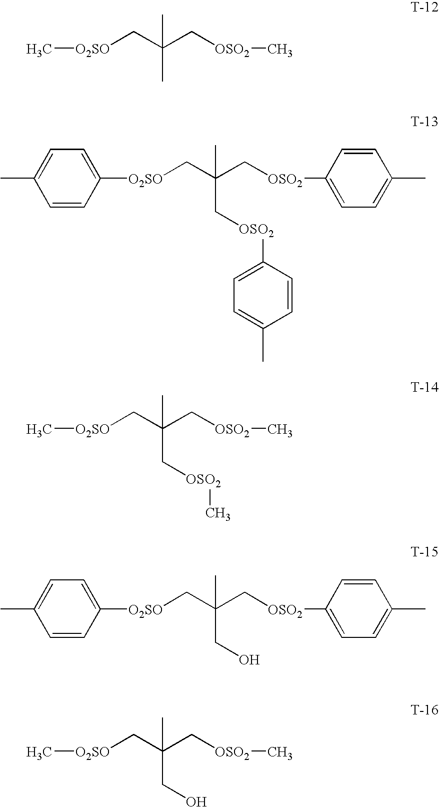

<Photoacid Generator>

Further, a photoacid generator capable of generating an acid when exposed to light to be described hereinafter with respect to the “first resist” can be used as the thermal acid generator in the treating agent of the present invention. As such, there can be mentioned, for example, an onium salt such as a sulfonium salt or an iodonium salt, an N-hydroxyimido sulfonate compound, an oxime sulfonate, an o-nitrobenzyl sulfonate or the like.

<Inactive Polymer or Oligomer>

It is preferred for the treating agent of the present invention to further contain an inactive polymer or oligomer that does not form any chemical bond with the chemical species of the present invention (hereinafter also simply referred to as an “inactive polymer”).

Preferably, the inactive polymer or oligomer even when heated does not form any chemical bond with the chemical species of the present invention and can be dissolved in solvents that do not dissolve the resist pattern.

As examples thereof, there can be mentioned a polyalkylene oxide, a polyalkylene glycol, a polyvinyl ether, a polystyrene, a poly(methyl)methacrylate, a polyvinyl ester, a polyamide, a polysiloxane and the like. Of these, a polyalkylene oxide and a polyalkylene glycol are preferred. With respect to the polyalkylene oxide and polyalkylene glycol, it would be preferred to block the terminals thereof with an ether structure or ester structure in order to inhibit the reaction with the chemical species of the present invention.

In particular, the inactive polymers that can be used in the present invention are as follows.

As the polyalkylene oxide, there can be mentioned a polyethylene oxide dialkyl ether, a polyethylene oxide diester, a polypropylene oxide dialkyl ether, a polypropylene oxide diester or the like.

As the polyalkylene glycol, there can be mentioned a polyethylene glycol dialkyl ether, a polyethylene glycol diester, a polypropylene glycol dialkyl ether, a polypropylene glycol diester or the like.

As the polystyrene, there can be mentioned polystyrene, a polyalkylstyrene, a polyalkoxystyrene, a polyvinylbenzoic ester, a polyvinylbenzoic amide, a polyhydroxystyrene salt, a polyvinylbenzoic salt or a polystyrenesulfonic salt.

As the poly(methyl)methacrylate, there can be mentioned a polyacrylic salt, a polymethacrylic salt, a polymethacrylic ester, a polyacrylic ester, a polymethacrylic amide or a polyacrylic amide.

As the polyvinyl ether, there can be mentioned polymethyl vinyl ether, polyisobutyl vinyl ether or poly[2-(methoxyethoxy)ethylene].

As the polyvinyl ester, there can be mentioned polyvinyl acetate.

As the polyamide, there can be mentioned polyalanine, polyphenylalanine, polyglycine, polyleucine, polyisoleucine, polyvaline, polymethionine or any of copolymers thereof.

As the polysiloxane, there can be mentioned polydimethylsiloxane.

The weight average molecular weight of inactive polymers as determined by the polyethylene oxide standard GPC measurement is preferably in the range of 2000 to 200,000, more preferably 7500 to 100,000.

When the treating agent of the present invention contains any of these inactive polymers, the content thereof based on the chemical species of the present invention is generally in the range of 1 to 100, preferably 1 to 20 and more preferably 1 to 10 in mass ratio.

<Other Additive>

According to necessity, the treating agent of the present invention may further contain a base, a photosensitizer, a freezing reaction accelerator other than the above-mentioned acid, a resin, a coating aid, etc.

2. First Resist

In the present invention, it is important to, after the formation of a first resist pattern on a first resist film, change the first resist pattern so as to be insoluble in a second resist liquid by use of the treating agent containing the chemical species of the present invention. This solubility control can be attained by changing not only the properties of the treating agent but also the properties of the first resist and/or the process conditions at application of the treating agent.

The first resist may be a positive resist or a negative resist. However, a positive resist is preferred from the viewpoint of an enhancement of reactivity with the treating agent. Herein, the “positive resist” refers to a resist whose exposed area is dissolved in a developer, and the “negative resist” refers to a resist whose non-exposed area is dissolved in a developer. In the positive resist, generally, use is made of a chemical reaction, such as the elimination of an atomic group protecting an alkali-soluble group in order to increase the solubility of an exposed area in a developer. On the other hand, in most of negative resists, use is made of an intermolecular bond formation through crosslinking reaction, polymerization reaction or the like.

The positive resist preferably contains (A) a resin that when acted on by an acid, is decomposed to thereby exhibit an increased solubility in an alkali developer and (B) a compound that when exposed to actinic rays or radiation, generates an acid.

[1] Resin that when Acted on by an Acid, is Decomposed to thereby Exhibit an Increased Solubility in an Alkali Developer (Resin (A))

It is preferred for the resin (A) to have a substituent that at the time of treatment of the surface of the first resist pattern, undergoes a nucleophilic reaction by the surface treating agent of the present invention so that a chemical reaction with the compound having nucleophilic functional groups contained in the treating agent of the present invention can be realized to thereby change the properties of the first resist pattern so as to be insoluble in the second resist liquid. Especially, a resin containing a cyclic group as the group undergoing the reaction with nucleophilic species is preferred.

The resin (A) is a resin whose solubility in an alkali developer is increased by the action of an acid; in particular, a resin having, in its principal chain or side chain, or both of its principal chain and side chain, a group (hereinafter also referred to as “an acid-decomposable group”) that is decomposed by the action of an acid to thereby generate an alkali soluble group.

As the alkali soluble group, there can be mentioned a phenolic hydroxyl group, a carboxyl group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali soluble groups, there can be mentioned a carboxyl group, a fluoroalcohol group (preferably hexafluoroisopropanol) and a sulfonate group.

The acid-decomposable group is preferably a group as obtained by substituting the hydrogen atom of any of these alkali soluble groups with an acid eliminable group.

As the acid eliminable group, there can be mentioned, for example, —C(R₃₆)(R₃₇)(R₃₈), —C(R₃₆)(R₃₇)(OR₃₉), —C(R₀₁)(R₀₂)(OR₃₉) or the like.

In the formulae, each of R₃₆ to R₃₉ independently represents an alkyl group, a cycloalkyl group, an aryl group, an aralkyl group or an alkenyl group. R₃₆ and R₃₇ may be bonded with each other to thereby form a ring structure.

Each of R₀₁ to R₀₂ independently represents a hydrogen atom, an alkyl group, a cycloalkyl group, an aryl group, an aralkyl group or an alkenyl group.

Preferably, the acid-decomposable group is a cumyl ester group, an enol ester group, an acetal ester group, a tertiary alkyl ester group or the like. A tertiary alkyl ester group is more preferred.

The repeating unit with an acid-decomposable group that may be contained in the resin (A) is preferably any of those of the following general formula (AI).

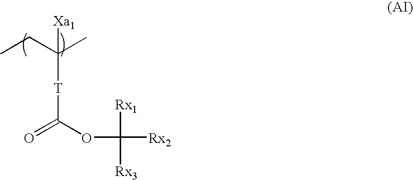

In the general formula (AI),

Xa₁ represents a hydrogen atom, a methyl group, a trifluoromethyl group or a hydroxymethyl group.

T represents a single bond or a bivalent connecting group.

Each of Rx₁ to Rx₃ independently represents an alkyl group (linear or branched) or a cycloalkyl group (monocyclic or polycyclic).

At least two of Rx₁ to Rx₃ may be bonded with each other to thereby form a cycloalkyl group (monocyclic or polycyclic).

As the bivalent connecting group represented by T, there can be mentioned an alkylene group, a group of the formula —COO-Rt-, a group of the formula —O-Rt- or the like. In the formulae, Rt represents an alkylene group or a cycloalkylene group.

T is preferably a single bond or a group of the formula —COO-Rt-. Rt is preferably an alkylene group having 1 to 5 carbon atoms, more preferably a —CH₂— group or —(CH₂)₃— group.

The alkyl group represented by each of Rx₁ to Rx₃ is preferably one having 1 to 4 carbon atoms, such as a methyl group, an ethyl group, an n-propyl group, an isopropyl group, an n-butyl group, an isobutyl group or a t-butyl group.

The cycloalkyl group represented by each of Rx₁ to Rx₃ is preferably a cycloalkyl group of one ring, such as a cyclopentyl group or a cyclohexyl group, or a cycloalkyl group of multiple rings, such as a norbornyl group, a tetracyclodecanyl group, a tetracyclododecanyl group or an adamantyl group.

The cycloalkyl group formed by bonding of at least two of Rx₁ to Rx₃ is preferably a cycloalkyl group of one ring, such as a cyclopentyl group or a cyclohexyl group, or a cycloalkyl group of multiple rings, such as a norbornyl group, a tetracyclodecanyl group, a tetracyclododecanyl group or an adamantyl group.

In a preferred mode, Rx₁ is a methyl group or an ethyl group, and Rx₂ and Rx₃ are bonded with each other to thereby form any of the above-mentioned cycloalkyl groups.

The aforementioned atomic group may further have a substituent. There can be mentioned, for example, an alkyl group, cycloalkyl group, an alkoxy group, a hydroxyl group or a cyano group.

The content of the repeating units with acid-decomposable groups is preferably in the range of 10 to 50 mol %, more preferably 15 to 45 mol %, based on all the repeating units of the resin (A).

Specific examples of the preferred repeating units with acid-decomposable groups will be shown below, which however in no way limit the scope of the present invention.

In the following formulae, Rx represents a hydrogen atom, CH₃, CF₃ or CH₂OH. Each of Rxa and Rxb represents an alkyl group having 1 to 4 carbon atoms.

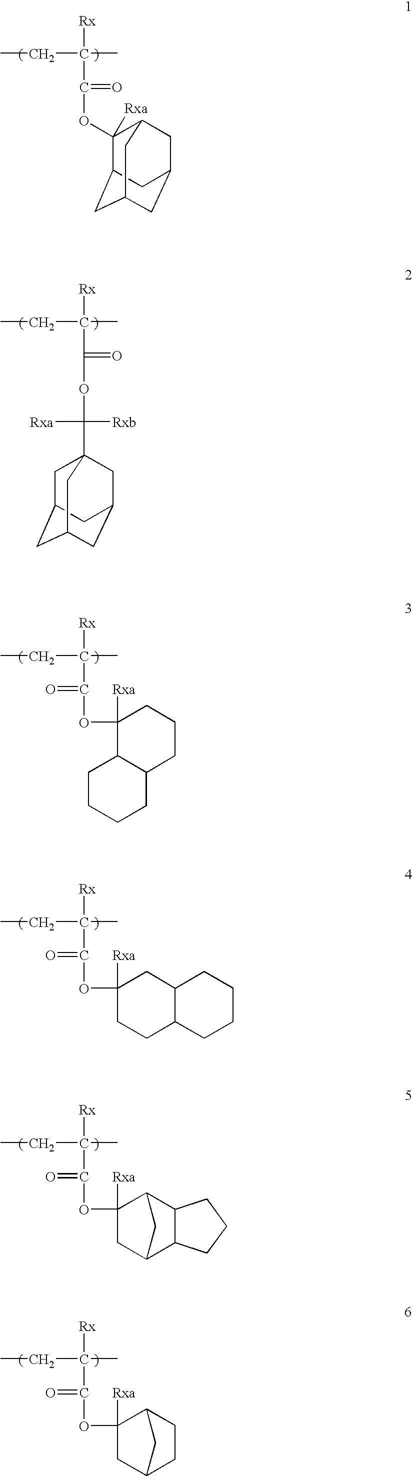

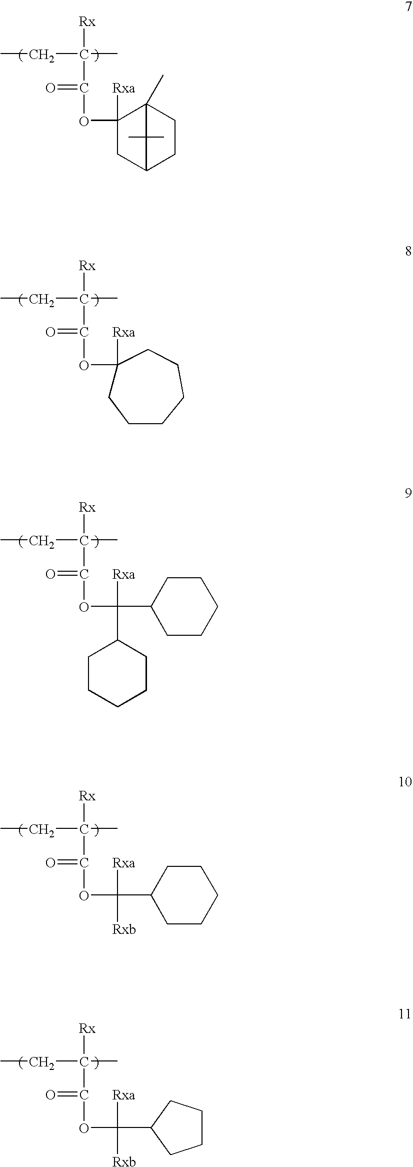

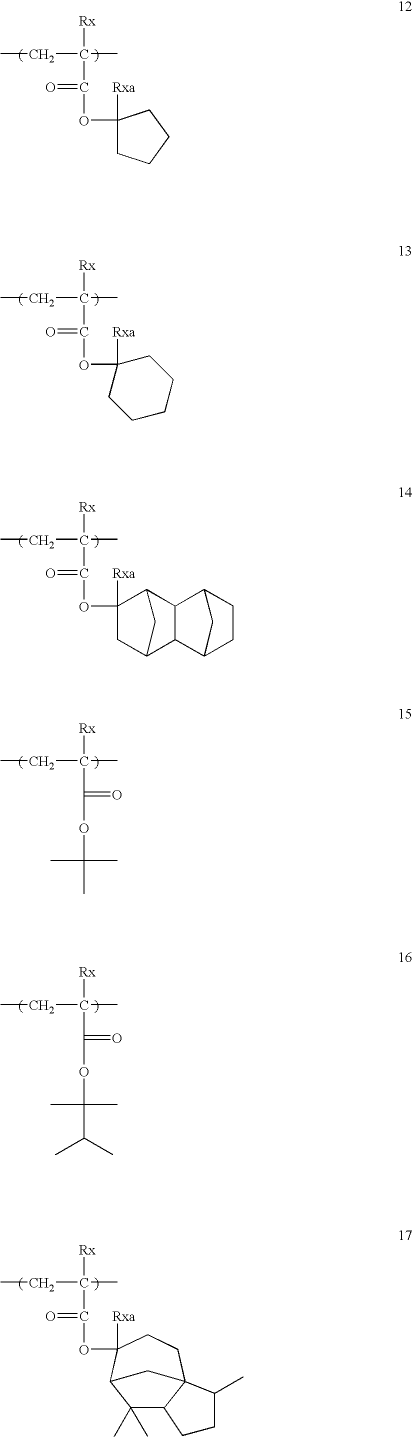

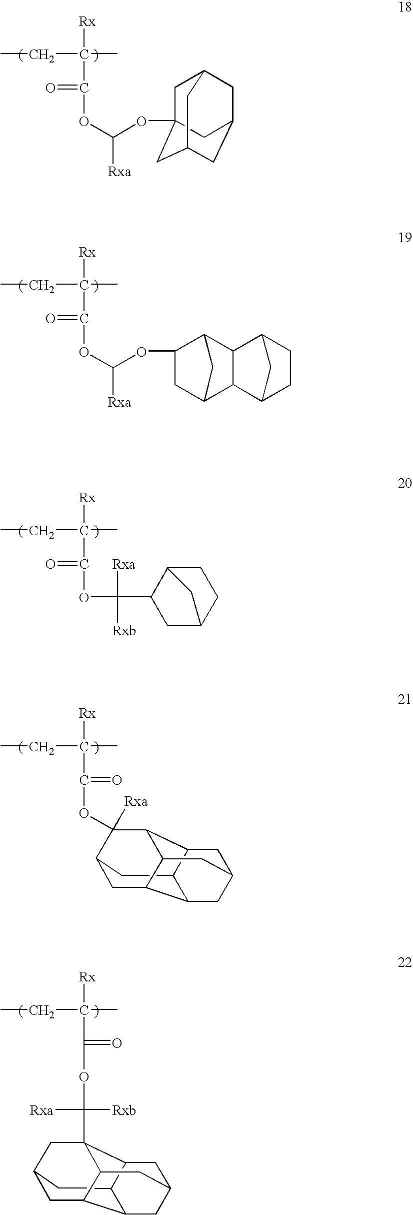

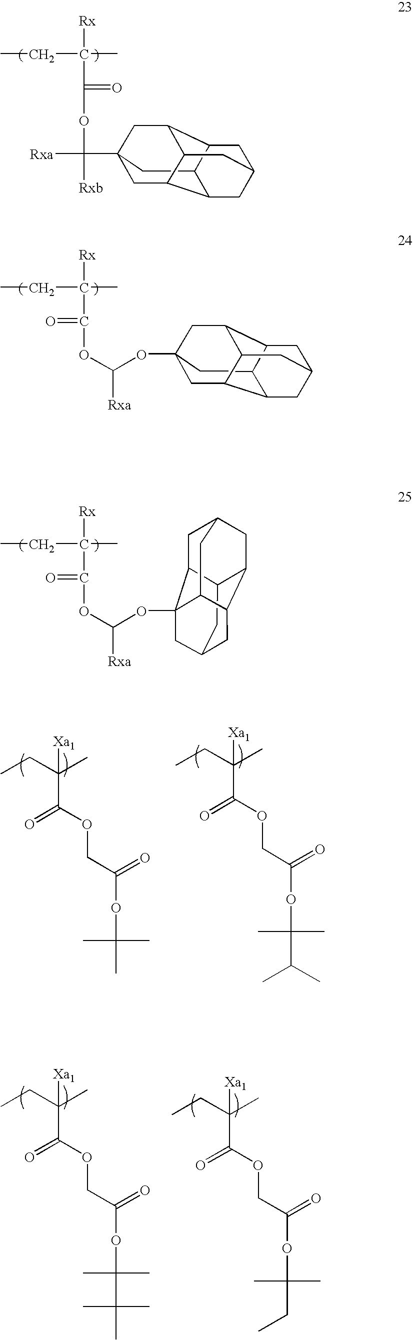

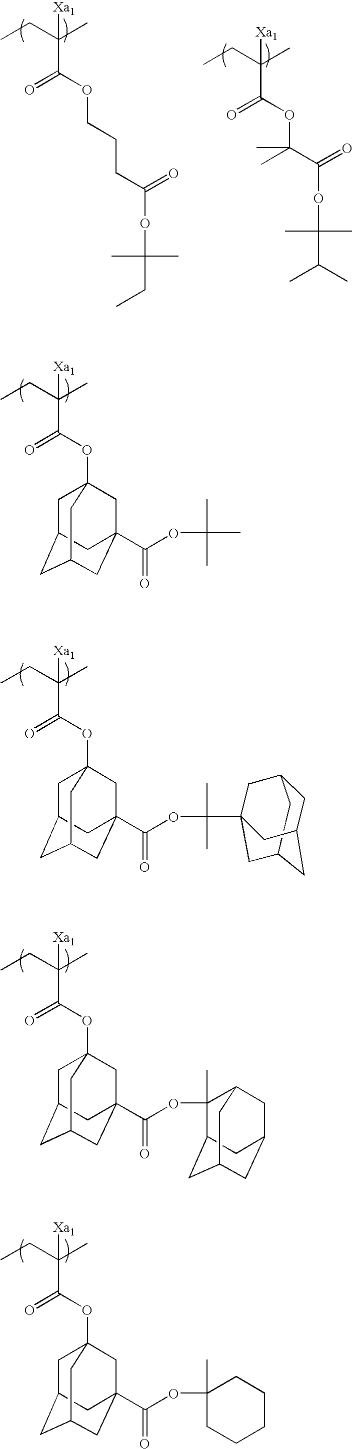

In the above-mentioned formulae, Xa₁ has the same meaning as that of the general formula (AI).

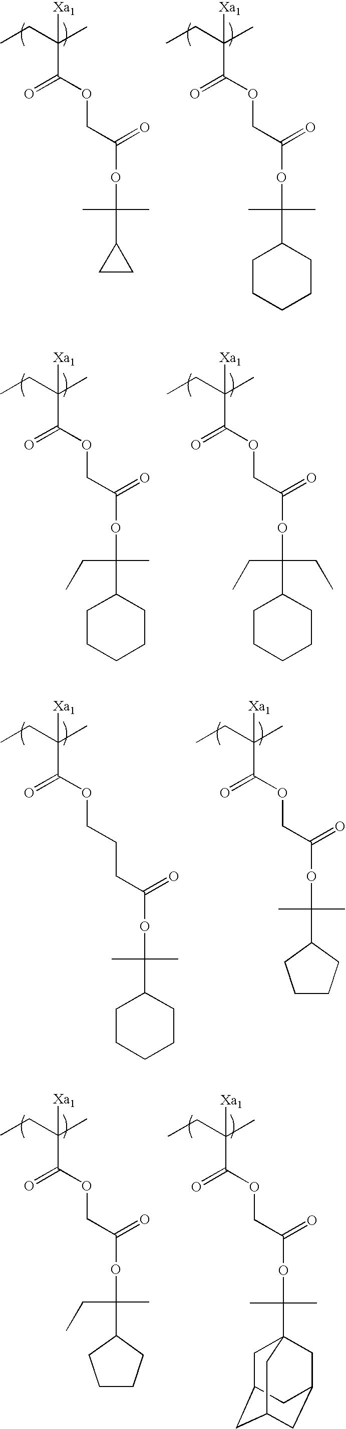

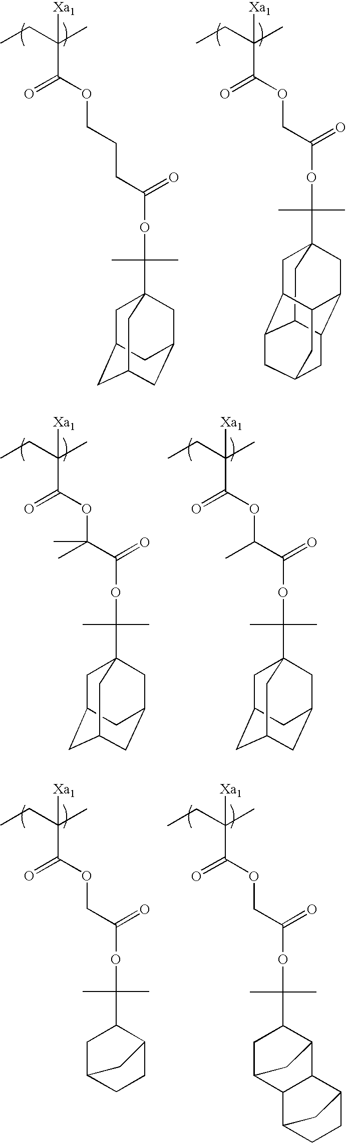

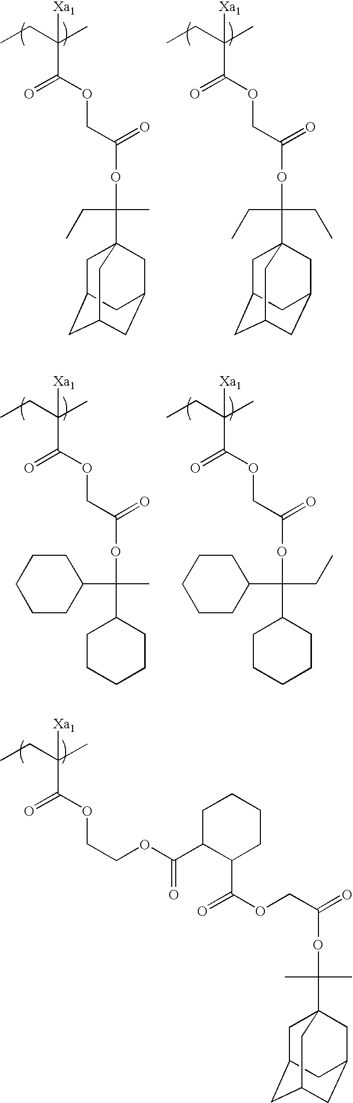

In the above-mentioned formulae, Xa₁ has the same meaning as that of the general formula (AI).

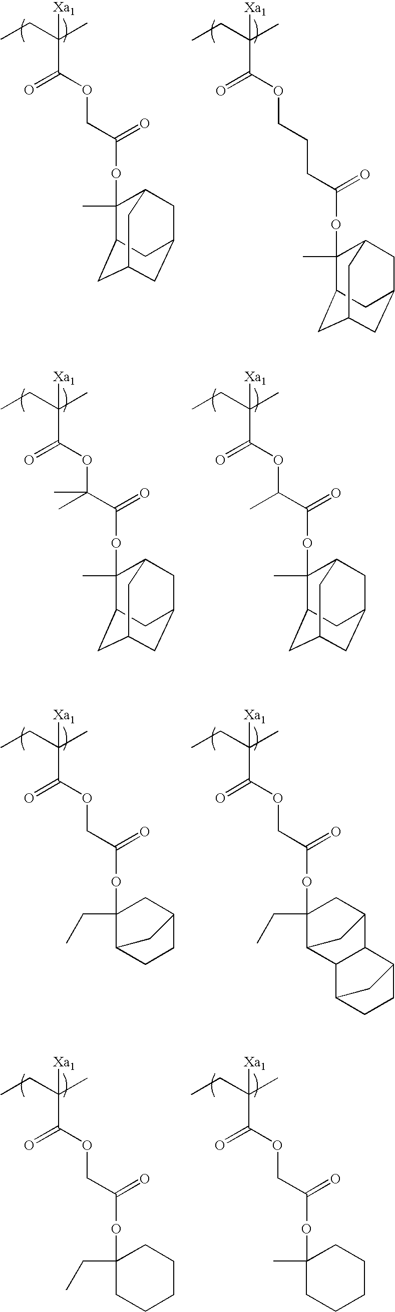

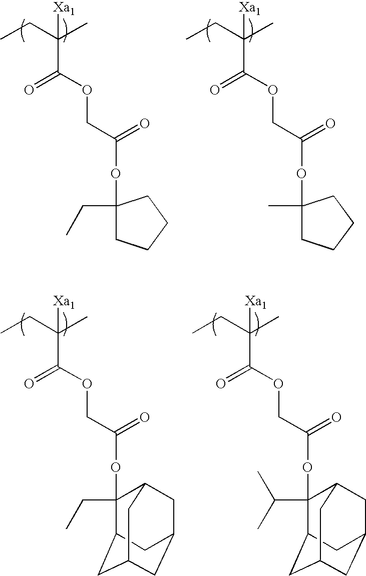

In the above-mentioned formulae, Xa₁ has the same meaning as that of the general formula (AI).

It is preferred for the resin (A) to further have a repeating unit having at least one cyclic group capable of undergoing the reaction with the nucleophilic functional groups. As the cyclic group, there can be mentioned a lactone group, a cyclic acid anhydride group or the like. The cyclic group may be introduced in side chains or the principal chain of the resin.

The repeating unit having a lactone group that may be contained in the resin (A) will now be described.

Any lactone groups can be employed as long as a lactone structure is possessed therein. However, lactone structures of a 5 to 7-membered ring are preferred, and in particular, those resulting from condensation of lactone structures of a 5 to 7-membered ring with other cyclic structures effected in a fashion to form a bicyclo structure or spiro structure are preferred. The possession of repeating units having a lactone structure represented by any of the following general formulae (LC1-1) to (LC1-16) is more preferred. Preferred lactone structures are those of the formulae (LC1-1), (LC1-4), (LC1-5), (LC1-6), (LC1-13) and (LC1-14). The use of these specified lactone structures would ensure improvement in the line edge roughness and development defect, and suppression of the first resist pattern line width change.

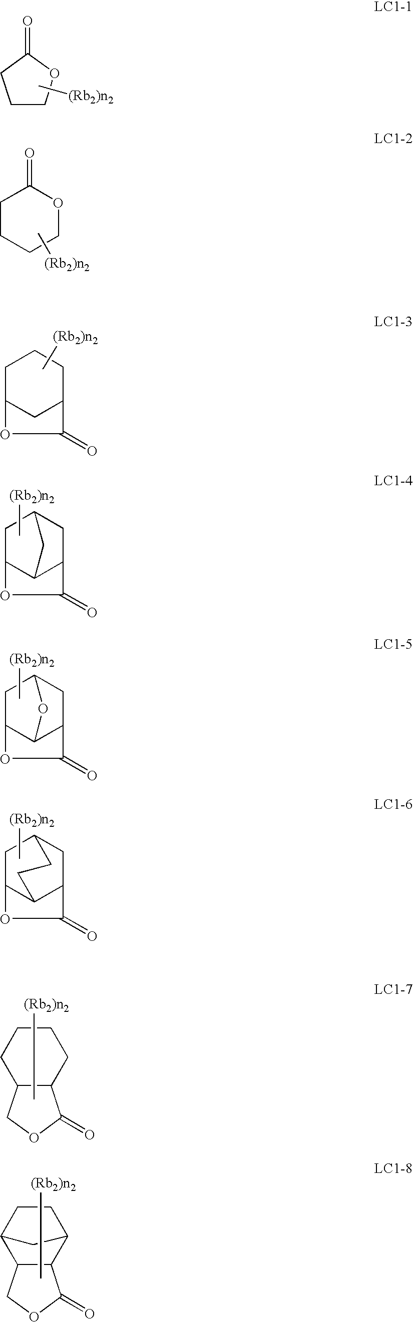

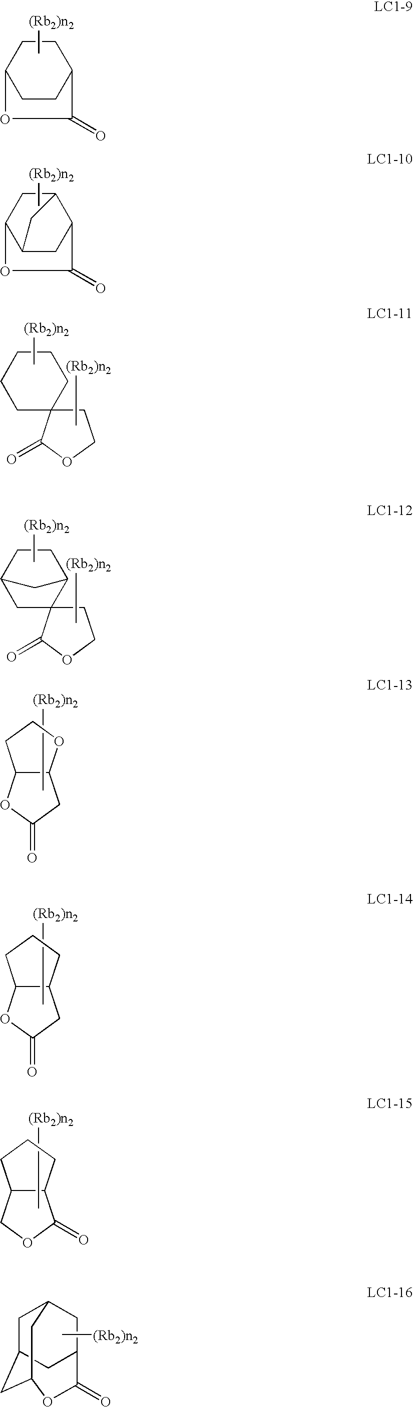

It is optional for the lactone structure portion to have a substituent (Rb₂). However, having an electron withdrawing substituent (Rb₂) is preferred. The electron withdrawing substituent refers to a substituent whose Hammett's substituent constant σp is greater than 0 (σp>0). The substituent constant σp of the electron withdrawing substituent employed in the present invention is preferably in the range of 0.10 to 1.5, more preferably 0.30 to 1.0. Detailed description of the Hammett's substituent constant can be found in C. Hansch, A. Leo. and R. W. Taft, Chemical Review, 1991, Vol. 91, pp. 165-195. The substitution position of the electron withdrawing substituent is preferably the α-position of the carbonyl group of the lactone structure.

In particular, as preferred examples thereof, there can be mentioned an alkoxycarbonyl group having 1 to 8 carbon atoms (alkoxy group optionally substituted), a carboxyl group, a halogen atom, a cyano group and the like. An alkoxycarbonyl group, a carboxyl group, a fluorine atom and a cyano group are more preferred.

Moreover, as preferred examples of the lactone structures, there can be mentioned those of the following formula.

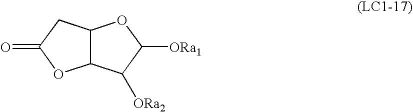

In the formula, each of Ra₁ and Ra₂ independently represents a hydrogen atom, an alkyl group, a cycloalkyl group, an acyl group or an acid-decomposable group. As an example of the acid-decomposable group, generally, there can be mentioned a hydroxyl protective group decomposed by the action of an acid. In this connection, reference can be made to examples given in Protective Groups in organic synthesis, Second edition (written by Theodora W. Greene and Peter G. Wuts), John Wiley & Sons, Inc., New York. As particular examples thereof, there can be mentioned a tetrahydrofiranyl group, a tetrahydrofuranyl group, a methoxyethoxymethyl group, a methoxymethyl group, a t-butyl group and the like. Further, there can be mentioned acid-decomposable groups capable of bonding with a hydroxyl group to thereby form an acetal or a ketal, such as —CH(CH₃)OC₂H₅ and —C(CH₃)₂OC₂H₅.

When Ra₁ and Ra₂ are alkyl groups, they may be bonded to each other to thereby form a ring. As a preferred example thereof, there can be mentioned the lactone structure of the following formula.

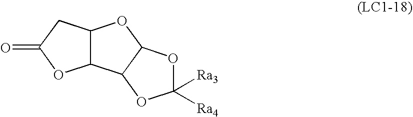

In the formula, each of Ra₃ and Ra₄ independently represents a hydrogen atom, an alkyl group or a cycloalkyl group.

As the repeating units with a lactone structure represented by any of the general formulae (LC1-1) to (LC1-18), there can be mentioned the repeating units represented by the following general formula (AII).

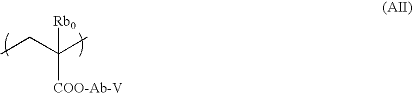

In the general formula (AII),

Rb₀ represents a hydrogen atom, a halogen atom or an alkyl group having 1 to 4 carbon atoms. As a preferred substituent optionally contained in the alkyl group represented by Rb₀, there can be mentioned a hydroxyl group or a halogen atom. As the halogen atom represented by Rb₀, there can be mentioned a fluorine atom, a chlorine atom, a bromine atom or an iodine atom. The Rb₀ is preferably a hydrogen atom and a methyl group.

Ab represents a single bond, an alkylene group, a bivalent connecting group with an alicyclic hydrocarbon structure of a single ring or multiple rings, an ether group, an ester group, a carbonyl group, or a bivalent connecting group resulting from combination thereof. A single bond and a bivalent connecting group of the formula -Ab₁-CO₂— are preferred. Ab₁ is a linear or branched alkylene group or a cycloalkylene group of a single ring or multiple rings, being preferably a methylene group, an ethylene group, a cyclohexylene group, an adamantylene group or a norbornylene group.

V represents a group with a structure represented by any of the general formulae (LC1-1) to (LC1-18).

The repeating unit having a lactone group is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity (ee) thereof is preferably 90 or higher, more preferably 95 or higher.

The content of the repeating unit having a lactone group based on all the repeating units of the resin (A) is preferably in the range of 15 to 60 mol %, more preferably 20 to 50 mol % and still more preferably 30 to 50 mol %.

Examples of the repeating units having a lactone group will now be shown, which however in no way limit the scope of the present invention.

In the formulae, Rx represents H, CH₃, CH₂OH or CF₃.

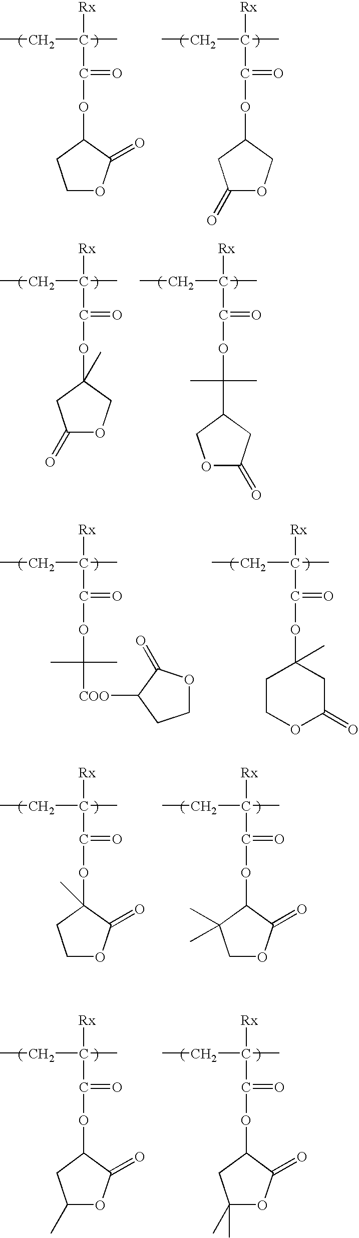

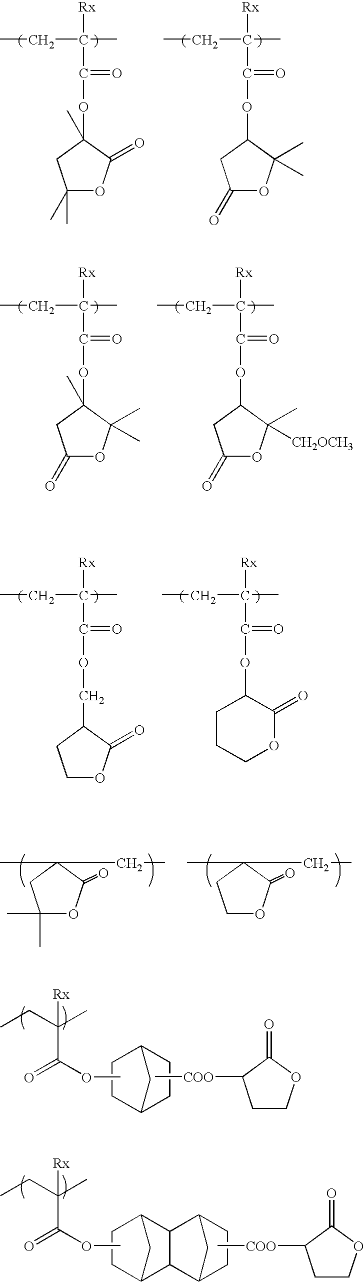

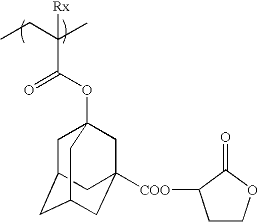

In the formulae, Rx represents H, CH₃, CH₂OH or CF₃.

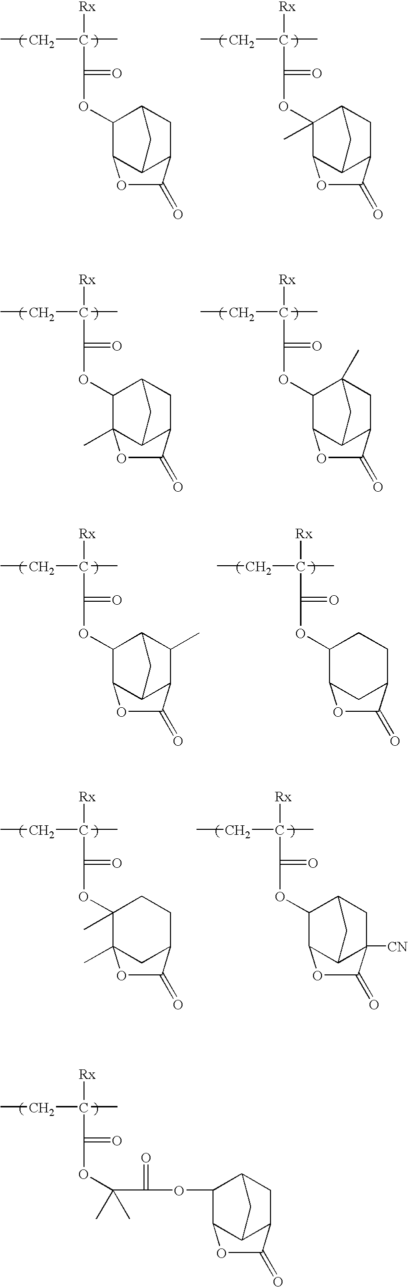

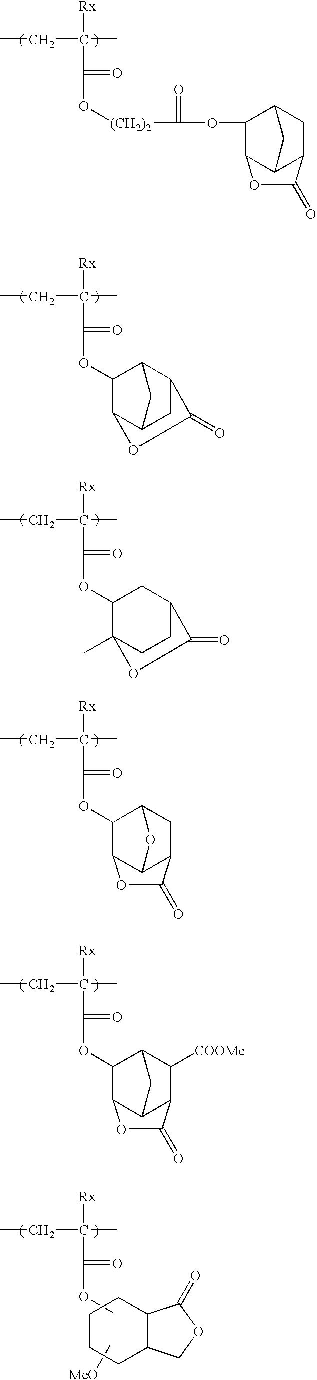

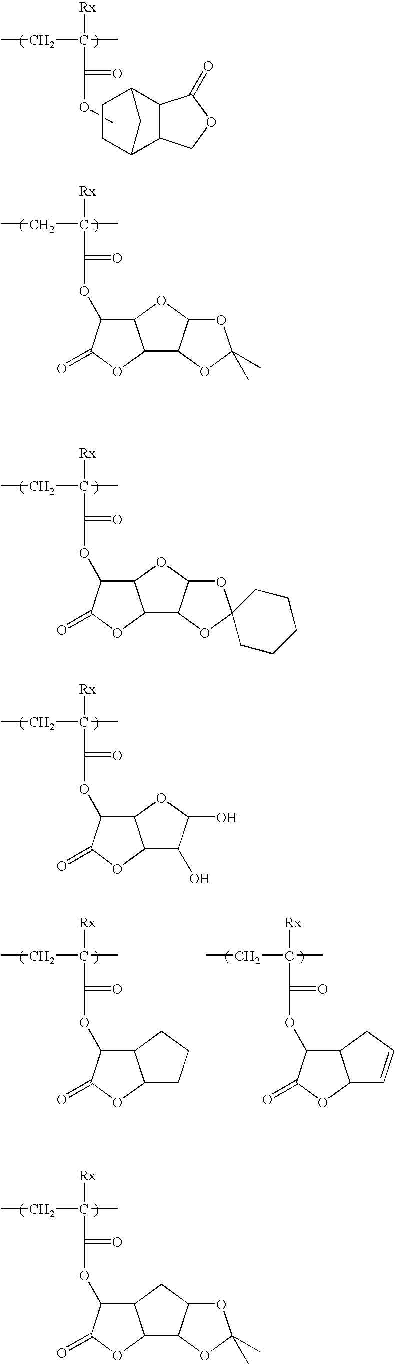

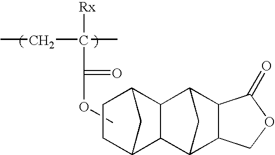

In the formulae, Rx represents H, CH₃, CH₂OH or CF₃.

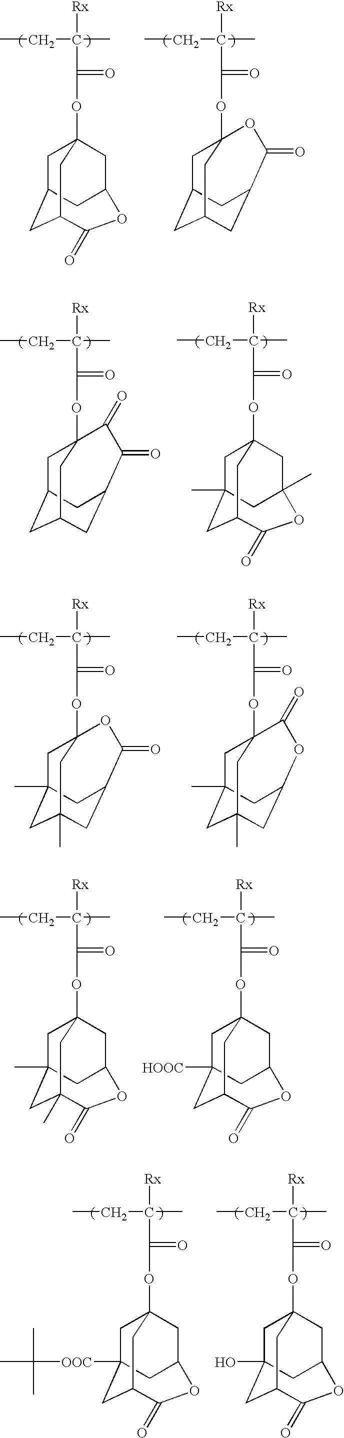

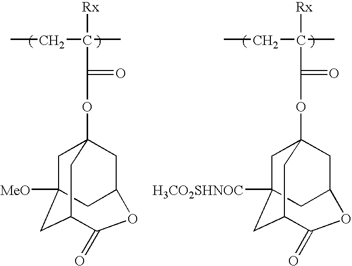

Repeating units having especially preferred lactone groups will be shown below. Not only an improvement in pattern profile and optical density dependence but also suppression of resist pattern line width changes and LWR changes can be attained by selection of the most appropriate lactone group.

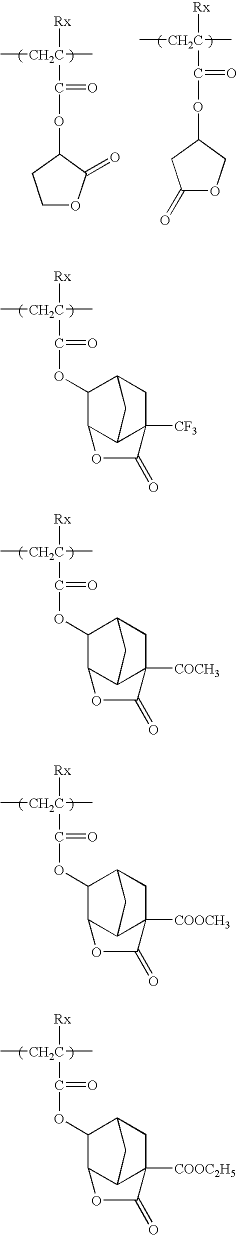

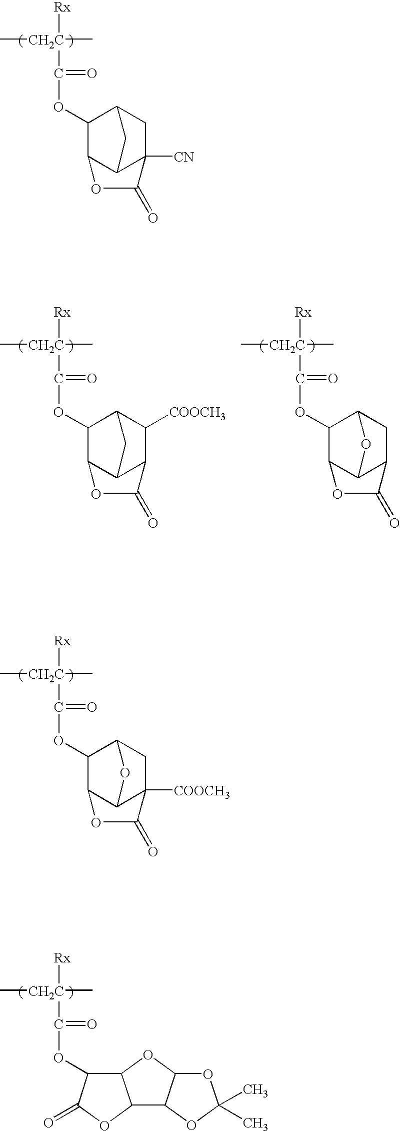

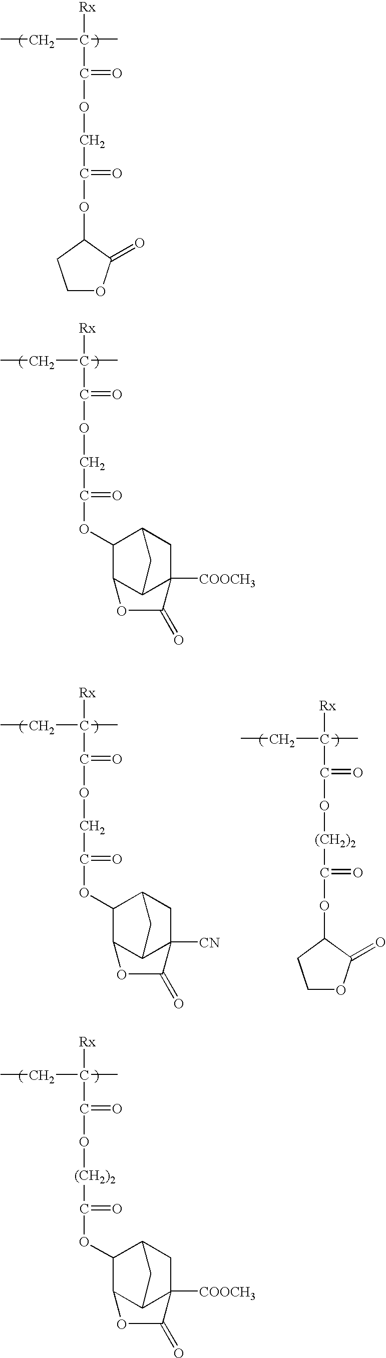

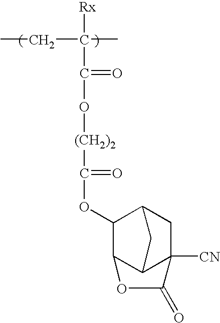

The repeating units having cyclic acid anhydride groups that can be preferably introduced in the resin (A) will be described below.

The cyclic acid anhydride groups may be introduced in side chains or the principal chain of the resin. The cyclic acid anhydride groups are preferably those of the following formula.

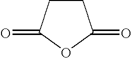

Repeating units having especially preferred cyclic acid anhydride groups are those shown below.

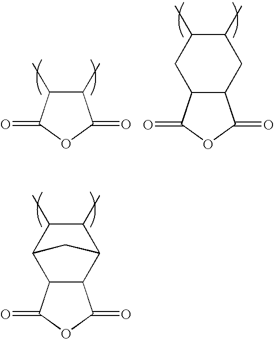

Not only an improvement in pattern profile and optical density dependence but also suppression of any line width changes of the first resist pattern can be attained by selection of the most appropriate cyclic acid anhydride group.

When the cyclic group is a lactone group, the content of repeating units having the cyclic group, based on all the repeating units of the resin (A), is preferably in the range of 1 to 70 mol %, more preferably 10 to 60 mol % and further preferably 20 to 50 mol %. When the cyclic group is an acid anhydride group, the content thereof based on all the repeating units of the resin (A) is preferably in the range of 1 to 50 mol %, more preferably 3 to 30 mol % and further preferably 5 to 20 mol %.

Preferably, the resin (A) contains a repeating unit having at least one group selected from among a hydroxyl group, a cyano group and an alkali soluble group.

The repeating unit having a hydroxyl group or a cyano group that may be contained in the resin (A) will now be described.

The containment of this repeating unit would realize enhancements of adhesion to substrate and developer affinity. The repeating unit having a hydroxyl group or a cyano group is preferably a repeating unit having an alicyclic hydrocarbon structure substituted with a hydroxyl group or a cyano group. In the alicyclic hydrocarbon structure substituted with a hydroxyl group or a cyano group, the alicyclic hydrocarbon structure preferably consists of an adamantyl group, a diamantyl group or a norbornane group. As preferred alicyclic hydrocarbon structures substituted with a hydroxyl group or a cyano group, there can be mentioned the partial structures of the following general formulae (VIIa) to (VIId).

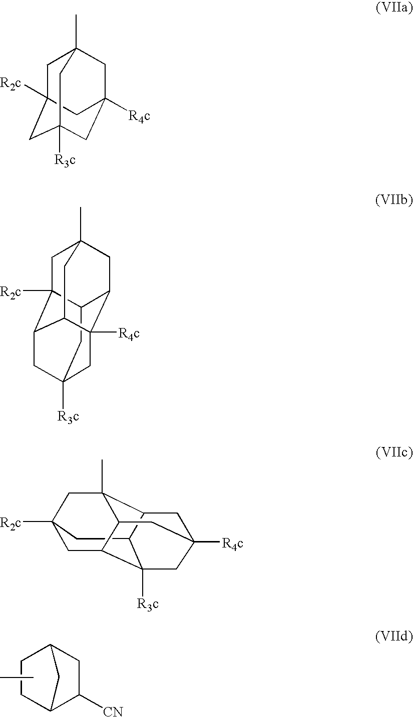

In the general formulae (VIIa) to (VIIc), each of R₂c to R₄c independently represents a hydrogen atom, a hydroxyl group or a cyano group, providing that at least one of the R₂c to R₄c represents a hydroxyl group or a cyano group. Preferably, one or two of the R₂c to R₄c are hydroxyl groups and the remainder is a hydrogen atom. In the general formula (VIIa), more preferably, two of the R₂c to R₄c are hydroxyl groups and the remainder is a hydrogen atom.

As the repeating units having any of the partial structures of the general formulae (VIIA) to (VIId), there can be mentioned those of the following general formulae (AIIa) to (AIId).

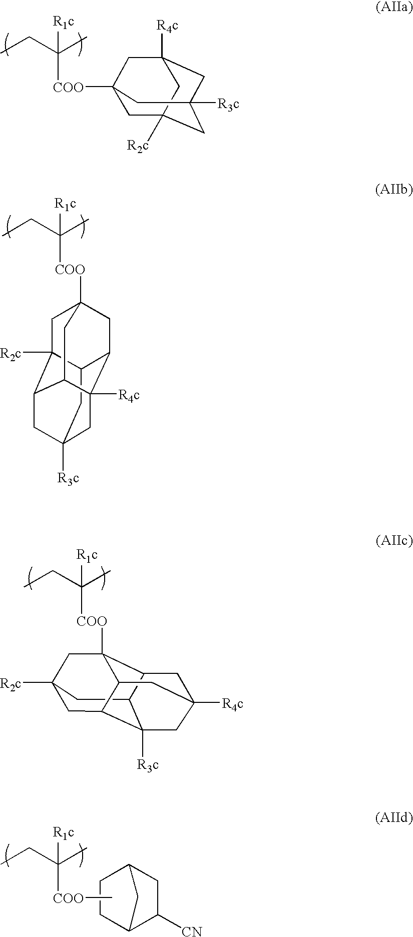

In the general formulae (AIIa) to (AIId),

R₁c represents a hydrogen atom, a methyl group, a trifluoromethyl group or a hydroxymethyl group.

R₂c to R₄c have the same meaning as those of the general formulae (VIIa) to (VIIc).

The content of the repeating unit having an alicyclic hydrocarbon structure substituted with a hydroxyl group or a cyano group, based on all the repeating units of the resin (A), is preferably in the range of 5 to 40 mol %, more preferably 5 to 30 mol % and still more preferably 10 to 25 mol %.

Specific examples of the repeating units having a hydroxyl group or a cyano group will be shown below, which however in no way limit the scope of the present invention.

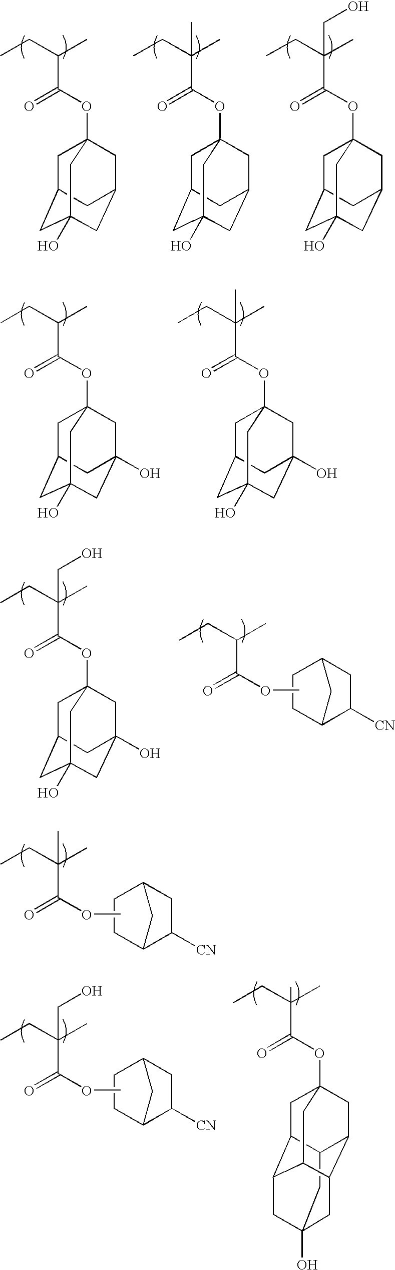

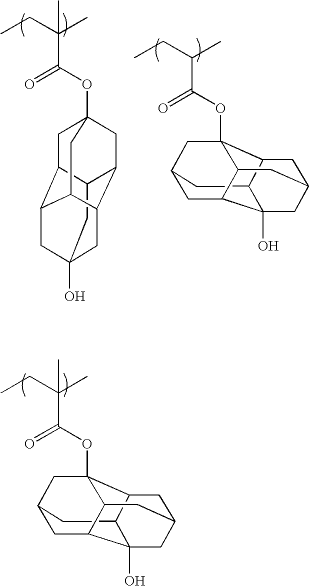

A repeating unit having an alkali soluble group that may preferably be contained in resin (A) will be described below. As the alkali-soluble group, there can be mentioned a carboxyl group, a sulfonamido group, a sulfonylimido group, a bisulfonylimido group or an aliphatic alcohol substituted at its α-position with an electron-withdrawing group (for example, a hexafluoroisopropanol group). The possession of a repeating unit having a carboxyl group is more preferred. The incorporation of the repeating unit having an alkali-soluble group would increase the resolving power in contact hole usage. The repeating unit having an alkali-soluble group is preferably any of a repeating unit wherein the alkali-soluble group is directly bonded to the principal chain of a resin such as a repeating unit of acrylic acid or methacrylic acid, a repeating unit wherein the alkali-soluble group is bonded via a connecting group to the principal chain of a resin and a repeating unit wherein the alkali-soluble group is introduced in a terminal of a polymer chain by the use of a chain transfer agent or polymerization initiator having the alkali-soluble group in the stage of polymerization. The connecting group may have a cyclohydrocarbon structure of a single ring or multiple rings. The repeating unit of acrylic acid or methacrylic acid is especially preferred.

The content of the repeating unit having an alkali-soluble group based on all the repeating units of the resin (A) is preferably in the range of 0 to 25 mol %, more preferably 3 to 20 mol % and still more preferably 5 to 15 mol %.

Specific examples of the repeating units having an alkali-soluble group will be shown below, which however in no way limit the scope of the present invention.

In the formulae, Rx represents H, CH₃, CF₃, or CH₂OH.

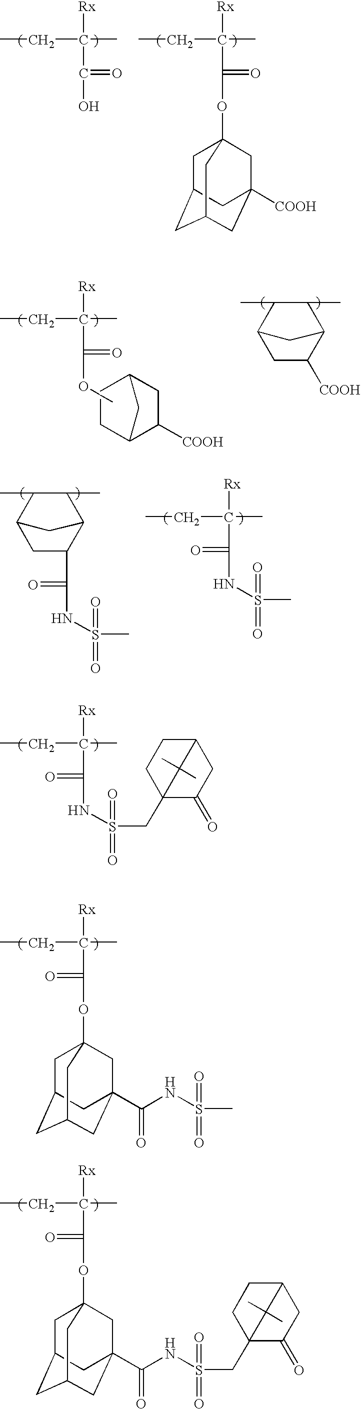

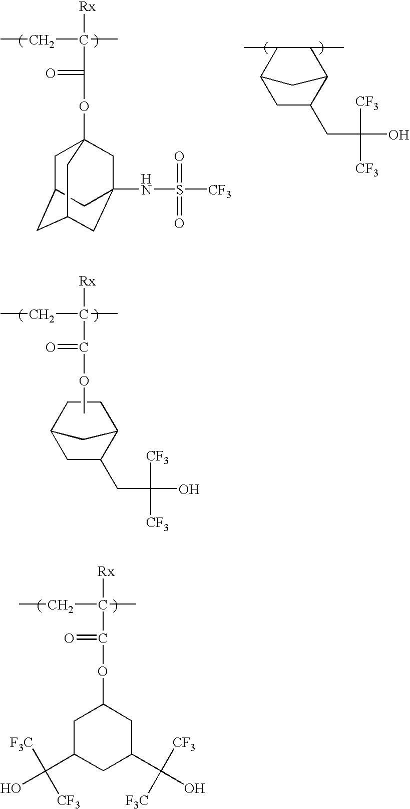

Still further, the resin (A) may have a repeating unit with an alicyclic hydrocarbon structure that does not exhibit any acid decomposability. This would reduce any leaching of low-molecular components from a resist film into a liquid for liquid immersion at the time of liquid immersion exposure, being also advantageous from the viewpoint of dry etching resistance. As specific examples thereof, there can be mentioned the repeating units of general formula (III) below.

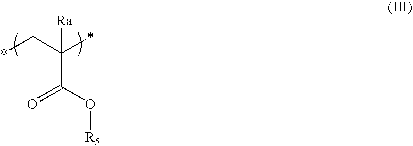

In the general formula (III), R₅ represents a hydrocarbon group having at least one cyclic structure in which neither a hydroxyl group nor a cyano group is contained.

Ra represents a hydrogen atom, an alkyl group or a group of the formula —CH₂—O—Ra₂ in which Ra₂ represents a hydrogen atom, an alkyl group or an acyl group.

The cyclic structures contained in R₅ include a monocyclic hydrocarbon group and a polycyclic hydrocarbon group. As the monocyclic hydrocarbon group, there can be mentioned, for example, a cycloalkyl group having 3 to 12 carbon atoms, such as a cyclopentyl group, a cyclohexyl group, a cycloheptyl group or a cyclooctyl group, or a cycloalkenyl group having 3 to 12 carbon atoms, such as a cyclohexenyl group. Preferably, the monocyclic hydrocarbon group is a monocyclic hydrocarbon group having 3 to 7 carbon atoms. A cyclopentyl group and a cyclohexyl group are more preferred.

The polycyclic hydrocarbon groups include ring-assembly hydrocarbon groups and crosslinked-ring hydrocarbon groups. Examples of the ring-assembly hydrocarbon groups include a bicyclohexyl group, a perhydronaphthalene group and the like. As the crosslinked-ring hydrocarbon rings, there can be mentioned, for example, bicyclic hydrocarbon rings, such as pinane, bornane, norpinane, norbornane and bicyclooctane rings (e.g., bicyclo[2.2.2]octane ring or bicyclo[3.2.1]octane ring); tricyclic hydrocarbon rings, such as homobledane, adamantane, tricyclo[5.2.1.0^{2,6}]decane and tricyclo[4.3.1.1^{2,5}]undecane rings; and tetracyclic hydrocarbon rings, such as tetracyclo[4.4.0.1^{2,5}.1^{7,10}]dodecane and perhydro-1,4-methano-5,8-methanonaphthalene rings. Further, the crosslinked-ring hydrocarbon rings include condensed-ring hydrocarbon rings, for example, condensed rings resulting from condensation of multiple 5- to 8-membered cycloalkane rings, such as perhydronaphthalene (decalin), perhydroanthracene, perhydrophenanthrene, perhydroacenaphthene, perhydrofluorene, perhydroindene and perhydrophenarene rings.

As preferred crosslinked-ring hydrocarbon rings, there can be mentioned, for example, a norbornyl group, an adamantyl group, a bicyclooctanyl group and a tricyclo[5,2,1,0^{2,6}]decanyl group. As more preferred crosslinked-ring hydrocarbon rings, there can be mentioned a norbornyl group and an adamantyl group.

These alicyclic hydrocarbon groups may have substituents. As preferred substituents, there can be mentioned, for example, a halogen atom, an alkyl group, a hydroxyl group protected by a protective group and an amino group protected by a protective group. The halogen atom is preferably a bromine, chlorine or fluorine atom, and the alkyl group is preferably a methyl, ethyl, butyl or t-butyl group. The alkyl group may further have a substituent. As the optional further substituent, there can be mentioned a halogen atom, an alkyl group, a hydroxyl group protected by a protective group or an amino group protected by a protective group.

As the protective group, there can be mentioned, for example, an alkyl group, a cycloalkyl group, an aralkyl group, a substituted methyl group, a substituted ethyl group, an alkoxycarbonyl group or an aralkyloxycarbonyl group. The alkyl group is preferably an alkyl group having 1 to 4 carbon atoms. The substituted methyl group is preferably a methoxymethyl, methoxythiomethyl, benzyloxymethyl, t-butoxymethyl or 2-methoxyethoxymethyl group. The substituted ethyl group is preferably a 1-ethoxyethyl or 1-methyl-l-methoxyethyl group. The acyl group is preferably an aliphatic acyl group having 1 to 6 carbon atoms, such as a formyl, acetyl, propionyl, butyryl, isobutyryl, valeryl or pivaloyl group. The alkoxycarbonyl group is, for example, an alkoxycarbonyl group having 1 to 4 carbon atoms.

The content of any of the repeating units of the general formula (III) having neither a hydroxyl group nor a cyano group, based on all the repeating units of the resin (A), is preferably in the range of 0 to 40 mol %, more preferably 0 to 20 mol %.

Specific examples of the repeating units of the general formula (III) will be shown below, which however in no way limit the scope of the present invention.

In the formulae, Ra represents H, CH₃, CH₂OH, or CF₃.

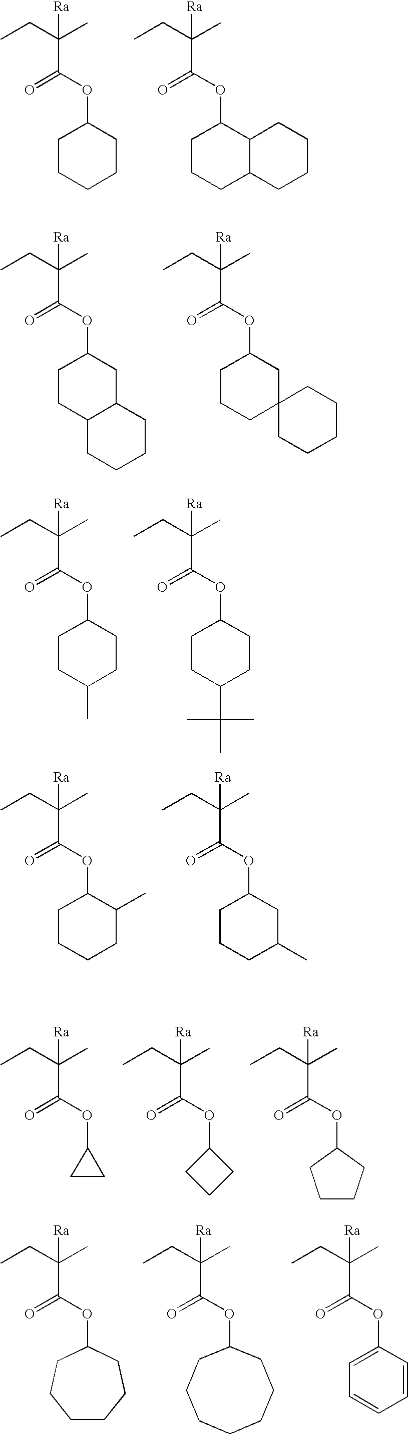

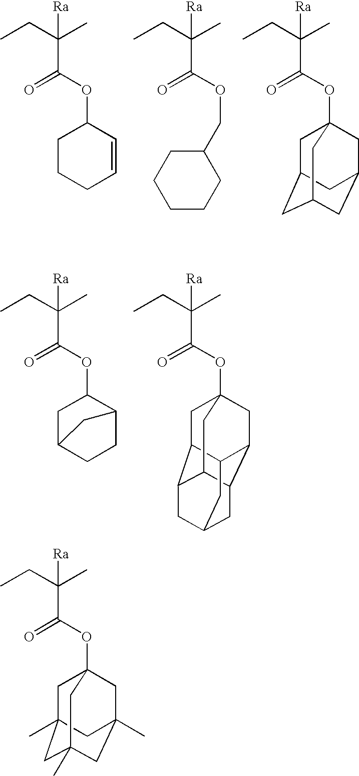

The resin (A) may have, in addition to the foregoing repeating structural units, various repeating structural units for the purpose of regulating the dry etching resistance, standard developer adaptability, substrate adhesion, resist profile and generally required properties of the resist such as resolving power, heat resistance and sensitivity.

As such repeating structural units, there can be mentioned those corresponding to the following monomers, which however are nonlimiting.

The use of such repeating structural units would enable fine regulation of the required properties of the resin (A), especially:

(1) solubility in applied solvents,

(2) film forming easiness (glass transition point),

(3) alkali developability,

(4) film thinning (selections of hydrophilicity/hydrophobicity and alkali-soluble group),

(5) adhesion of unexposed area to substrate,

(6) dry etching resistance, etc.

As appropriate monomers, there can be mentioned, for example, a compound having an unsaturated bond capable of addition polymerization, selected from among acrylic esters, methacrylic esters, acrylamides, methacrylamides, allyl compounds, vinyl ethers, vinyl esters and the like.

In addition, any unsaturated compound capable of addition polymerization that is copolymerizable with monomers corresponding to the above various repeating structural units may be copolymerized therewith.

The molar ratios of individual repeating structural units contained in the resin (A) are appropriately determined from the viewpoint of regulation of not only the dry etching resistance of the resist but also the standard developer adaptability, substrate adhesion, resist profile and generally required properties of the resist such as the resolving power, heat resistance and sensitivity.

When the positive resist composition of the present invention is one for ArF exposure, it is preferred for the resin as the component (A) to have no aromatic group from the viewpoint of transparency to ArF beams.

In the resin (A), preferably, all the repeating units consist of (meth)acrylate repeating units. In that instance, use can be made of any of a resin wherein all the repeating units consist of methacrylate repeating units, a resin wherein all the repeating units consist of acrylate repeating units and a resin wherein all the repeating units consist of methacrylate repeating units and acrylate repeating units. However, it is preferred for the acrylate repeating units to account for 50 mol % or less of all the repeating units. It is more preferred to employ a copolymer containing 20 to 50 mol % of (meth)acrylate repeating units having an acid-decomposable group according to the general formula (AI), 20 to 50 mol % of (meth)acrylate repeating units having a lactone group, 5 to 30 mol % of (meth)acrylate repeating units having an alicyclic hydrocarbon structure substituted with a hydroxyl group or a cyano group and 0 to 20 mol % of other (meth)acrylate repeating units.

In the event of exposure of the positive resist composition of the present invention to KrF excimer laser beams, electron beams, X-rays or high-energy light rays of 50 nm or less wavelength (EUV, etc.), it is preferred for the resin (A) to have not only the repeating units of the general formula (AI) but also hydroxystyrene repeating units. More preferably, the resin (A) has hydroxystyrene repeating units, hydroxystyrene repeating units protected by an acid-decomposable group and acid-decomposable repeating units of a (meth)acrylic acid tertiary alkyl ester, etc.

As preferred repeating units having an acid-decomposable group, there can be mentioned, for example, repeating units derived from t-butoxycarbonyloxystyrene, a 1-alkoxyethoxystyrene and a (meth)acrylic acid tertiary alkyl ester. Repeating units derived from a 2-alkyl-2-adamantyl(meth)acrylate and a dialkyl(1-adamantyl)methyl (meth)acrylate are more preferred.

The resin (A) can be synthesized by conventional techniques (for example, radical polymerization). As general synthetic methods, there can be mentioned, for example, a batch polymerization method in which a monomer species and an initiator are dissolved in a solvent and heated so as to accomplish polymerization and a dropping polymerization method in which a solution of monomer species and initiator is added by dropping to a heated solvent over a period of 1 to 10 hours. The dropping polymerization method is preferred. As a reaction solvent, there can be mentioned, for example, an ether, such as tetrahydrofuran, 1,4-dioxane or diisopropyl ether; a ketone, such as methyl ethyl ketone or methyl isobutyl ketone; an ester solvent, such as ethyl acetate; an amide solvent, such as dimethylformamide or dimethylacetamide; or the latter described solvent capable of dissolving the composition of the present invention, such as propylene glycol monomethyl ether acetate, propylene glycol monomethyl ether or cyclohexanone. It is preferred to perform the polymerization with the use of the same solvent as employed in the photosensitive composition of the present invention. This would inhibit any particle generation during storage.

The polymerization reaction is preferably carried out in an atmosphere of inert gas, such as nitrogen or argon. The polymerization is initiated by the use of a commercially available radical initiator (azo initiator, peroxide, etc.) as a polymerization initiator. Among the radical initiators, an azo initiator is preferred. An azo initiator having an ester group, a cyano group or a carboxyl group is especially preferred. As preferred initiators, there can be mentioned azobisisobutyronitrile, azobisdimethylvaleronitrile, dimethyl 2,2′-azobis(2-methylpropionate) and the like. According to necessity, a supplementation of initiator or divided addition thereof may be effected. After the completion of the reaction, the reaction mixture is poured into a solvent. The desired polymer is recovered by a method for powder or solid recovery, etc. The concentration during the reaction is in the range of 5 to 50 mass %, preferably 10 to 30 mass %. The reaction temperature is generally in the range of 10° to 150° C., preferably 30° to 120° C. and more preferably 60° to 100° C.

After the completion of the reaction, the mixture is allowed to stand still to cool to room temperature and purified. In the purification, use is made of customary methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to thereby coagulate the resin in the poor solvent and thus remove residual monomers, etc., and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to thereby precipitate the resin as a solid.

The solvent for use in the operation of precipitation or re-precipitation from a polymer solution (precipitation or re-precipitation solvent) is not limited as long as the solvent is a poor solvent for the polymer. Use can be made of any solvent appropriately selected from among a hydrocarbon, a halogenated hydrocarbon, a nitro compound, an ether, a ketone, an ester, a carbonate, an alcohol, a carboxylic acid, water, a mixed solvent containing these solvents and the like, according to the type of polymer. Of these, it is preferred to employ a solvent containing at least an alcohol (especially methanol or the like) or water as the precipitation or re-precipitation solvent.

The amount of precipitation or re-precipitation solvent used can be appropriately selected taking efficiency, yield, etc. into account, and is generally in the range of 100 to 10,000 parts by mass, preferably 200 to 2000 parts by mass and more preferably 300 to 1000 parts by mass per 100 parts by mass of the polymer solution.

The temperature at which the precipitation or re-precipitation is carried out can be appropriately selected taking efficiency and operation easiness into account, and is generally in the range of about 0° to 50° C., preferably about room temperature (for example, about 20° to 35° C.). The operation of precipitation or re-precipitation can be carried out by a publicly known method, such as a batch or continuous method, with the use of a customary mixing vessel, such as an agitation vessel.

The polymer obtained by precipitation or re-precipitation is generally subjected to customary solid/liquid separation, such as filtration or centrifugal separation, and dried before use. The filtration is carried out with the use of a filter medium ensuring solvent resistance, preferably under pressure. The drying is performed at about 30° to 100° C., preferably about 30° to 50° C. at ordinary pressure or reduced pressure (preferably reduced pressure).

Alternatively, after the resin precipitation and separation once, the resin may be once more dissolved in a solvent and brought into contact with a solvent in which the resin is poorly soluble or insoluble. Specifically, the method may include the steps of, after the completion of the polymerization reaction, bringing the polymer into contact with a solvent wherein the polymer is poorly soluble or insoluble to thereby attain resin precipitation (step a), separating the resin from the solution (step b), re-dissolving the resin in a solvent to thereby obtain a resin solution (A) (step c), thereafter bringing the resin solution (A) into contact with a solvent wherein the resin is poorly soluble or insoluble amounting to less than 10 times (preferably 5 times or less) the volume of the resin solution (A) to thereby attain resin solid precipitation (step d) and separating the precipitated resin (step e).

The weight average molecular weight of the resin (A) in terms of polystyrene molecular weight as measured by GPC is preferably in the range of 1000 to 200,000, more preferably 2000 to 20,000, still more preferably 3000 to 15,000 and further preferably 3000 to 10,000. The regulation of the weight average molecular weight to 1000 to 200,000 would prevent deteriorations of heat resistance and dry etching resistance and also prevent deterioration of developability and increase of viscosity leading to poor film forming property.

Use is made of the resin whose degree of dispersal (molecular weight distribution) is generally in the range of 1 to 3, preferably 1 to 2.6, more preferably 1 to 2 and most preferably 1.4 to 1.7. The lower the molecular weight distribution, the more excellent the resolving power and resist profile and the smoother the side wall of the resist pattern to thereby attain an excellence in roughness.

The content of the resin (A) in the positive resist composition of the present invention based on the total solids thereof is preferably in the range of 50 to 99.9 mass %, more preferably 60 to 99.0 mass %.

In the present invention, use may be made of either solely one or two or more of the resins as the resin(A).

Specific examples of the polymer that may be used in the present invention will be shown below, which however in no way limit the scope of the present invention.

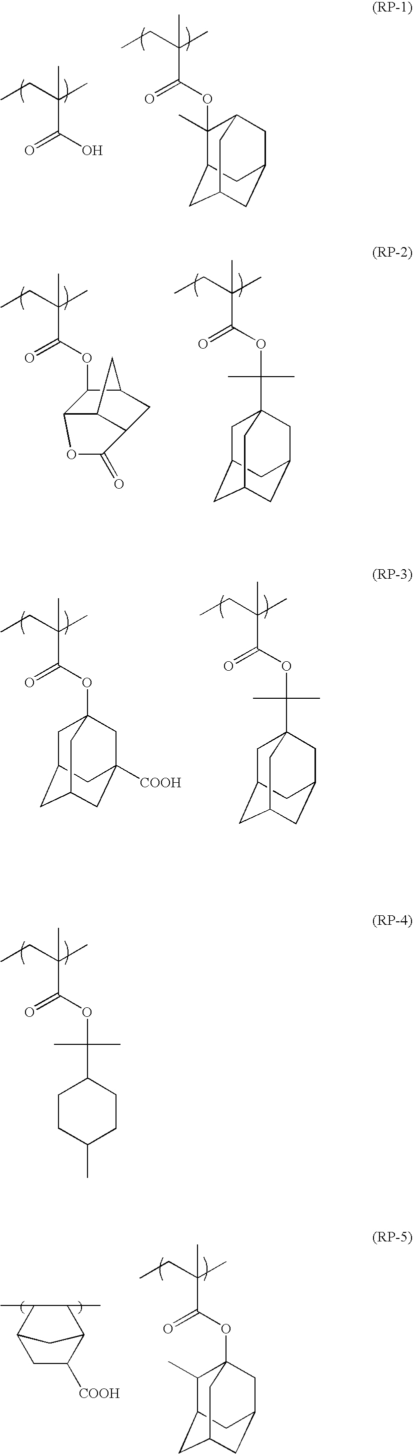

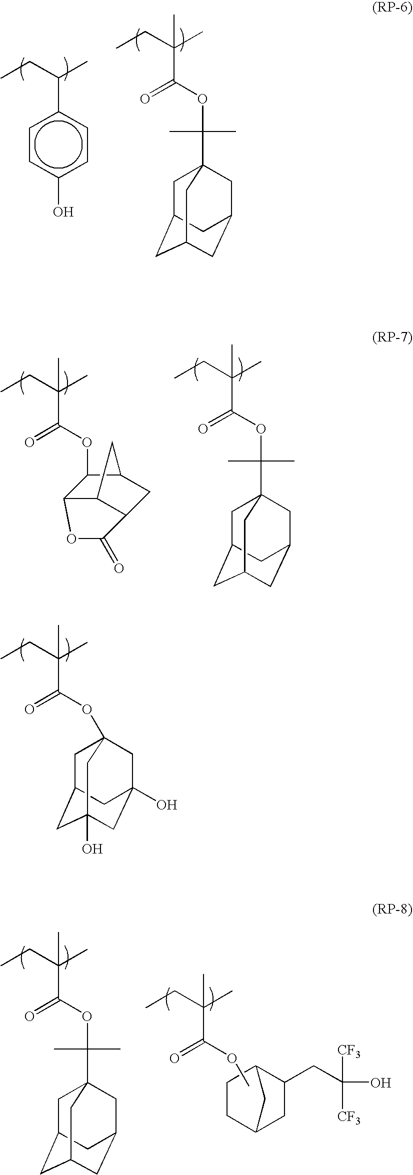

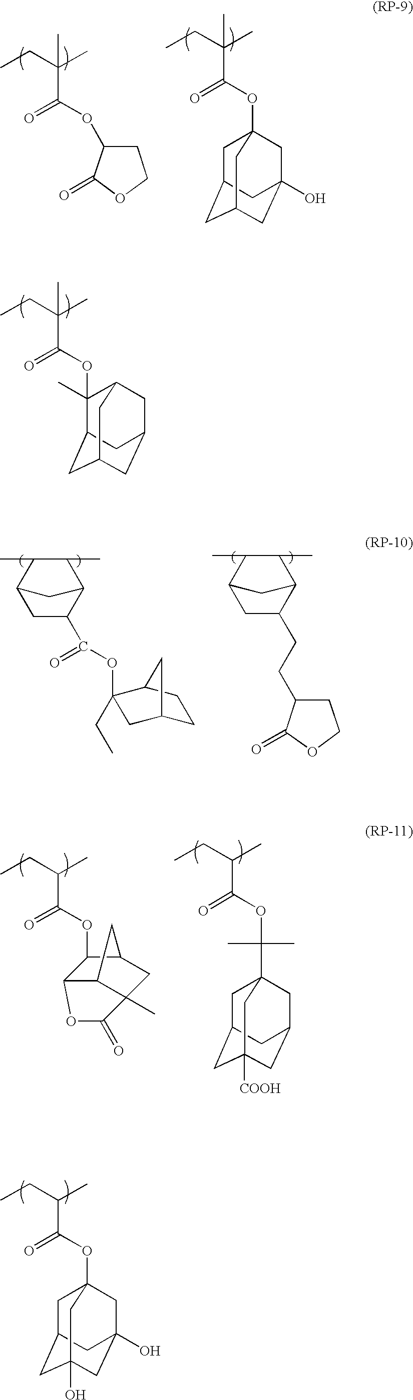

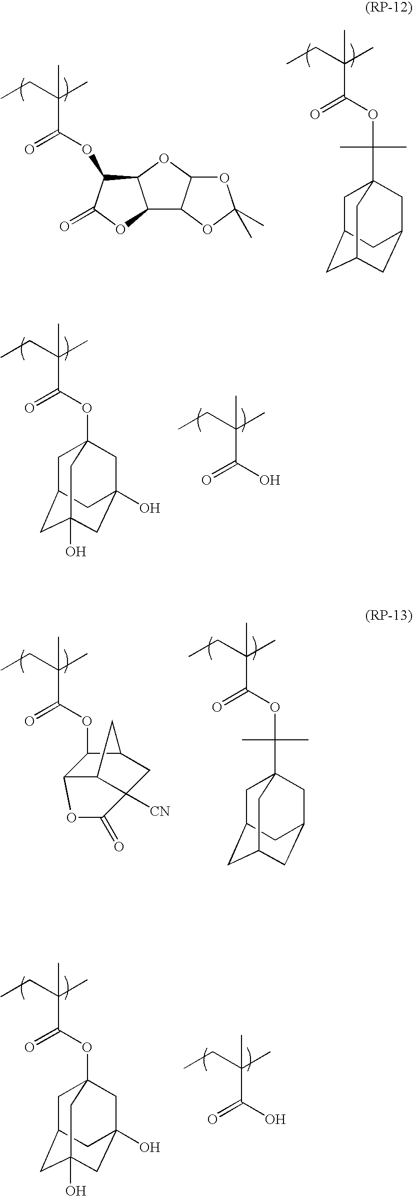

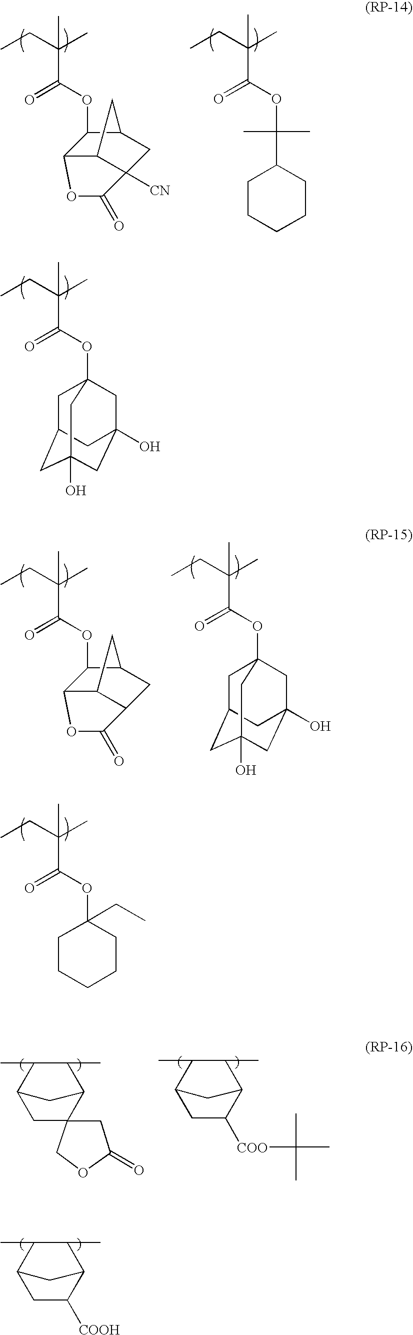

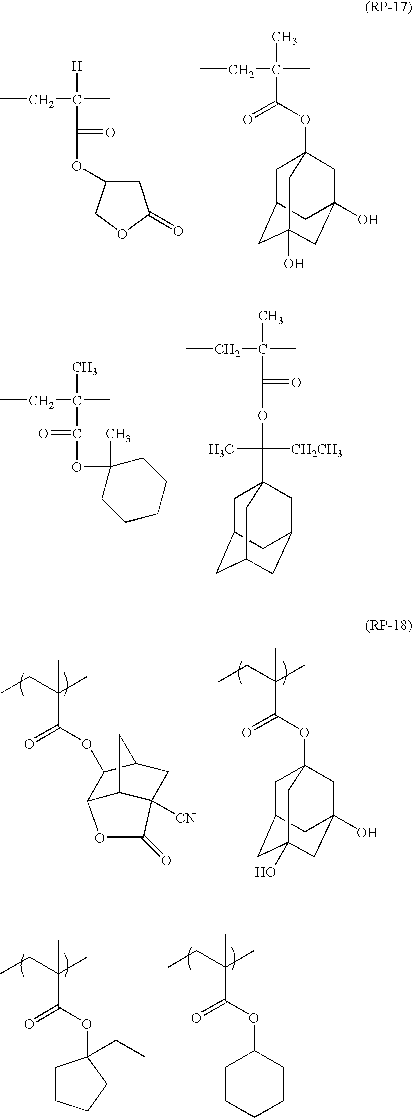

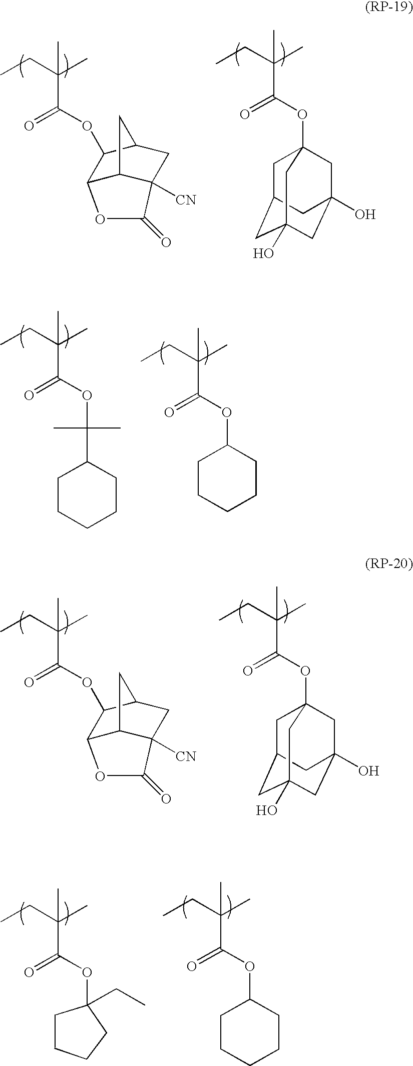

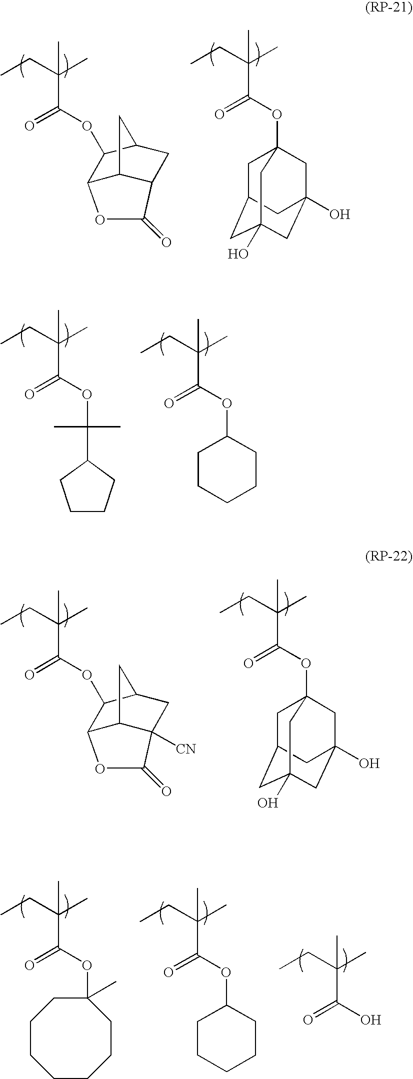

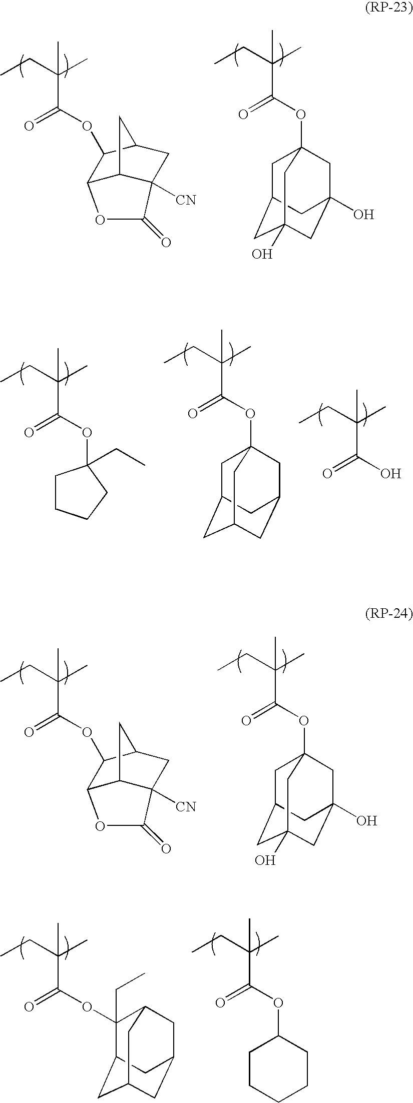

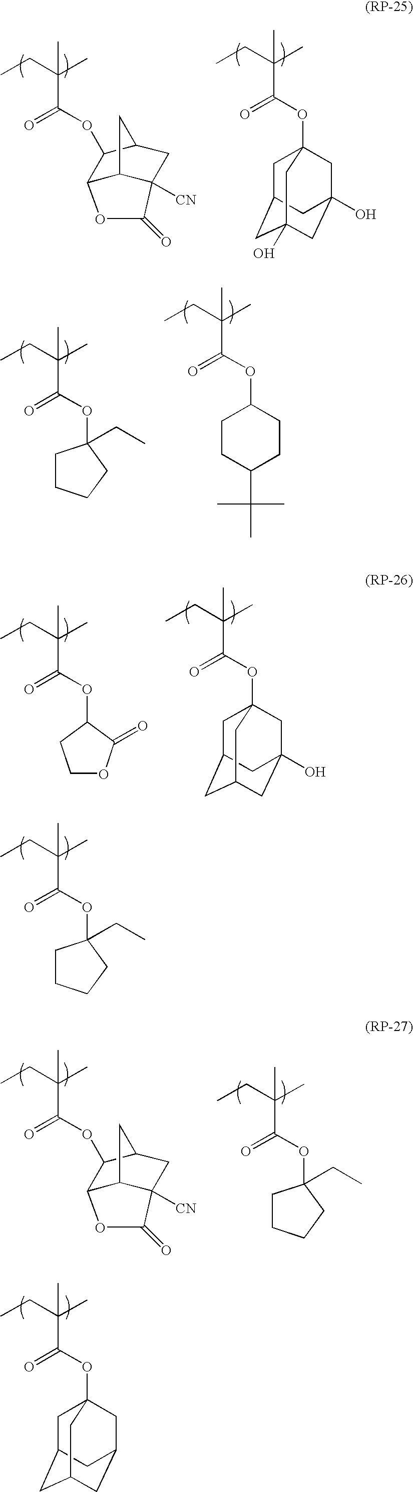

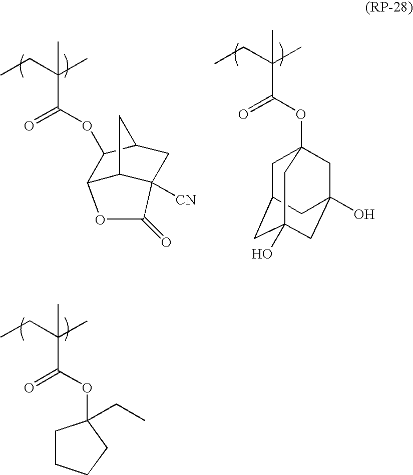

[2] Compound that Generates an Acid when Exposed to Actinic Rays or Radiation (Component (B))

The positive resist composition of the present invention contains a compound that when exposed to actinic rays or radiation, generates an acid (hereinafter also referred to as “acid generator”).

As the acid generator, use can be made of a member appropriately selected from among a photoinitiator for photocationic polymerization, a photoinitiator for photoradical polymerization, a photo-achromatic agent and photo-discoloring agent for dyes, any of publicly known compounds that when exposed to actinic rays or radiation, generate an acid, employed in microresists, etc., and mixtures thereof.

For example, as the acid generator, there can be mentioned a diazonium salt, a phosphonium salt, a sulfonium salt, an iodonium salt, an imide sulfonate, an oxime sulfonate, diazosulfone, disulfone or o-nitrobenzyl sulfonate.

Further, use can be made of compounds obtained by introducing any of the above groups or compounds that when exposed to actinic rays or radiation, generate an acid in a polymer principal chain or side chain, for example, compounds described in U.S. Pat. No. 3,849,137, DE 3914407, JP-A's-63-26653, 55-164824, 62-69263, 63-146038, 63-163452, 62-153853, 63-146029, etc.

Furthermore, use can be made of compounds that when exposed to light, generate an acid described in U.S. Pat. No. 3,779,778 and EP 126,712.

As preferred compounds among the acid generators, there can be mentioned those of the following general formulae (ZI), (ZII) and (ZIII).

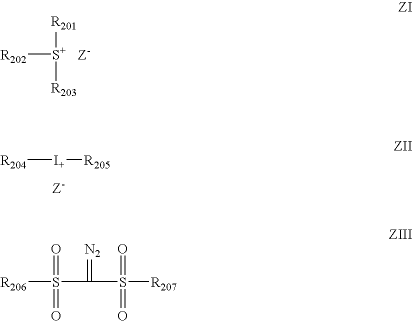

In the above general formula (ZI),

each of R₂₀₁, R₂₀₂ and R₂₀₃ independently represents an organic group.

The number of carbon atoms of the organic group represented by R₂₀₁, R₂₀₂ and R₂₀₃ is generally in the range of 1 to 30, preferably 1 to 20.

Two of R₂₀₁ to R₂₀₃ may be bonded with each other to thereby form a ring structure, and the ring within the same may contain an oxygen atom, a sulfur atom, an ester bond, an amido bond or a carbonyl group. As the group formed by bonding of two of R₂₀₁ to R₂₀₃, there can be mentioned an alkylene group (for example, a butylene group or a pentylene group).

Z⁻ represents a nonnucleophilic anion.

As the nonnucleophilic anion represented by Z⁻, there can be mentioned, for example, a sulfonate anion, a carboxylate anion, a sulfonylimido anion, a bis(alkylsulfonyl)imido anion, a tris(alkylsulfonyl)methyl anion or the like.

The nonnucleophilic anion means an anion whose capability of inducing a nucleophilic reaction is extremely low and is an anion capable of inhibiting any temporal decomposition by intramolecular nucleophilic reaction. This would realize an enhancement of the temporal stability of the resist.

As the sulfonate anion, there can be mentioned, for example, an aliphatic sulfonate anion, an aromatic sulfonate anion, a camphor sulfonate anion or the like.

As the carboxylate anion, there can be mentioned, for example, an aliphatic carboxylate anion, an aromatic carboxylate anion, an aralkyl carboxylate anion or the like.

The aliphatic moiety of the aliphatic sulfonate anion may be an alkyl group or a cycloalkyl group, being preferably an alkyl group having 1 to 30 carbon atoms or a cycloalkyl group having 3 to 30 carbon atoms. As such, there can be mentioned, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a boronyl group or the like.

As a preferred aromatic group of the aromatic sulfonate anion, there can be mentioned an aryl group having 6 to 14 carbon atoms, for example, a phenyl group, a tolyl group, a naphthyl group or the like.

The alkyl group, cycloalkyl group and aryl group of the aliphatic sulfonate anion and aromatic sulfonate anion may have a substituent. As the substituent of the alkyl group, cycloalkyl group and aryl group of the aliphatic sulfonate anion and aromatic sulfonate anion, there can be mentioned, for example, a nitro group, a halogen atom (fluorine atom, chlorine atom, bromine atom or iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) or the like. The aryl group or ring structure of these groups may further have an alkyl group (preferably having 1 to 15 carbon atoms) as its substituent.

As the aliphatic moiety of the aliphatic carboxylate anion, there can be mentioned the same alkyl groups and cycloalkyl groups as mentioned with respect to the aliphatic sulfonate anion.

As the aromatic group of the aromatic carboxylate anion, there can be mentioned the same aryl groups as mentioned with respect to the aromatic sulfonate anion.

As a preferred aralkyl group of the aralkyl carboxylate anion, there can be mentioned an aralkyl group having 6 to 12 carbon atoms, for example, a benzyl group, a phenethyl group, a naphthylmethyl group, a naphthylethyl group, a naphthylbutyl group or the like.

The alkyl group, cycloalkyl group, aryl group and aralkyl group of the aliphatic carboxylate anion, aromatic carboxylate anion and aralkyl carboxylate anion may have a substituent. As the substituent of the alkyl group, cycloalkyl group, aryl group and aralkyl group of the aliphatic carboxylate anion, aromatic carboxylate anion and aralkyl carboxylate anion, there can be mentioned, for example, the same halogen atom, alkyl group, cycloalkyl group, alkoxy group, alkylthio group, etc. as mentioned with respect to the aromatic sulfonate anion.

As the sulfonylimido anion, there can be mentioned, for example, a saccharin anion.

The alkyl group of the bis(alkylsulfonyl)imido anion and tris(alkylsulfonyl)methyl anion is preferably an alkyl group having 1 to 5 carbon atoms. As such, there can be mentioned, for example, a methyl group, an ethyl group, a propyl group, an isopropyl group, an n-butyl group, an isobutyl group, a sec-butyl group, a pentyl group, a neopentyl group or the like. As a substituent of these alkyl groups, there can be mentioned a halogen atom, an alkyl group substituted with a halogen atom, an alkoxy group, an alkylthio group, an alkyloxysulfonyl group, an aryloxysulfonyl group, a cycloalkylaryloxysulfonyl group or the like. An alkyl group substituted with a fluorine atom is preferred.

As the other nonnucleophilic anions, there can be mentioned, for example, phosphorus fluoride, boron fluoride, antimony fluoride and the like.

The nonnucleophilic anion represented by Z⁻ is preferably selected from among an aliphatic sulfonate anion substituted at its α-position of sulfonic acid with a fluorine atom, an aromatic sulfonate anion substituted with a fluorine atom or a group having a fluorine atom, a bis(alkylsulfonyl)imido anion whose alkyl group is substituted with a fluorine atom and a tris(alkylsulfonyl)methide anion whose alkyl group is substituted with a fluorine atom. More preferably, the nonnucleophilic anion is a perfluorinated aliphatic sulfonate anion having 4 to 8 carbon atoms, a benzene sulfonate anion having a fluorine atom, a bis(alkylsulfonyl)imido anion whose alkyl group is substituted with a fluorine atom and a tris(alkylsulfonyl)methide anion whose alkyl group is substituted with a fluorine atom.

As the organic groups represented by R₂₀₁, R₂₀₂ and R₂₀₃, there can be mentioned, for example, groups corresponding to the following compounds (ZI-1), (ZI-2) and (ZI-3).

Appropriate use may be made of compounds with two or more of the structures of the general formula (ZI). For example, use may be made of compounds having a structure wherein at least one of R₂₀₁ to R₂₀₃ of a compound of the general formula (ZI) is bonded with at least one of R₂₀₁ to R₂₀₃ of another compound of the general formula (ZI).

As preferred (ZI) components, there can be mentioned the following compounds (ZI-1), (ZI-2) and (ZI-3).

The compounds (ZI-1) are arylsulfonium compounds of the general formula (ZI) wherein at least one of R₂₀₁ to R₂₀₃ is an aryl group, namely, compounds containing an arylsulfonium as a cation.

In the arylsulfonium compounds, all of the R₂₀₁ to R₂₀₃ may be aryl groups. It is also appropriate that the R₂₀₁ to R203 are partially an aryl group and the remainder is an alkyl group or a cycloalkyl group.

As the arylsulfonium compounds, there can be mentioned, for example, a triarylsulfonium compound, a diarylalkylsulfonium compound, an aryldialkylsulfonium compound, a diarylcycloalkylsulfonium compound and an aryldicycloalkylsulfonium compound.

The aryl group of the arylsulfonium compounds is preferably a phenyl group or a naphthyl group, more preferably a phenyl group. The aryl group may be one having a heterocyclic structure containing an oxygen atom, nitrogen atom, sulfur atom or the like. As the aryl group having a heterocyclic structure, there can be mentioned, for example, a pyrrole residue (group formed by loss of one hydrogen atom from pyrrole), a furan residue (group formed by loss of one hydrogen atom from furan), a thiophene residue (group formed by loss of one hydrogen atom from thiophene), an indole residue (group formed by loss of one hydrogen atom from indole), a benzofuran residue (group formed by loss of one hydrogen atom from benzofuran), a benzothiophene residue (group formed by loss of one hydrogen atom from benzothiophene) or the like. When the arylsulfonium compound has two or more aryl groups, the two or more aryl groups may be identical to or different from each other.

The alkyl group or cycloalkyl group contained in the arylsulfonium compound according to necessity is preferably a linear or branched alkyl group having 1 to 15 carbon atoms or a cycloalkyl group having 3 to 15 carbon atoms. As such, there can be mentioned, for example, a methyl group, an ethyl group, a propyl group, an n-butyl group, a sec-butyl group, a t-butyl group, a cyclopropyl group, a cyclobutyl group, a cyclohexyl group or the like.

The aryl group, alkyl group or cycloalkyl group represented by R₂₀₁ to R₂₀₃ may have as its substituent an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxyl group or a phenylthio group. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. More preferred substituents are an alkyl group having 1 to 4 carbon atoms and an alkoxy group having 1 to 4 carbon atoms. The substituents may be contained in any one of the three R₂₀₁ to R₂₀₃, or alternatively may be contained in all three of R₂₀₁ to R₂₀₃. When R₂₀₁ to R₂₀₃ represent an aryl group, the substituent preferably lies at the p-position of the aryl group.

Now, the compounds (ZI-2) will be described.

The compounds (ZI-2) are compounds of the formula (ZI) wherein each of R₂₀₁ to R₂₀₃ independently represents an organic group having no aromatic ring. The aromatic rings include an aromatic ring having a heteroatom.

The organic group having no aromatic ring represented by R₂₀₁ to R₂₀₃ generally has 1 to 30 carbon atoms, preferably 1 to 20 carbon atoms.

Preferably, each of R₂₀₁ to R₂₀₃ independently represents an alkyl group, a cycloalkyl group, an allyl group or a vinyl group. More preferred groups are a linear or branched 2-oxoalkyl group, a 2-oxocycloalkyl group and an alkoxycarbonylmethyl group. Especially preferred is a linear or branched 2-oxoalkyl group.

As preferred alkyl groups and cycloalkyl groups represented by R₂₀₁ to R₂₀₃, there can be mentioned a linear or branched alkyl group having 1 to 10 carbon atoms (for example, a methyl group, an ethyl group, a propyl group, a butyl group or a pentyl group) and a cycloalkyl group having 3 to 10 carbon atoms (a cyclopentyl group, a cyclohexyl group or a norbornyl group). As more preferred alkyl groups, there can be mentioned a 2-oxoalkyl group and an alkoxycarbonylmethyl group. As more preferred cycloalkyl group, there can be mentioned a 2-oxocycloalkyl group.

The 2-oxoalkyl group may be linear or branched. A group having >C═O at the 2-position of the alkyl group is preferred.

The 2-oxocycloalkyl group is preferably a group having >C═O at the 2-position of the cycloalkyl group.

As preferred alkoxy groups of the alkoxycarbonylmethyl group, there can be mentioned alkoxy groups having 1 to 5 carbon atoms (a methoxy group, an ethoxy group, a propoxy group, a butoxy group and a pentoxy group).

The R₂₀₁ to R₂₀₃ may be further substituted with a halogen atom, an alkoxy group (for example, 1 to 5 carbon atoms), a hydroxyl group, a cyano group or a nitro group.

Now, the compounds (ZI-3) will be described.

The compounds (ZI-3) are those represented by the following general formula (ZI-3) which have a phenacylsulfonium salt structure.

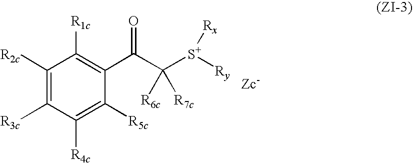

In the general formula (ZI-3),

each of R_{1c} to R_{5c} independently represents a hydrogen atom, an alkyl group, a cycloalkyl group, an alkoxy group or a halogen atom.

Each of R_{6c} and R_{7c} independently represents a hydrogen atom, an alkyl group or a cycloalkyl group.

Each of Rₓ and R_{y} independently represents an alkyl group, a cycloalkyl group, an allyl group or a vinyl group.

Any two or more of R_{1c} to R_{5c}, and R_{6c} and R_{7c}, and Rₓ and R_{y} may be bonded with each other to thereby form a ring structure. This ring structure may contain an oxygen atom, a sulfur atom, an ester bond or an amido bond. As the group formed by bonding of any two or more of R_{1c} to R_{5c}, and R_{6c} and R_{7c}, and Rₓ and R_{y}, there can be mentioned a butylene group, a pentylene group or the like.

Zc⁻ represents a nonnucleophilic anion. There can be mentioned the same nonnucleophilic anions as mentioned with respect to the Z⁻ of the general formula (ZI).

The alkyl group represented by R_{1c} to R_{7c} may be linear or branched. As such, there can be mentioned, for example, an alkyl group having 1 to 20 carbon atoms, preferably a linear or branched alkyl group having 1 to 12 carbon atoms (for example, a methyl group, an ethyl group, a linear or branched propyl group, a linear or branched butyl group or a linear or branched pentyl group). As the cycloalkyl group, there can be mentioned, for example, a cycloalkyl group having 3 to 8 carbon atoms (for example, a cyclopentyl group or a cyclohexyl group).

The alkoxy group represented by R_{1c} to R_{5c} may be linear, or branched, or cyclic. As such, there can be mentioned, for example, an alkoxy group having 1 to 10 carbon atoms, preferably a linear or branched alkoxy group having 1 to 5 carbon atoms (for example, a methoxy group, an ethoxy group, a linear or branched propoxy group, a linear or branched butoxy group or a linear or branched pentoxy group) and a cycloalkoxy group having 3 to 8 carbon atoms (for example, a cyclopentyloxy group or a cyclohexyloxy group).

Preferably, any one of R_{1c} to R_{5c} is a linear or branched alkyl group, a cycloalkyl group or a linear, branched or cyclic alkoxy group. More preferably, the sum of carbon atoms of R_{1c} to R_{5c} is in the range of 2 to 15. Accordingly, there can be attained an enhancement of solvent solubility and inhibition of particle generation during storage.

As the alkyl groups and cycloalkyl groups represented by Rₓ and R_{y}, there can be mentioned the same alkyl groups and cycloalkyl groups as mentioned with respect to R_{1c} to R_{7c}. Among them, a 2-oxoalkyl group, a 2-oxocycloalkyl group and an alkoxycarbonylmethyl group are preferred.

As the 2-oxoalkyl group and 2-oxocycloalkyl group, there can be mentioned groups having >C═O at the 2-position of the alkyl group and cycloalkyl group represented by R_{1c} to R_{7c}.

Regarding the alkoxy group of the alkoxycarbonylmethyl group, there can be mentioned the same alkoxy groups as mentioned with respect to R_{1c} to R_{5c}.

Each of Rₓ and R_{y} is preferably an alkyl group or cycloalkyl group having preferably 4 or more carbon atoms. The alkyl group or cycloalkyl group has more preferably 6 or more carbon atoms and still more preferably 8 or more carbon atoms.

Now, the general formulae (ZII) and (ZIII) will be described.

In the general formulae (ZII) and (ZIII), each of R₂₀₄ to R₂₀₇ independently represents an aryl group, an alkyl group or a cycloalkyl group.

The aryl group represented by R₂₀₄ to R₂₀₇ is preferably a phenyl group or a naphthyl group, more preferably a phenyl group. The aryl group represented by R₂₀₄ to R₂₀₇ may be one having a heterocyclic structure containing an oxygen atom, nitrogen atom, sulfur atom or the like. As the aryl group having a heterocyclic structure, there can be mentioned, for example, a pyrrole residue (group formed by loss of one hydrogen atom from pyrrole), a furan residue (group formed by loss of one hydrogen atom from furan), a thiophene residue (group formed by loss of one hydrogen atom from thiophene), an indole residue (group formed by loss of one hydrogen atom from indole), a benzofuran residue (group formed by loss of one hydrogen atom from benzofuran), a benzothiophene residue (group formed by loss of one hydrogen atom from benzothiophene) or the like.

As preferred alkyl groups and cycloalkyl groups represented by R₂₀₄ to R₂₀₇, there can be mentioned a linear or branched alkyl group having 1 to 10 carbon atoms (for example, a methyl group, an ethyl group, a propyl group, a butyl group or a pentyl group) and a cycloalkyl group having 3 to 10 carbon atoms (a cyclopentyl group, a cyclohexyl group or a norbornyl group).

The aryl group, alkyl group and cycloalkyl group represented by R₂₀₄ to R₂₀₇ may have a substituent. As a possible substituent on the aryl group, alkyl group and cycloalkyl group represented by R₂₀₄ to R₂₀₇, there can be mentioned, for example, an alkyl group (for example, 1 to 15 carbon atoms), a cycloalkyl group (for example, 3 to 15 carbon atoms), an aryl group (for example, 6 to 15 carbon atoms), an alkoxy group (for example, 1 to 15 carbon atoms), a halogen atom, a hydroxyl group, a phenylthio group or the like.

Z⁻ represents a nonnucleophilic anion. As such, there can be mentioned the same nonnucleophilic anions as mentioned with respect to the Z⁻ of the general formula (ZI).

As the acid generators, there can be further mentioned the compounds of the following general formulae (ZIV), (ZV) and (ZVI).

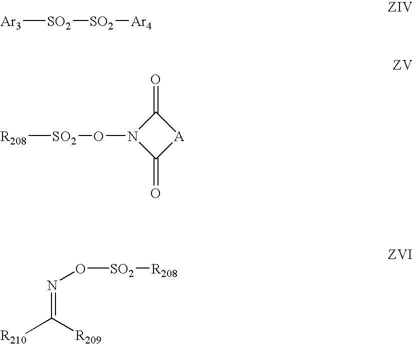

In the general formulae (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Among the acid generators, the compounds of the general formulae (ZI) to (ZIII) are more preferred.

As a preferred acid generator, there can be mentioned a compound that generates an acid having one sulfonate group or imido group. As a more preferred acid generator, there can be mentioned a compound that generates a monovalent perfluoroalkanesulfonic acid, a compound that generates a monovalent aromatic sulfonic acid substituted with a fluorine atom or fluorine-atom-containing group, or a compound that generates a monovalent imidic acid substituted with a fluorine atom or fluorine-atom-containing group. As a still more preferred acid generator, there can be mentioned any of sulfonium salts of fluorinated alkanesulfonic acid, fluorinated benzenesulfonic acid, fluorinated imidic acid and fluorinated methide acid. With respect to practicable acid generators, it is especially preferred for the generated acid to be a fluorinated alkanesulfonic acid, fluorinated benzenesulfonic acid or fluorinated imidic acid of −1 or below pKa. By the use thereof, an enhancement of sensitivity can be attained.

Especially preferred examples of the acid generators are as follows, which however in no way limit the scope of the present invention.

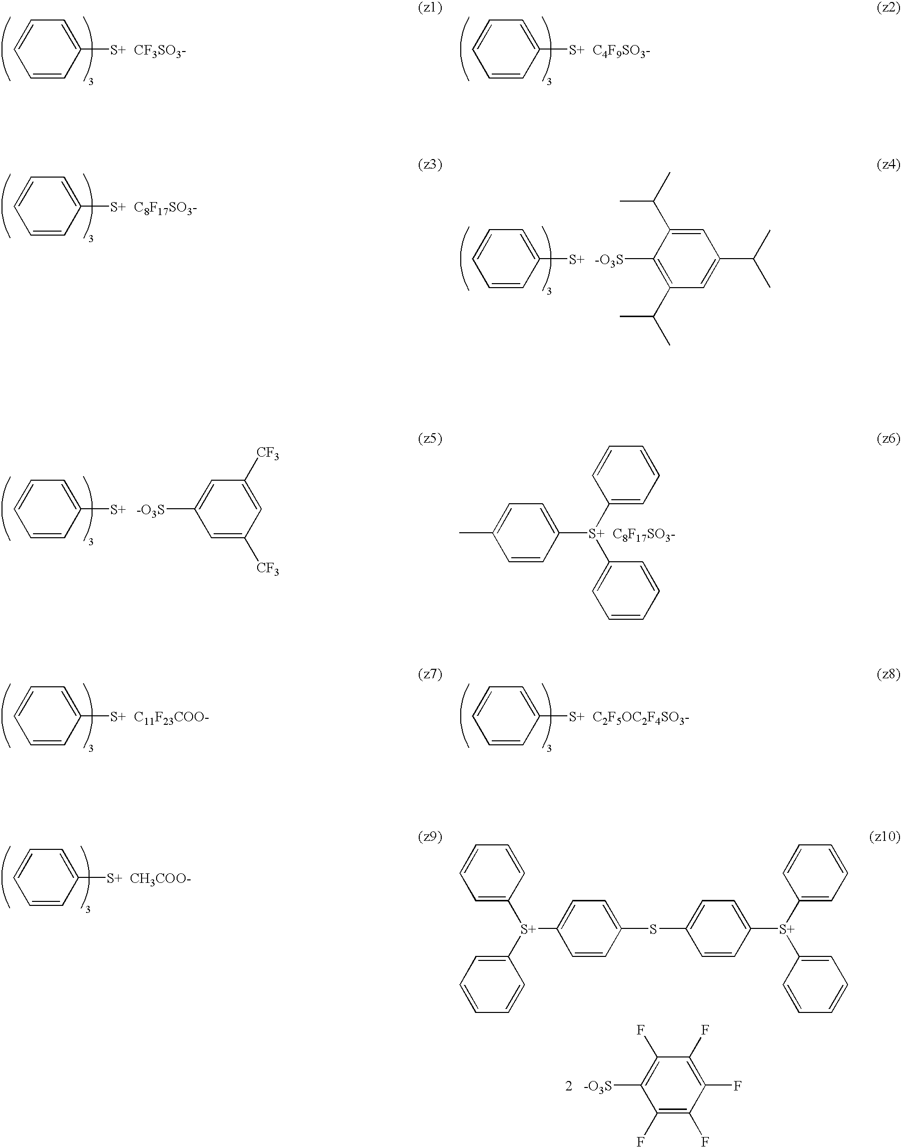

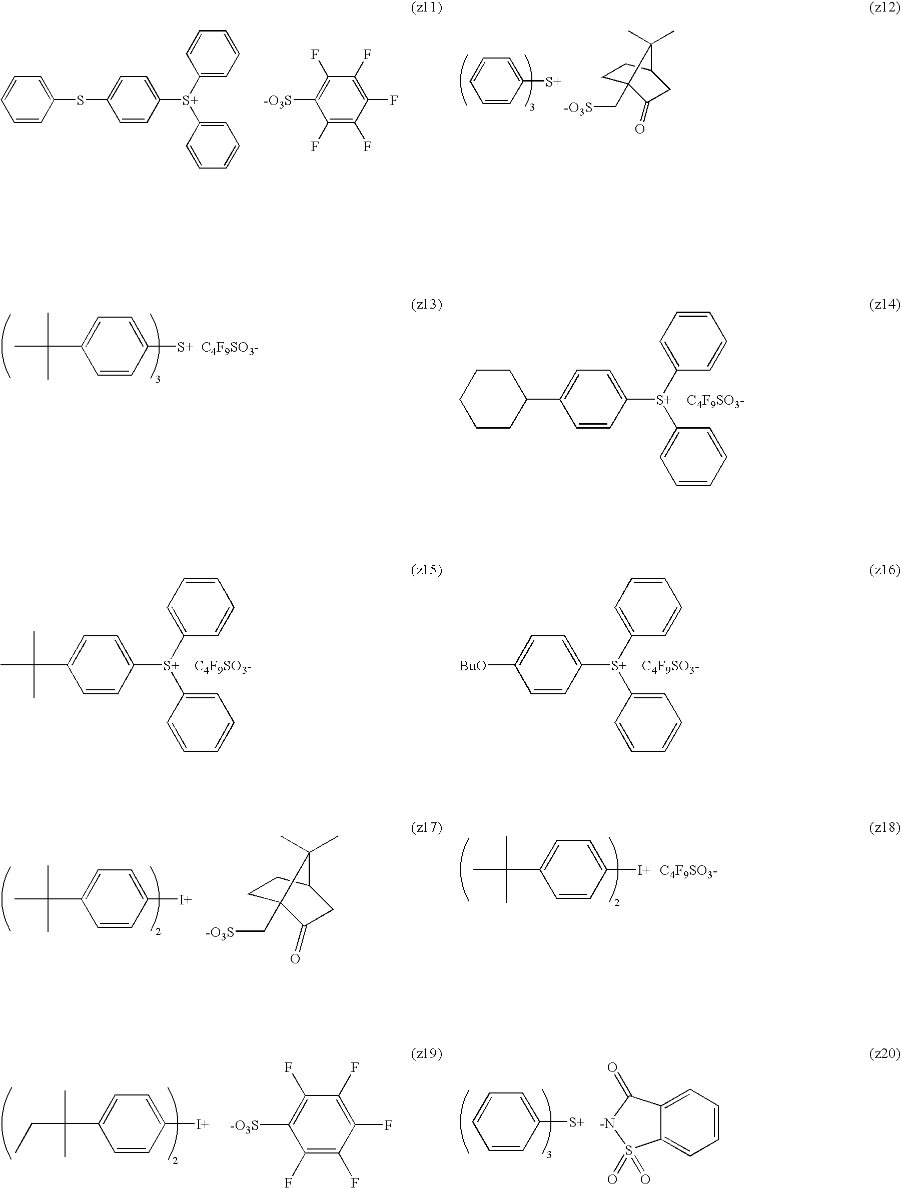

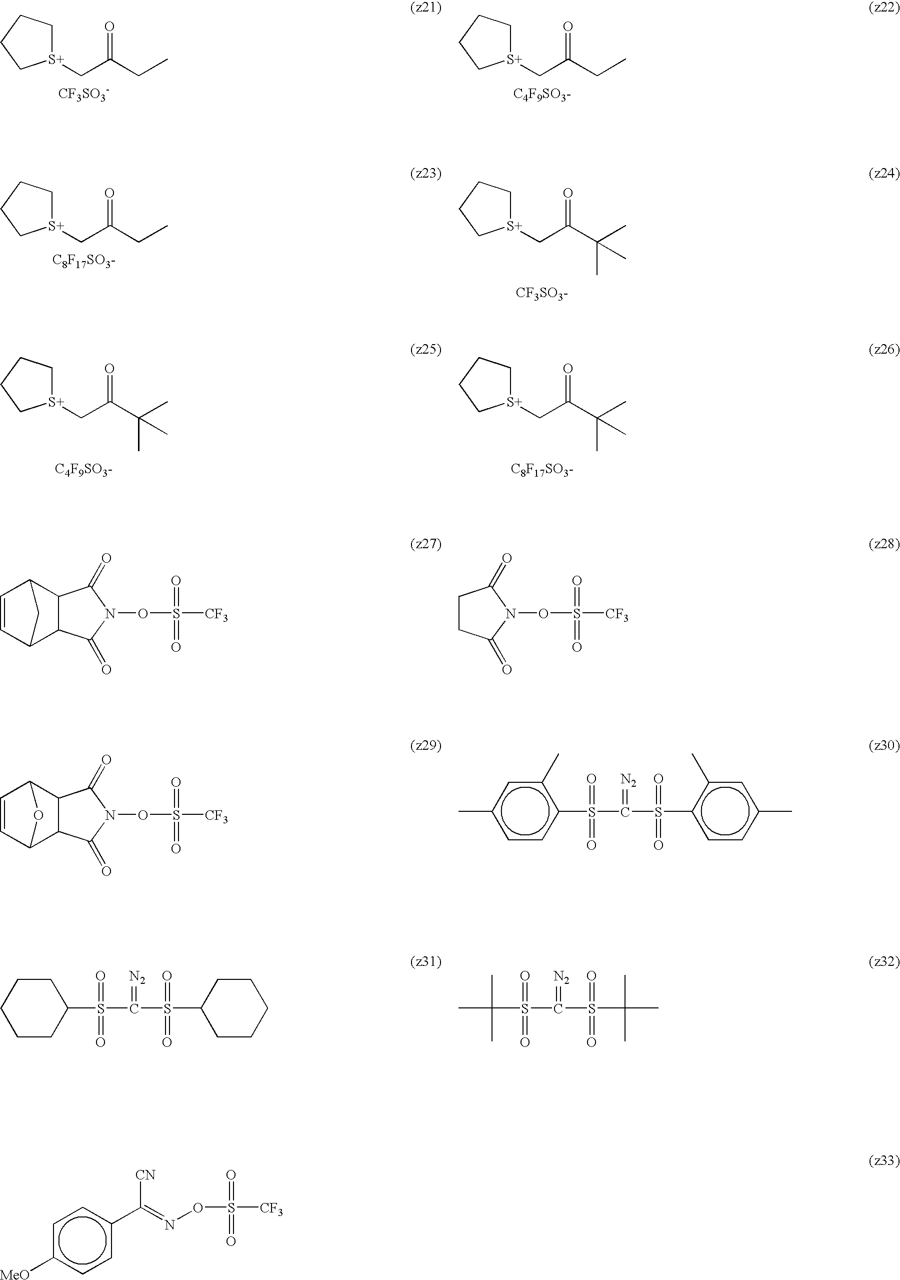

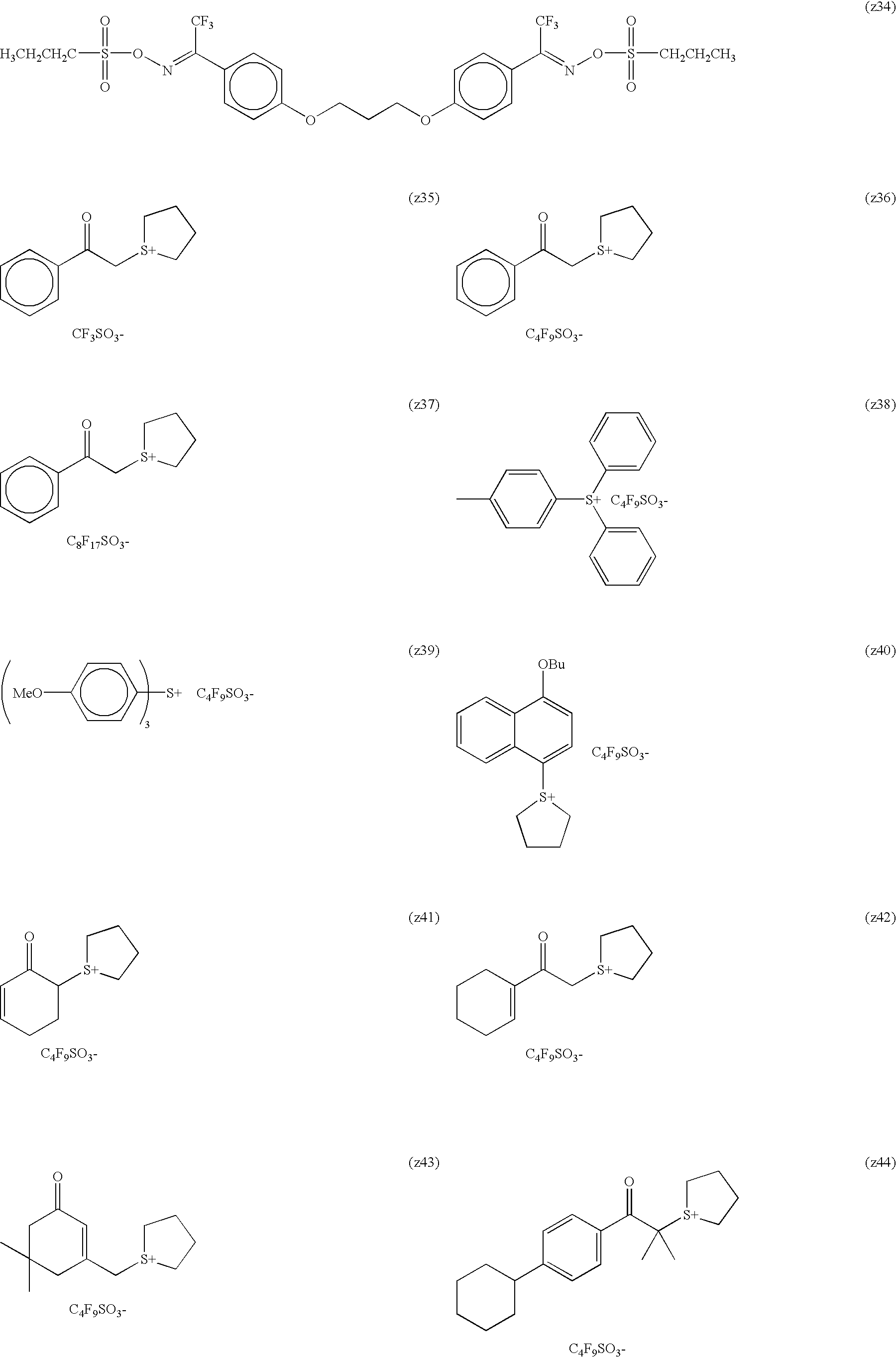

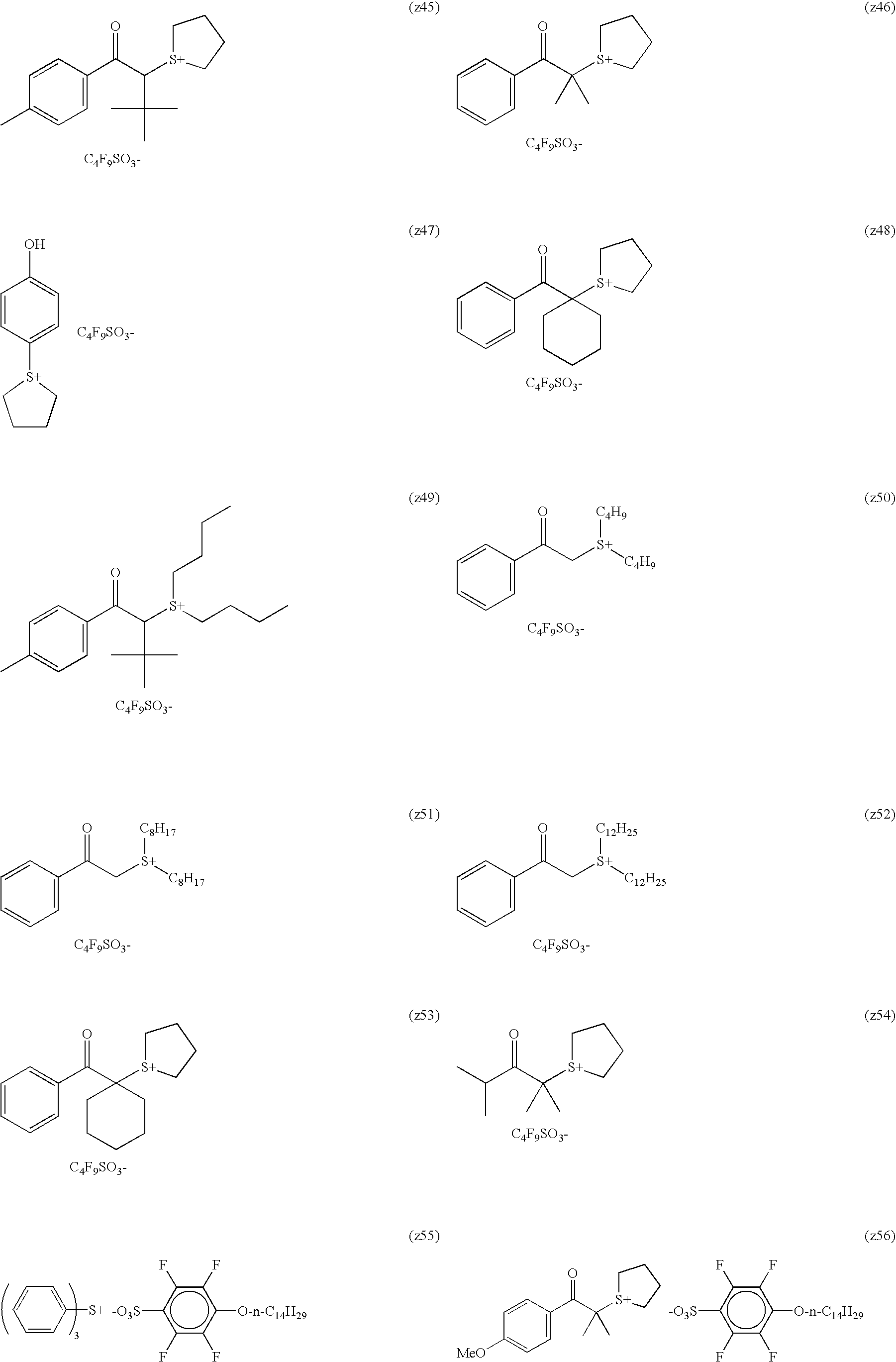

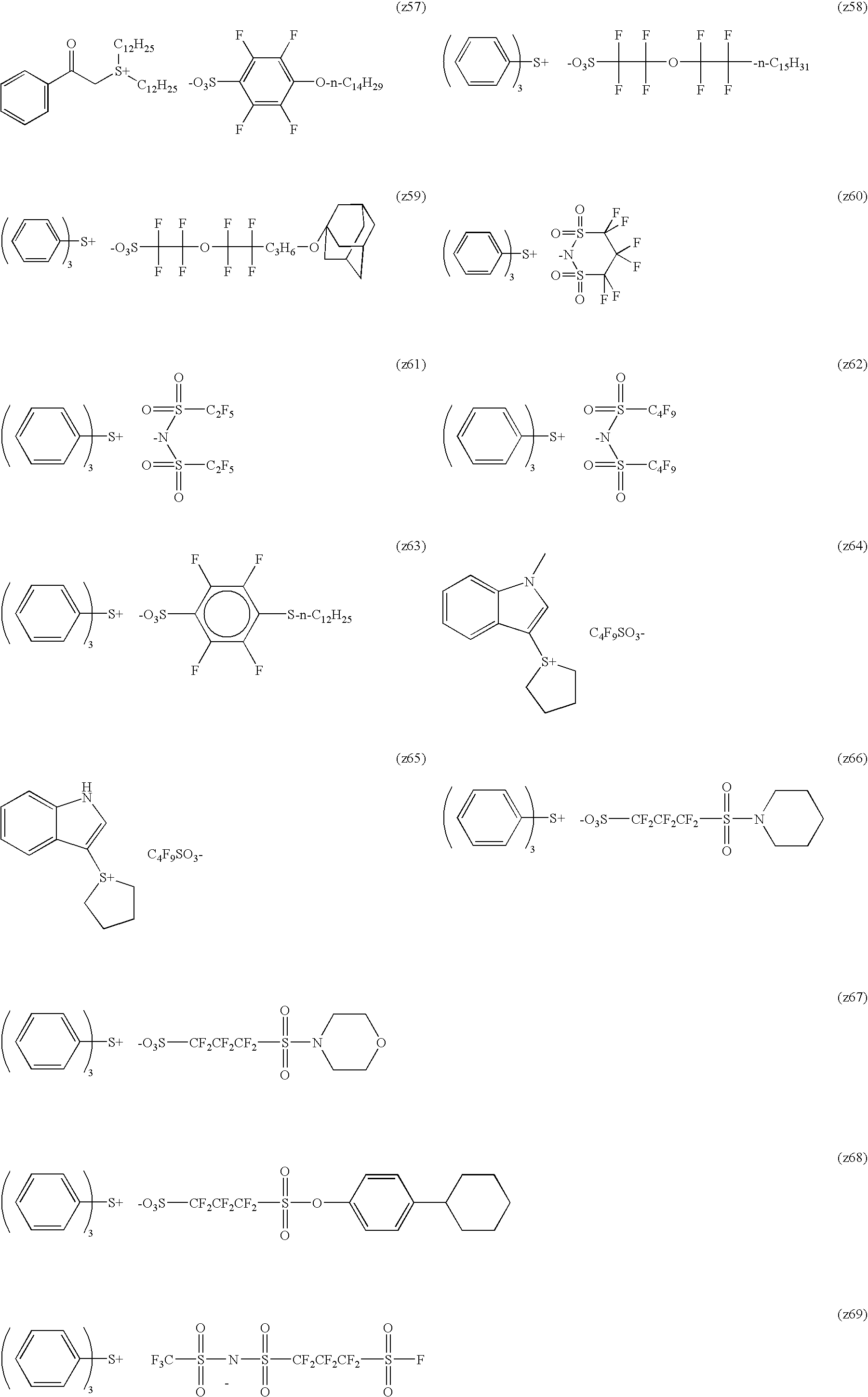

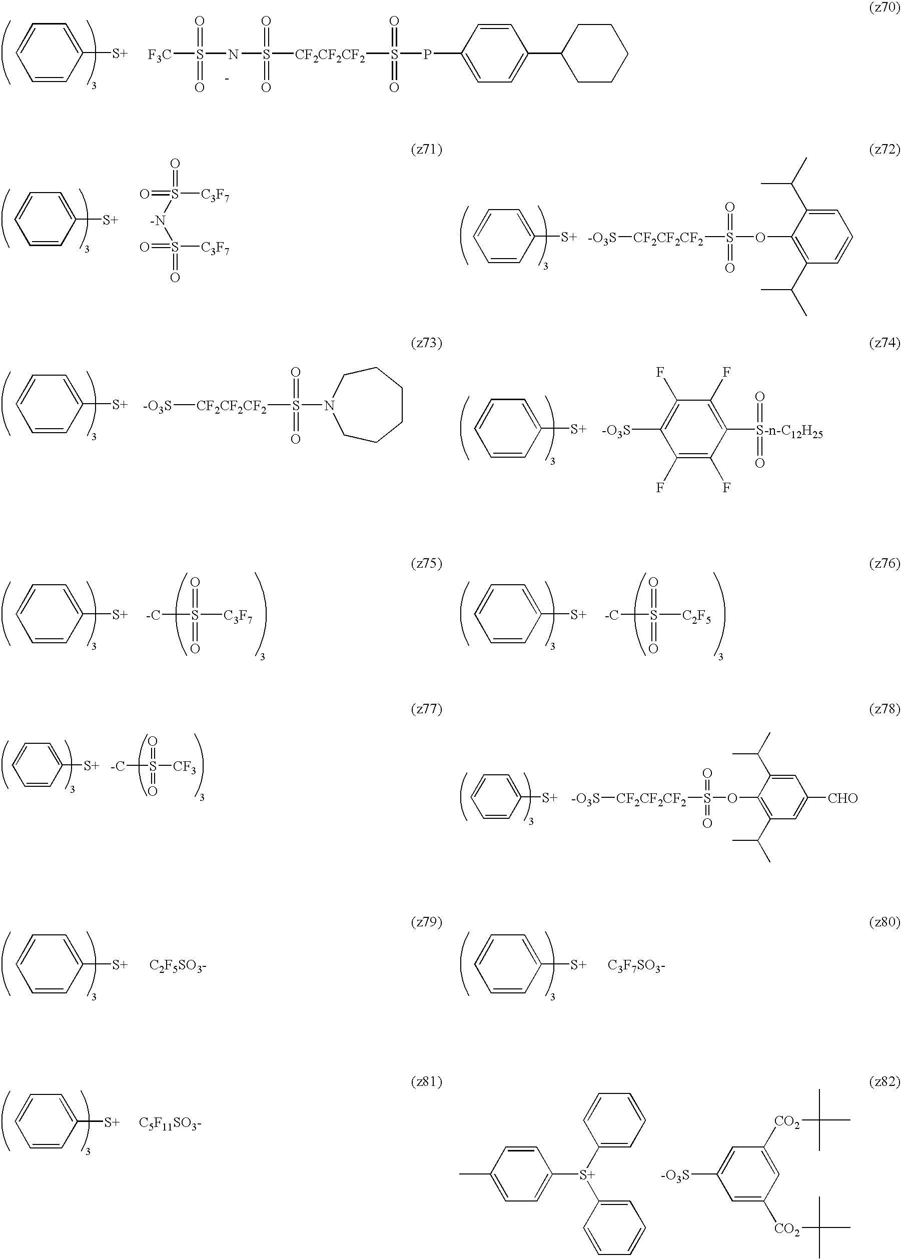

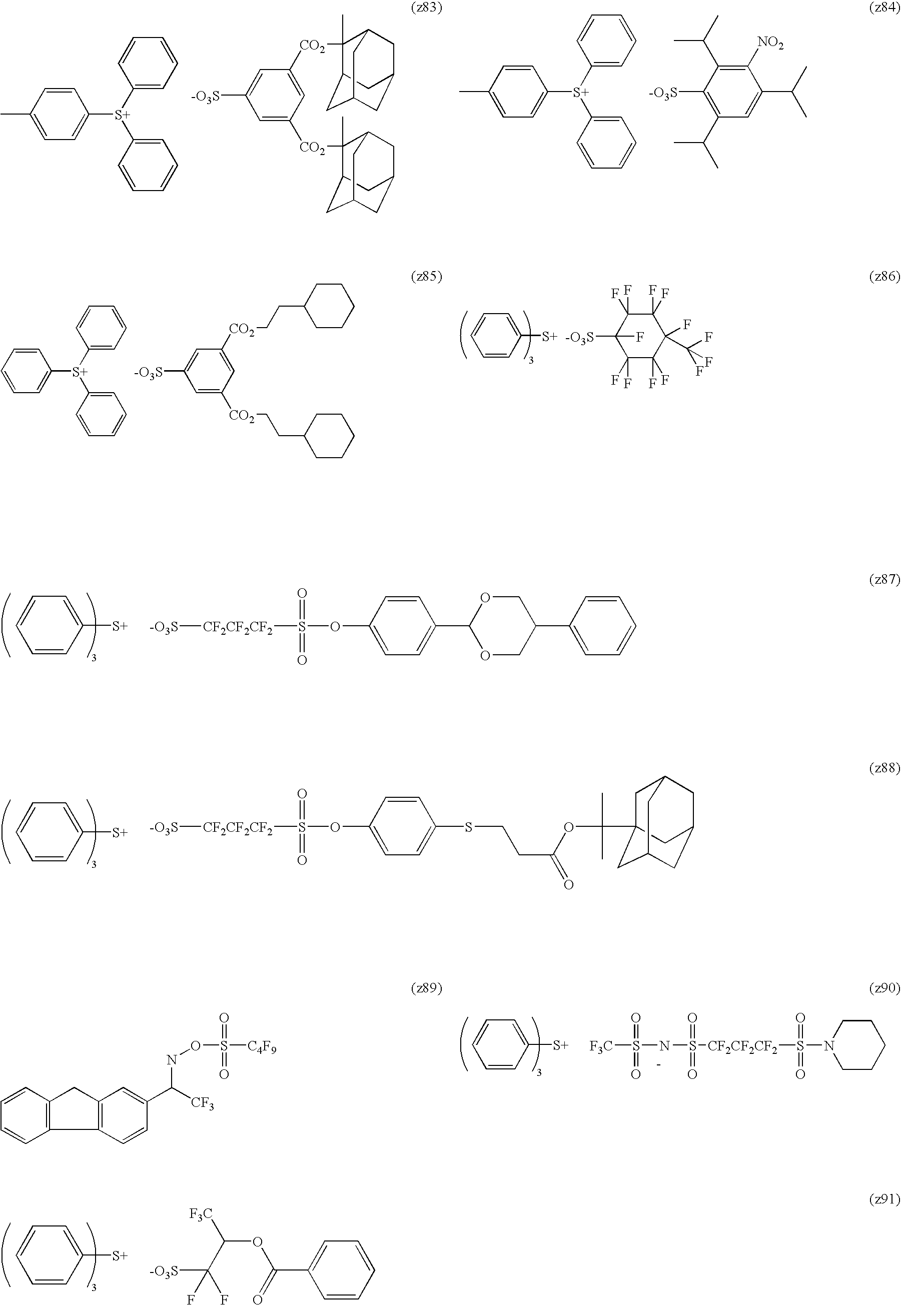

The acid generators can be used either individually or in combination.

The content of the acid generators is preferably in the range of 0.1 to 20 mass %, more preferably 0.5 to 10 mass % and still more preferably 1 to 7 mass % based on the total solids of the positive resist composition.

[3] Basic Compound

The photosensitive composition of the present invention preferably contains a basic compound so as to decrease any performance alteration over time from exposure to heating.

As preferred basic compounds, there can be mentioned the compounds having the structures of the following formulae (A) to (E).

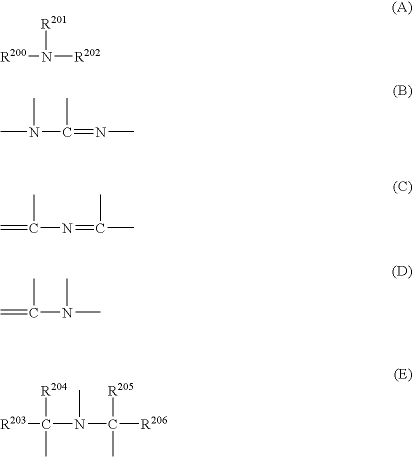

In the general formulae (A) and (E),

R²⁰⁰, R²⁰¹ and R²⁰² may be identical to or different from each other and each represent a hydrogen atom, an alkyl group (preferably having 1 to 20 carbon atoms), a cycloalkyl group (preferably having 3 to 20 carbon atoms) or an aryl group (having 6 to 20 carbon atoms). R²⁰¹ and R²⁰² may be bonded with each other to thereby form a ring.

With respect to the above alkyl group, as a preferred substituted alkyl group, there can be mentioned an aminoalkyl group having 1 to 20 carbon atoms, a hydroxyalkyl group having 1 to 20 carbon atoms or a cyanoalkyl group having 1 to 20 carbon atoms.

R²⁰³, R²⁰⁴, R²⁰⁵ and R²⁰⁶ may be identical to or different from each other and each represent an alkyl group having 1 to 20 carbon atoms.

More preferably, in these general formulae (A) and (E) the alkyl group is unsubstituted.

As preferred compounds, there can be mentioned guanidine, aminopyrrolidine, pyrazole, pyrazoline, piperazine, aminomorpholine, aminoalkylmorpholine, piperidine and the like. Further, as preferred compounds, there can be mentioned compounds with an imidazole structure, a diazabicyclo structure, an onium hydroxide structure, an onium carboxylate structure, a trialkylamine structure, an aniline structure or a pyridine structure, alkylamine derivatives having a hydroxyl group and/or an ether bond, aniline derivatives having a hydroxyl group and/or an ether bond and the like.

As the compounds with an imidazole structure, there can be mentioned imidazole, 2,4,5-triphenylimidazole, benzimidazole, 2-phenylbenzoimidazole and the like. As the compounds with a diazabicyclo structure, there can be mentioned 1,4-diazabicyclo[2,2,2]octane, 1,5-diazabicyclo[4,3,0]non-5-ene, 1,8-diazabicyclo[5,4,0]undec-7-ene and the like. As the compounds with an onium hydroxide structure, there can be mentioned tetrabutylammonium hydroxide, triarylsulfonium hydroxide, phenacylsulfonium hydroxide, and sulfonium hydroxides having a 2-oxoalkyl group such as triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. As the compounds with an onium carboxylate structure, there can be mentioned those having a carboxylate at the anion moiety of the compounds with an onium hydroxide structure, for example, acetate, adamantane-1-carboxylate, perfluoroalkyl carboxylate and the like. As the compounds with a trialkylamine structure, there can be mentioned tri(n-butyl)amine, tri(n-octyl)amine and the like. As the aniline compounds, there can be mentioned 2,6-diisopropylaniline, N,N-dimethylaniline, N,N-dibutylaniline, N,N-dihexylaniline and the like. As the alkylamine derivatives having a hydroxyl group and/or an ether bond, there can be mentioned ethanolamine, diethanolamine, triethanolamine, N-phenyldiethanolamine, tris(methoxyethoxyethyl)amine and the like. As the aniline derivatives having a hydroxyl group and/or an ether bond, there can be mentioned N,N-bis(hydroxyethyl)aniline and the like.

As preferred basic compounds, there can be further mentioned an amine compound having a phenoxy group, an ammonium salt compound having a phenoxy group, an amine compound having a sulfonic ester group and an ammonium salt compound having a sulfonic ester group.

As the amine compound, use can be made of primary, secondary and tertiary amine compounds. An amine compound having its at least one alkyl group bonded to the nitrogen atom thereof is preferred. Among the amine compounds, a tertiary amine compound is more preferred. In the amine compounds, as long as at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) besides the alkyl group may be bonded to the nitrogen atom. In the amine compounds, it is preferred for the alkyl chain to contain an oxygen atom so as to form an oxyalkylene group. The number of oxyalkylene groups in each molecule is one or more, preferably 3 to 9 and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

As the ammonium salt compound, use can be made of primary, secondary, tertiary and quaternary ammonium salt compounds. An ammonium salt compound having its at least one alkyl group bonded to the nitrogen atom thereof is preferred. Of the ammonium salt compounds, as long as at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) besides the alkyl group may be bonded to the nitrogen atom. Of the ammonium salt compounds, it is preferred for the alkyl chain to contain an oxygen atom so as to form an oxyalkylene group. The number of oxyalkylene groups in each molecule is one or more, preferably 3 to 9 and still more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

As the anion of the ammonium salt compounds, there can be mentioned a halide, a sulfonate, a borate, a phosphate or the like. Of these, a halide and a sulfonate are preferred. Among halides, chloride, bromide and iodide are especially preferred. Among sulfonates, an organic sulfonate having 1 to 20 carbon atoms is especially preferred. As the organic sulfonate, there can be mentioned an aryl sulfonate and an alkyl sulfonate having 1 to 20 carbon atoms. The alkyl group of the alkyl sulfonate may have a substituent. As the substituent, there can be mentioned, for example, fluorine, chlorine, bromine, an alkoxy group, an acyl group, an aryl group or the like. As specific examples of the alkyl sulfonates, there can be mentioned methane sulfonate, ethane sulfonate, butane sulfonate, hexane sulfonate, octane sulfonate, benzyl sulfonate, trifluoromethane sulfonate, pentafluoroethane sulfonate, nonafluorobutane sulfonate and the like. As the aryl group of the aryl sulfonate, there can be mentioned a benzene ring, a naphthalene ring or an anthracene ring. The benzene ring, naphthalene ring or anthracene ring may have a substituent. As preferred substituents, there can be mentioned a linear or branched alkyl group having 1 to 6 carbon atoms and a cycloalkyl group having 3 to 6 carbon atoms. As specific examples of the linear or branched alkyl groups and cycloalkyl groups, there can be mentioned methyl, ethyl, n-propyl, isopropyl, n-butyl, i-butyl, t-butyl, n-hexyl, cyclohexyl and the like. As other substituents, there can be mentioned an alkoxy group having 1 to 6 carbon atoms, a halogen atom, cyano, nitro, an acyl group, an acyloxy group and the like.

The amine compound having a phenoxy group and ammonium salt compound having a phenoxy group are those having a phenoxy group at the end of the alkyl group of the amine compound or ammonium salt compound opposed to the nitrogen atom. The phenoxy group may have a substituent. As the substituent of the phenoxy group, there can be mentioned, for example, an alkyl group, an alkoxy group, a halogen atom, a cyano group, a nitro group, a carboxyl group, a carboxylic ester group, a sulfonic ester group, an aryl group, an aralkyl group, an acyloxy group, an aryloxy group or the like. The substitution position of the substituent may be any of 2- to 6-positions. The number of substituents is optional within the range of 1 to 5.

It is preferred that at least one oxyalkylene group exist between the phenoxy group and the nitrogen atom. The number of oxyalkylene groups in each molecule is one or more, preferably 3 to 9 and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

The sulfonic ester group of the amine compound having a sulfonic ester group or ammonium salt compound having a sulfonic ester group may be any of an alkylsulfonic ester, a cycloalkylsulfonic ester and an arylsulfonic ester. In the alkylsulfonic ester, the alkyl group preferably has 1 to 20 carbon atoms. In the cycloalkylsulfonic ester, the cycloalkyl group preferably has 3 to 20 carbon atoms. In the arylsulfonic ester, the aryl group preferably has 6 to 12 carbon atoms. The alkylsulfonic ester, cycloalkylsulfonic ester and arylsulfonic ester may have substituents. As preferred substituents, there can be mentioned a halogen atom, a cyano group, a nitro group, a carboxyl group, a carboxylic ester group and a sulfonic ester group.

It is preferred that at least one oxyalkylene group exist between the sulfonic ester group and the nitrogen atom. The number of oxyalkylene groups in each molecule is one or more, preferably 3 to 9 and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

These basic compounds are used either individually or in combination.

The amount of basic compound used is generally in the range of 0.001 to 10 mass %, preferably 0.01 to 5 mass % based on the total solid contents of the positive resist composition.

With respect to the ratio of the acid generator to basic compound used in the composition, preferably, the acid generator/basic compound (molar ratio)=2.5 to 300. The reason for this is that the molar ratio is preferred to be 2.5 or higher from the viewpoint of sensitivity and resolving power. The molar ratio is preferred to be 300 or below from the viewpoint of the inhibition of any resolving power deterioration due to thickening of resist pattern over time from exposure to heating treatment. The acid generator/basic compound (molar ratio) is more preferably in the range of 5.0 to 200, still more preferably 7.0 to 150.

[4] Surfactant

The positive resist composition of the present invention preferably further contains a surfactant, and more preferably contains any one, or two or more members, of fluorinated and/or siliconized surfactants (fluorinated surfactant, siliconized surfactant and surfactant containing both fluorine and silicon atoms).

The positive resist composition of the present invention when containing the above surfactant would, in the use of an exposure light source of 250 nm or below, especially 220 nm or below, realize favorable sensitivity and resolving power and produce a resist pattern with less adhesion and development defects.

As the fluorinated and/or siliconized surfactants, there can be mentioned, for example, those described in JP-A's-62-36663, 61-226746, 61-226745, 62-170950, 63-34540, 7-230165, 8-62834, 9-54432, 9-5988 and 2002-277862 and U.S. Pat. Nos. 5,405,720, 5,360,692, 5,529,881, 5,296,330, 5,436,098, 5,576,143, 5,294,511 and 5,824,451. Any of the following commercially available surfactants can be used as is.

As useful commercially available surfactants, there can be mentioned, for example, fluorinated surfactants/siliconized surfactants, such as Eftop EF301 and EF303 (produced by Shin-Akita Kasei Co., Ltd.), Florad FC 430, 431 and 4430 (produced by Sumitomo 3M Ltd.), Megafac F171, F173, F176, F189, F113, F110, F177, F120 and R08 (produced by Dainippon Ink & Chemicals, Inc.), Surflon S-382, SC101, 102, 103, 104, 105 and 106 (produced by Asahi Glass Co., Ltd.), Troy Sol S-366 (produced by Troy Chemical Co., Ltd.), GF-300 and GF-150 (produced by TOAGOSEI CO., LTD.), Sarfron S-393 (produced by SEIMI CHEMICAL CO., LTD.), Eftop EF121, EF122A, EF122B, RF122C, EF125M, EF135M, EF351, EF352, EF801, EF802 and EF601 (produced by JEMCO INC.), PF636, PF656, PF6320 and PF6520 (produced by OMNOVA), and FTX-204G, 208G, 218G, 230G, 204D, 208D, 212D, 218D and 222D (produced by NEOS). Further, polysiloxane polymer KP-341 (produced by Shin-Etsu Chemical Co., Ltd.) can be employed as the siliconized surfactant.

As the surfactant, besides the above publicly known surfactants, use can be made of a surfactant based on a polymer having a fluorinated aliphatic group derived from a fluorinated aliphatic compound, produced by a telomerization technique (also called a telomer process) or an oligomerization technique (also called an oligomer process). The fluorinated aliphatic compound can be synthesized by the process described in JP-A-2002-90991.

The polymer having a fluorinated aliphatic group is preferably a copolymer from a monomer having a fluorinated aliphatic group and a poly(oxyalkylene) acrylate and/or poly(oxyalkylene) methacrylate, which copolymer may have an irregular distribution or may result from block copolymerization. As the poly(oxyalkylene) group, there can be mentioned a poly(oxyethylene) group, a poly(oxypropylene) group, a poly(oxybutylene) group or the like. Further, use can be made of a unit having alkylene groups of different chain lengths in a single chain, such as poly(oxyethylene-oxypropylene-oxyethylene block concatenation) or poly(oxyethylene-oxypropylene block concatenation). Moreover, the copolymer from a monomer having a fluorinated aliphatic group and a poly(oxyalkylene) acrylate(or methacrylate) is not limited to two-monomer copolymers and may be a three or more monomer copolymer obtained by simultaneous copolymerization of two or more different monomers having a fluorinated aliphatic group, two or more different poly(oxyalkylene) acrylates (or methacrylates), etc.

For example, as a commercially available surfactant, there can be mentioned Megafac F178, F-470, F-473, F-475, F-476 or F-472 (produced by Dainippon Ink & Chemicals, Inc.). Further, there can be mentioned a copolymer from an acrylate (or methacrylate) having a C₆F₁₃ group and a poly(oxyalkylene) acrylate (or methacrylate), a copolymer from an acrylate (or methacrylate) having a C₃F₇ group, poly(oxyethylene) acrylate (or methacrylate) and poly(oxypropylene) acrylate (or methacrylate), or the like.

In the present invention, surfactants other than the fluorinated and/or siliconized surfactants can also be employed. In particular, there can be mentioned, for example, nonionic surfactants including a polyoxyethylene alkyl ether such as polyoxyethylene lauryl ether, polyoxyethylene stearyl ether, polyoxyethylene cetyl ether or polyoxyethylene oleyl ether, a polyoxyethylene alkylaryl ether such as polyoxyethylene octylphenol ether or polyoxyethylene nonylphenol ether, a polyoxyethylene-polyoxypropylene block copolymer, a sorbitan fatty acid ester such as sorbitan monolaurate, sorbitan monopalmitate, sorbitan monostearate, sorbitan monooleate, sorbitan trioleate or sorbitan tristearate, a polyoxyethylene sorbitan fatty acid ester such as polyoxyethylene sorbitan monolaurate, polyoxyethylene sorbitan monopalmitate, polyoxyethylene sorbitan monostearate, polyoxyethylene sorbitan trioleate or polyoxyethylene sorbitan tristearate, or the like

These surfactants may be used either individually or in combination.

The amount of each surfactant used is preferably in the range of 0.0001 to 2 mass %, more preferably 0.001 to 1 mass % based on the total mass of the positive resist composition (excluding the solvent).

[5] Solvent

The solvent is not limited as long as it can be used in the preparation of a positive resist composition through dissolution of the above-mentioned components. As the solvent, there can be mentioned, for example, an organic solvent, such as an alkylene glycol monoalkyl ether carboxylate, an alkylene glycol monoalkyl ether, an alkyl lactate, an alkyl alkoxypropionate, a cyclolactone (preferably having 4 to 10 carbon atoms), an optionally cyclized monoketone compound (preferably having 4 to 10 carbon atoms), an alkylene carbonate, an alkyl alkoxyacetate or an alkyl pyruvate.

As preferred alkylene glycol monoalkyl ether carboxylates, there can be mentioned, for example, propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate and ethylene glycol monoethyl ether acetate.

As preferred alkylene glycol monoalkyl ethers, there can be mentioned, for example, propylene glycol monomethyl ether, propylene glycol monoethyl ether, propylene glycol monopropyl ether, propylene glycol monobutyl ether, ethylene glycol monomethyl ether and ethylene glycol monoethyl ether.

As preferred alkyl lactates, there can be mentioned, for example, methyl lactate, ethyl lactate, propyl lactate and butyl lactate.

As preferred alkyl alkoxypropionates, there can be mentioned, for example, ethyl 3-ethoxypropionate, methyl 3-methoxypropionate, methyl 3-ethoxypropionate and ethyl 3-methoxypropionate.

As preferred cyclolactones, there can be mentioned, for example, β-propiolactone, β-butyrolactone, γ-butyrolactone, α-methyl-γ-butyrolactone, β-methyl-γ-butyrolactone, γ-valerolactone, γ-caprolactone, γ-octanoic lactone and α-hydroxy-γ-butyrolactone.

As preferred optionally cyclized monoketone compounds, there can be mentioned, for example, 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone and 3-methylcycloheptanone.

As preferred alkylene carbonates, there can be mentioned, for example, propylene carbonate, vinylene carbonate, ethylene carbonate and butylene carbonate.

As preferred alkyl alkoxyacetates, there can be mentioned, for example, acetic acid 2-methoxyethyl ester, acetic acid 2-ethoxyethyl ester, acetic acid 2-(2-ethoxyethoxy)ethyl ester, acetic acid 3-methoxy-3-methylbutyl ester and acetic acid 1-methoxy-2-propyl ester.

As preferred alkyl pyruvates, there can be mentioned, for example, methyl pyruvate, ethyl pyruvate and propyl pyruvate.

As a preferably employable solvent, there can be mentioned a solvent having a boiling point of 130° C. or above measured at ordinary temperature under ordinary pressure. For example, there can be mentioned cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, acetic acid 2-ethoxyethyl ester, acetic acid 2-(2-ethoxyethoxy)ethyl ester or propylene carbonate.

In the present invention, these solvents may be used either individually or in combination.

In the present invention, a mixed solvent consisting of a mixture of a solvent having a hydroxyl group in its structure and a solvent having no hydroxyl group may be used as the organic solvent.

As the solvent having a hydroxyl group, there can be mentioned, for example, ethylene glycol, ethylene glycol monomethyl ether, ethylene glycol monoethyl ether, propylene glycol, propylene glycol monomethyl ether, propylene glycol monoethyl ether, ethyl lactate or the like. Of these, propylene glycol monomethyl ether and ethyl lactate are especially preferred.

As the solvent having no hydroxyl group, there can be mentioned, for example, propylene glycol monomethyl ether acetate, ethyl ethoxypropionate, 2-heptanone, γ-butyrolactone, cyclohexanone, butyl acetate, N-methylpyrrolidone, N,N-dimethylacetamide, dimethyl sulfoxide or the like. Of these, propylene glycol monomethyl ether acetate, ethyl ethoxypropionate, 2-heptanone, γ-butyrolactone, cyclohexanone and butyl acetate are especially preferred. Propylene glycol monomethyl ether acetate, ethyl ethoxypropionate and 2-heptanone are most preferred.

The mixing ratio (mass) of a solvent having a hydroxyl group and a solvent having no hydroxyl group is in the range of 1/99 to 99/1, preferably 10/90 to 90/10 and more preferably 20/80 to 60/40. The mixed solvent containing 50 mass % or more of a solvent having no hydroxyl group is especially preferred from the viewpoint of uniform applicability.

It is preferred for the solvent to be a mixed solvent consisting of two or more solvents containing propylene glycol monomethyl ether acetate.

3. Second Resist

Among those described above as the first resist, an appropriate one can be employed as the second resist for use in the formation of the second resist pattern. However, it is preferred to use in the second resist substantially the same resin as employed in the first resist from the viewpoint of allowing the dry etching resistance of the second resist pattern to be equivalent to that of the first resist pattern. Further, from the viewpoint of allowing the first resist and the second resist to form patterns of substantially the same characteristics through a practical semiconductor device mask having patterns of various sizes and configurations, it is most preferred that the first resist and the second resist consist of exactly the same resists.

4. Method of Forming Double Pattern

<Formation of First Resist Pattern>

In the present invention, the first resist composition in the use thereof is first filtered and then applied onto the following given support. The filter medium for use in the filtration preferably consists of a polytetrafluoroethylene, polyethylene or nylon having a pore size of 0.1 μm or less, especially 0.05 μm or less and more especially 0.03 μm or less.

The resist composition having been filtered is applied onto a substrate, such as one for use in the production of precision integrated circuit elements (e.g., silicon/silicon dioxide coating), by appropriate application means, such as a spinner or coater, and dried to thereby form a resist film. In the stage of drying, it is preferred to perform heating (prebake). The thickness of the resist film is preferably regulated so as to fall within the range of 50 to 200 nm, more preferably 70 to 180 nm.

When the resist composition is applied by a spinner, the rotating speed thereof is generally in the range of 500 to 3000 rpm, preferably 800 to 2000 rpm and more preferably 1000 to 1500 rpm.

Prior to the formation of the resist film, the substrate may be coated with an antireflection film.

As the antireflection film, use can be made of not only an inorganic film of titanium, titanium dioxide, titanium nitride, chromium oxide, carbon, amorphous silicon or the like but also an organic film composed of a light absorber and a polymer material. Also, as the organic antireflection film, use can be made of any of commercially available organic antireflection films, such as the DUV30 Series and DUV40 Series produced by Brewer Science Inc., and AR-2, AR-3 and AR-5 produced by Shipley Co., Ltd.

[Dry Exposure System]

The resist film is exposed through a given mask to actinic rays or radiation, preferably baked (heated), and developed and rinsed. Accordingly, a desirable pattern can be obtained.

As the actinic rays or radiation, there can be mentioned infrared rays, visible light, ultraviolet rays, far ultraviolet rays, X-rays, electron beams or the like. Of them, preferred use is made of far ultraviolet rays of especially 250 nm or less, more especially 220 nm or less and still more especially 1 to 200 nm wavelength. In particular, an ArF excimer laser, an F₂ excimer laser, EUV (13 nm) and electron beams are preferred. An ArF excimer laser is more preferred.

[Liquid Immersion Exposure]

At the time of irradiation with actinic rays or radiation, exposure (liquid immersion exposure) may be carried out after filling the interstice between resist film and lens with a liquid (liquid immersion medium, liquid for liquid immersion) of refractive index higher than that of air. This would bring about an enhancement of resolving power. Any liquid with a refractive index higher than that of air can be employed as the liquid immersion medium. Preferably, pure water is employed.

The liquid for liquid immersion for use in the liquid immersion exposure will now be described.

The liquid for liquid immersion preferably consists of a liquid being transparent in exposure wavelength whose temperature coefficient of refractive index is as low as possible so as to ensure minimization of any distortion of optical image projected on the resist film. Especially in the use of an ArF excimer laser (wavelength: 193 nm) as an exposure light source, however, it is more preferred to use water from not only the above viewpoints but also the viewpoints of easy procurement and easy handling.

Further, from the viewpoint of refractive index increase, use can be made of a medium of 1.5 or higher refractive index. Such a medium may be an aqueous solution or an organic solvent.

In the use of water as a liquid for liquid immersion, a slight proportion of additive (liquid) that would not dissolve the resist film on a wafer and would be negligible with respect to its influence on an optical coat for an under surface of lens element may be added in order to not only decrease the surface tension of water but also increase a surface activating power. The additive is preferably an aliphatic alcohol with a refractive index approximately equal to that of water, for example, methyl alcohol, ethyl alcohol, isopropyl alcohol or the like. The addition of an alcohol with a refractive index approximately equal to that of water is advantageous in that even when the alcohol component is evaporated from water to thereby cause a change of content concentration, the change of refractive index of the liquid as a whole can be minimized. On the other hand, when a substance being opaque in 193 nm rays or an impurity whose refractive index is greatly different from that of water is mixed therein, the mixing would invite a distortion of optical image projected on the resist film. Accordingly, it is preferred to use distilled water as the liquid immersion water. Furthermore, use may be made of pure water having been filtered through an ion exchange filter or the like.

Desirably, the electrical resistance of the water is 18.3 MQcm or higher, and the TOC (organic matter concentration) thereof is 20 ppb or below. Prior deaeration of the water is desired.

Raising the refractive index of the liquid for liquid immersion would enable an enhancement of lithography performance. From this viewpoint, an additive suitable for refractive index increase may be added to the water, or heavy water (D₂O) may be used in place of water.

In the exposure of the resist film of the photosensitive resist composition of the present invention via the liquid immersion medium, a hydrophobic resin (HR) may be further added according to necessity. This would bring about uneven localization of the hydrophobic resin (HR) on the surface layer of the resist film. When the liquid immersion medium is water, there would be attained an improvement of receding contact angle on the surface of the resist film with reference to water upon formation of the resist film, and accordingly an enhancement of the liquid immersion water tracking property. Although the hydrophobic resin (HR) is not particularly limited as long as an improvement of receding contact angle on the surface is realized by the addition thereof, it is preferred to employ a resin having at least either a fluorine atom or a silicon atom. The receding contact angle of the resist film is preferably in the range of 60° to 90°, more preferably 70° or higher. The amount of resin added can be appropriately regulated so that the receding contact angle of the resist film falls within the above range. However, the addition amount is preferably in the range of 0.1 to 10 mass %, more preferably 0.1 to 5 mass % based on the total solids of the positive resist composition. Although the hydrophobic resin (HR) is unevenly localized on the interface as aforementioned, differing from the surfactant, the hydrophobic resin does not necessarily have to have a hydrophilic group in its molecule and does not need to contribute toward uniform mixing of polar/nonpolar substances.

The receding contact angle refers to a contact angle determined when the contact line at a droplet-substrate interface draws back. It is generally known that the receding contact angle is useful in the simulation of droplet mobility in a dynamic condition. In a simple definition, the receding contact angle can be defined as the contact angle exhibited at the recession of the droplet interface at the time of, after application of a droplet discharged from a needle tip onto a substrate, re-indrawing the droplet into the needle. Generally, the receding contact angle can be measured according to a method of contact angle measurement known as the dilation/contraction method.

In the operation of liquid immersion exposure, it is needed for the liquid for liquid immersion to move on a wafer while tracking the movement of an exposure head involving high-speed scanning on the wafer and thus forming an exposure pattern. Therefore, the contact angle of the liquid for liquid immersion with respect to the resist film in dynamic condition is important, and it is required for the resist to be capable of tracking the high-speed scanning of the exposure head without leaving any droplets.

The fluorine atom or silicon atom of the hydrophobic resin (HR) may be present in the principal chain of the resin or may be a substituent on the side chain thereof.

The hydrophobic resin (HR) is preferably a resin having an alkyl group containing a fluorine atom, a cycloalkyl group containing a fluorine atom or an aryl group containing a fluorine atom as a partial structure containing a fluorine atom.

The alkyl group containing a fluorine atom (preferably having 1 to 10 carbon atoms, more preferably 1 to 4 carbon atoms) is a linear or branched alkyl group having at least one hydrogen atom thereof substituted with a fluorine atom. Further, other substituents may be possessed.

The cycloalkyl group containing a fluorine atom is a cycloalkyl group of a single ring or multiple rings having at least one hydrogen atom thereof substituted with a fluorine atom. Further, other substituents may be contained.

As the aryl group containing a fluorine atom, there can be mentioned one having at least one hydrogen atom of an aryl group, such as a phenyl or naphthyl group, substituted with a fluorine atom. Further, other substituents may be contained.

As preferred alkyl groups containing a fluorine atom, cycloalkyl groups containing a fluorine atom and aryl groups containing a fluorine atom, there can be mentioned groups of the following general formulae (F2) to (F4), which however in no way limit the scope of the present invention.

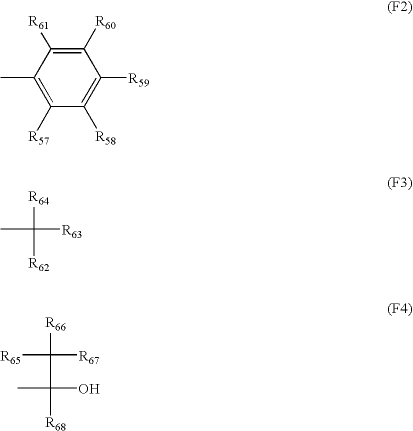

In the general formulae (F2) to (F4), each of R₅₇ to R₆₈ independently represents a hydrogen atom, a fluorine atom or an alkyl group, provided that at least one of each of R₅₇-R₆₁, R₆₂-R₆₄ and R₆₅-R₆₈ represents a fluorine atom or an alkyl group (preferably having 1 to 4 carbon atoms) having at least one hydrogen atom thereof substituted with a fluorine atom. It is preferred that all of R₅₇-R₆₁ and R₆₅-R₆₇ represent fluorine atoms. Each of R₆₂, R₆₃ and R₆₈ preferably represents an alkyl group (especially having 1 to 4 carbon atoms) having at least one hydrogen atom thereof substituted with a fluorine atom, more preferably a perfluoroalkyl group having 1 to 4 carbon atoms. R₆₂ and R₆₃ may be bonded with each other to thereby form a ring.

Specific examples of the groups of the general formula (F2) include a p-fluorophenyl group, a pentafluorophenyl group, a 3,5-di(trifluoromethyl)phenyl group and the like.

Specific examples of the groups of the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

Specific examples of the groups of the general formula (F4) include —C(CF₃)₂OH, —C(C₂F₅)₂OH, —C(CF₃)(CF₃)OH, —CH(CF₃)OH and the like. —C(CF₃)₂OH is preferred.

Specific examples of the repeating units having a fluorine atom will be shown below, which however in no way limit the scope of the present invention.

In the specific examples, X₁ represents a hydrogen atom, —CH₃, —F or —CF₃.

X₂ represents —F or —CF₃.

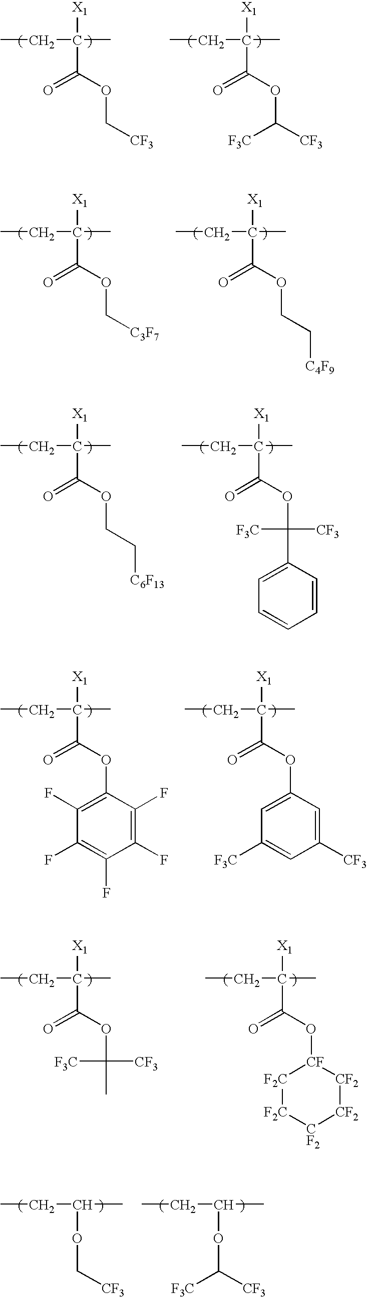

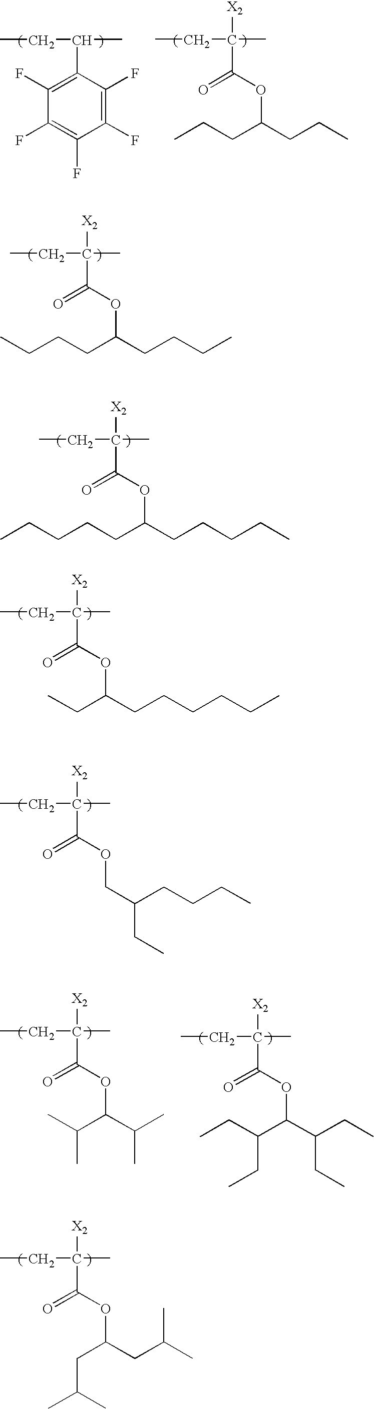

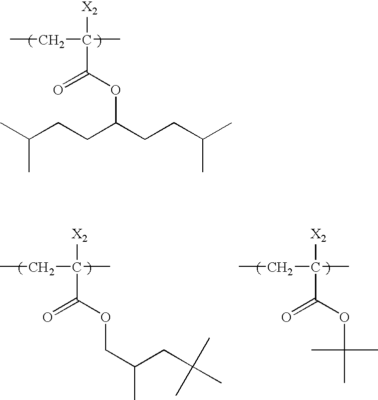

The hydrophobic resin (HR) is preferably a resin having an alkylsilyl structure (preferably a trialkylsilyl group) or a cyclosiloxane structure as a partial structure having a silicon atom.

As the alkylsilyl structure or cyclosiloxane structure, there can be mentioned, for example, any of the groups of the following general formulae (CS-1) to (CS-3) or the like.

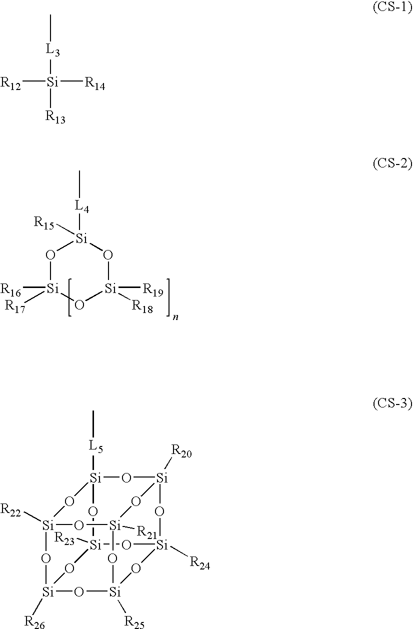

In the general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

Each of L₃ to L₅ represents a single bond or a bivalent connecting group. As the bivalent connecting group, there can be mentioned any one or a combination of two or more groups selected from the group consisting of an alkylene group, a phenylene group, an ether group, a thioether group, a carbonyl group, an ester group, an amido group, a urethane group and a urea group.

n is an integer of 1 to 5.

Specific examples of the repeating units having the groups of the general formulae (CS-1) to (CS-3) will be shown below, which however in no way limit the scope of the present invention.

In the specific examples, X₁ represents a hydrogen atom, —CH₃, —F or —CF₃.

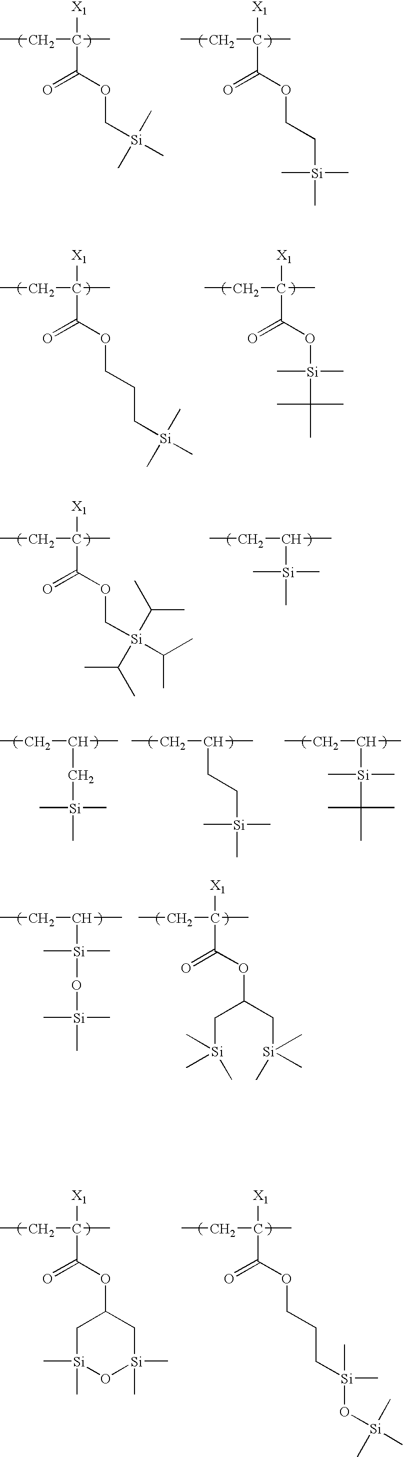

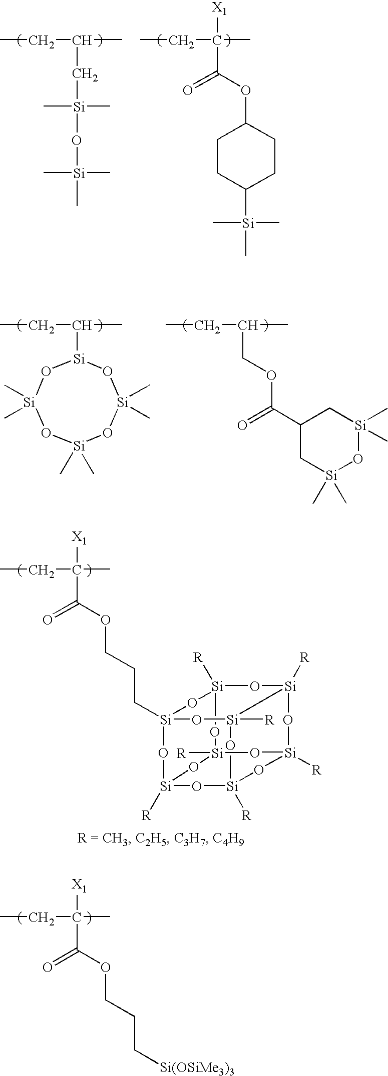

Moreover, the hydrophobic resin (HR) may have at least one group selected from among the following groups (x) to (z):

(x) an alkali soluble group,

(y) a group that is decomposed by the action of an alkali developer, resulting in an increase of solubility in the alkali developer, and

(z) a group that is decomposed by the action of an acid.

As the alkali soluble group (x), there can be mentioned a phenolic hydroxyl group, a carboxylate group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali soluble groups, there can be mentioned a fluoroalcohol group (preferably hexafluoroisopropanol), a sulfonimido group and a bis(carbonyl)methylene group.

As the repeating unit having an alkali soluble group (x), preferred use is made of any of a repeating unit resulting from direct bonding of an alkali soluble group to the principal chain of a resin like a repeating unit of acrylic acid or methacrylic acid, a repeating unit resulting from bonding, via a connecting group, of an alkali soluble group to the principal chain of a resin and a repeating unit resulting from polymerization with the use of a chain transfer agent or polymerization initiator having an alkali soluble group to thereby introduce the same in a polymer chain terminal.

The content of repeating units having an alkali soluble group (x) is preferably in the range of 1 to 50 mol %, more preferably 3 to 35 mol % and still more preferably 5 to 20 mol % based on all the repeating units of the polymer.

Specific examples of the repeating units having an alkali soluble group (x) will be shown below, which however in no way limit the scope of the present invention.

In the formulae, Rx represents H, CH₃, CF₃ or CH₂OH.

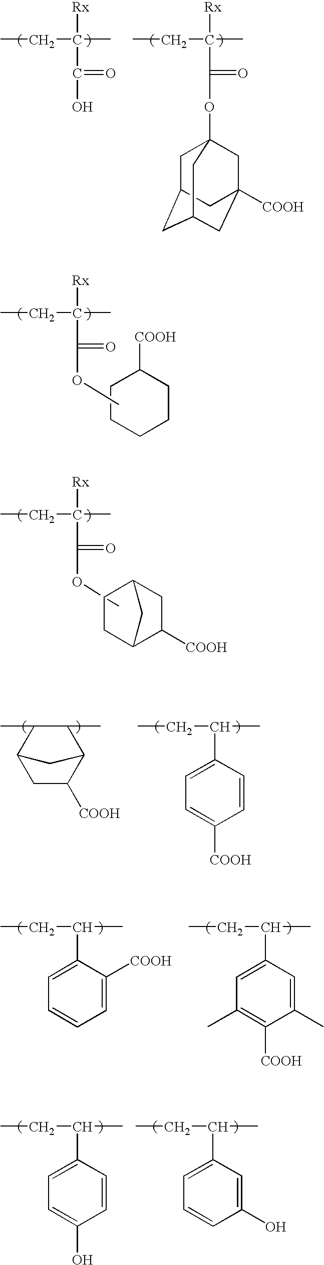

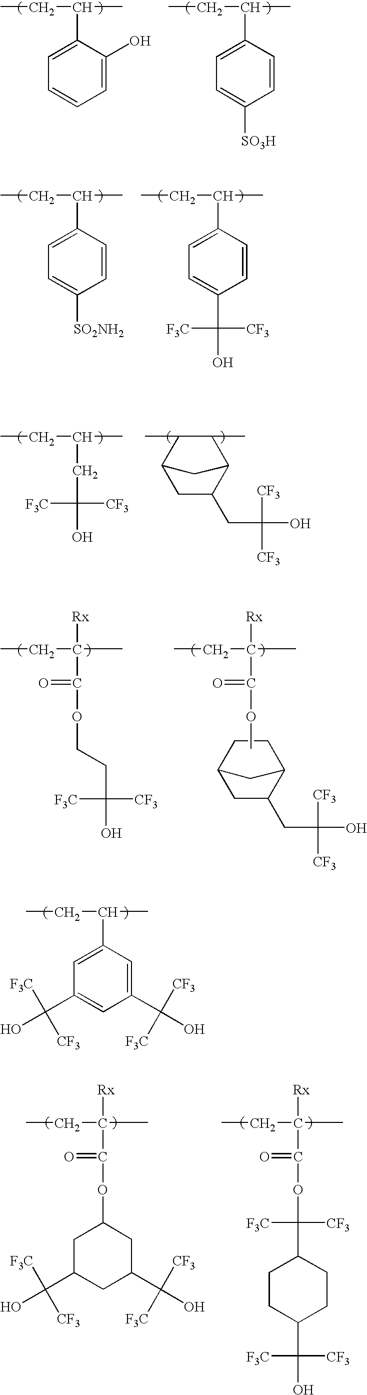

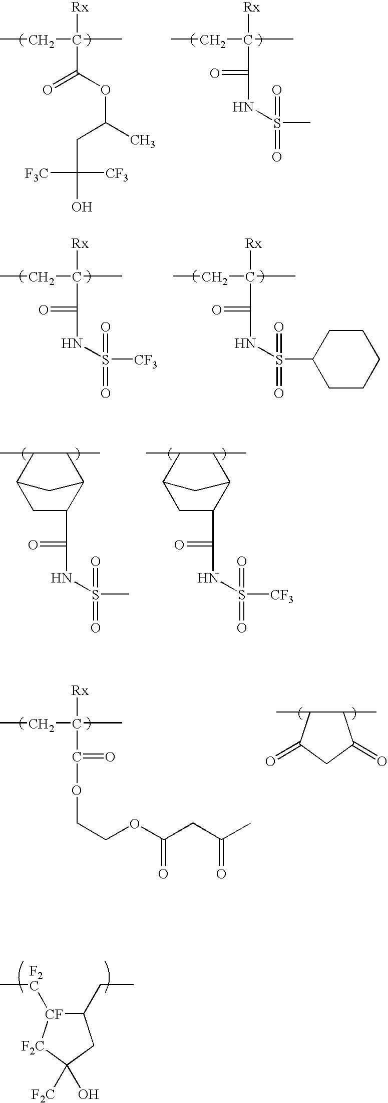

As the group (y) that is decomposed by the action of an alkali developer, resulting in an increase of solubility in the alkali developer, there can be mentioned, for example, a group having a lactone structure, an acid anhydride group, an acid imide group or the like. A group having a lactone structure is preferred.

As the repeating unit having a group (y) that is decomposed by the action of an alkali developer, resulting in an increase of solubility in the alkali developer, preferred use is made of both of a repeating unit resulting from bonding of a group (y) that is decomposed by the action of an alkali developer, resulting in an increase of solubility in the alkali developer, to the principal chain of a resin such as a repeating unit of acrylic ester or methacrylic ester, and a repeating unit resulting from polymerization with the use of a chain transfer agent or polymerization initiator having a group (y) resulting in an increase of solubility in an alkali developer to thereby introduce the same in a polymer chain terminal.

The content of repeating units having a group (y) resulting in an increase of solubility in an alkali developer is preferably in the range of 1 to 40 mol %, more preferably 3 to 30 mol % and still more preferably 5 to 15 mol % based on all the repeating units of the polymer.

As specific examples of the repeating units having a group (y) resulting in an increase of solubility in an alkali developer, there can be mentioned those similar to the repeating units having a lactone structure set forth with respect to the resins as the component (A).

As the repeating unit having a group (z) that is decomposed by the action of an acid in the hydrophobic resin (HR), there can be mentioned those similar to the repeating units having an acid decomposable group set forth with respect to the resin (A). The content of repeating units having a group (z) that is decomposed by the action of an acid in the hydrophobic resin (HR) is preferably in the range of 1 to 80 mol %, more preferably 10 to 80 mol % and still more preferably 20 to 60 mol % based on all the repeating units of the polymer.

The hydrophobic resin (HR) may further have any of the repeating units of the following general formula (IV).

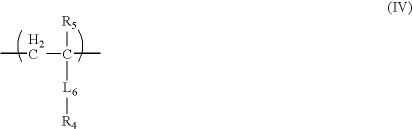

In the general formula (IV),

R₅ represents a hydrogen atom or optionally substituted alkyl group.

R₄ represents a group having any of an alkyl group, a cycloalkyl group, an alkenyl group and a cycloalkenyl group.

L₆ represents a single bond or a bivalent connecting group.

In the general formula (IV), the alkyl group represented by RS is preferably a methyl group. As a preferred substituent optionally contained in the alkyl group, there can be mentioned a hydroxyl group, a fluorine atom or the like.

The alkyl group represented by R₄ is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The bivalent connecting group represented by L₆ is preferably an alkylene group (preferably having 1 to 5 carbon atoms) or an oxy group.

When the hydrophobic resin (HR) has a fluorine atom, the content of fluorine atom(s) is preferably in the range of 5 to 80 mass %, more preferably 10 to 80 mass %, based on the molecular weight of the hydrophobic resin (HR). The repeating unit containing a fluorine atom preferably exists in the hydrophobic resin (HR) in an amount of 10 to 100 mass %, more preferably 30 to 100 mass %.

When the hydrophobic resin (HR) has a silicon atom, the content of silicon atom(s) is preferably in the range of 2 to 50 mass %, more preferably 2 to 30 mass %, based on the molecular weight of the hydrophobic resin (HR). The repeating unit containing a silicon atom preferably exists in the hydrophobic resin (HR) in an amount of 10 to 100 mass %, more preferably 20 to 100 mass %.

The weight average molecular weight of the hydrophobic resin (HR) in terms of standard polystyrene molecular weight is preferably in the range of 1000 to 100,000, more preferably 1000 to 50,000 and still more preferably 2000 to 15,000.

Impurities, such as metals, should naturally be of low quantity in the hydrophobic resin (HR), as for the resin as the component (A). The content of residual monomers and oligomer components is preferably 0 to 10 mass %, more preferably 0 to 5 mass % and still more preferably 0 to 1 mass %. Accordingly, there can be obtained a resist being free from a change of in-liquid foreign matter, sensitivity, etc. over time. From the viewpoint of resolving power, resist profile, side wall of resist pattern, roughness, etc., the molecular weight distribution (Mw/Mn, also referred to as the degree of dispersal) thereof is preferably in the range of 1 to 5, more preferably 1 to 3 and still more preferably 1 to 2.

A variety of commercially available products can be used as the hydrophobic resin (HR), and also the resin can be synthesized in accordance with conventional methods (for example, radical polymerization). As general synthesizing methods, there can be mentioned, for example, a batch polymerization method in which a monomer species and an initiator are dissolved in a solvent and heated to thereby carry out polymerization, a dropping polymerization method in which a solution of monomer species and initiator is dropped into a hot solvent over a period of 1 to 10 hours, and the like. The dropping polymerization method is preferred. As a reaction solvent, there can be mentioned, for example, an ether such as tetrahydrofuran, 1,4-dioxane or diisopropyl ether, a ketone such as methyl ethyl ketone or methyl isobutyl ketone, an ester solvent such as ethyl acetate, an amide solvent such as dimethylformamide or dimethylacetamide, or the after-mentioned solvent capable of dissolving the composition of the present invention, such as propylene glycol monomethyl ether acetate, propylene glycol monomethyl ether or cyclohexanone. Preferably, the polymerization is carried out with the use of the same solvent as that used in the positive resist composition of the present invention. This would inhibit any particle generation during storage.

The polymerization reaction is preferably carried out in an atmosphere consisting of an inert gas, such as nitrogen or argon. In the initiation of polymerization, a commercially available radical initiator (azo initiator, peroxide, etc.) is used as the polymerization initiator. Among the radical initiators, an azo initiator is preferred, and azo initiators having an ester group, a cyano group and a carboxyl group are more preferred. As specific preferred initiators, there can be mentioned azobisisobutyronitrile, azobisdimethylvaleronitrile, dimethyl 2,2′-azobis(2-methylpropionate) and the like. The reaction concentration is in the range of 5 to 50 mass %, preferably 30 to 50 mass %. The reaction temperature is generally in the range of 10° to 150° C., preferably 30° to 120° C. and more preferably 60° to 100° C.

After the completion of the reaction, the mixture is allowed to stand still to cool to room temperature and purified. In the purification, use is made of routine methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to thereby coagulate the resin in the poor solvent and thus remove residual monomers, etc. and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to thereby precipitate the resin as a solid.

The solvent for use in the operation of precipitation or re-precipitation from a polymer solution (precipitation or re-precipitation solvent) is not limited as long as the solvent is a poor solvent for the polymer. According to the type of polymer, use can be made of any one appropriately selected from among a hydrocarbon, a halogenated hydrocarbon, a nitro compound, an ether, a ketone, an ester, a carbonate, an alcohol, a carboxylic acid, water, a mixed solvent containing these solvents and the like. Of these, it is preferred to employ a solvent containing at least an alcohol (especially methanol or the like) or water as the precipitation or re-precipitation solvent.

The amount of precipitation or re-precipitation solvent used is generally in the range of 100 to 10,000 parts by mass, preferably 200 to 2000 parts by mass and more preferably 300 to 1000 parts by mass per 100 parts by mass of the polymer solution, according to intended efficiency, yield, etc.

The temperature at which the precipitation or re-precipitation is carried out is generally in the range of about 0° to 50° C., preferably about room temperature (for example, about 20° to 35° C.), according to efficiency and operation easiness. The operation of precipitation or re-precipitation can be carried out by a publicly known method, such as a batch or continuous method, with the use of a common mixing vessel, such as an agitation vessel.

The polymer obtained by the precipitation or re-precipitation is generally subjected to common solid/liquid separation, such as filtration or centrifugal separation, and dried before use. The filtration is carried out with the use of a filter medium ensuring solvent resistance, preferably under pressure. The drying is performed at about 30° to 100° C., preferably about 30° to 50° C. at ordinary pressure or reduced pressure (preferably reduced pressure).

Alternatively, after the resin precipitation and separation, the obtained resin may be once more dissolved in a solvent and brought into contact with a solvent wherein the resin is poorly soluble or insoluble. Specifically, the method may include the steps of, after the completion of the radical polymerization reaction, bringing the polymer into contact with a solvent wherein the polymer is poorly soluble or insoluble to thereby precipitate a resin (step a), separating the resin from the solution (step b), re-dissolving the resin in a solvent to thereby obtain a resin solution (A) (step c), thereafter bringing the resin solution (A) into contact with a solvent wherein the resin is poorly soluble or insoluble amounting to less than 10 times (preferably 5 times or less) the volume of the resin solution (A) to thereby precipitate a resin solid (step d) and separating the precipitated resin (step e).

Specific examples of the hydrophobic resins (HR) will be shown below. The following Table 1 shows the molar ratio of individual repeating units (corresponding to individual repeating units in order from the left), weight average molecular weight and degree of dispersal with respect to each of the resins.

TABLE 1

| | |
|---|---|
| | (HR-1) |
| 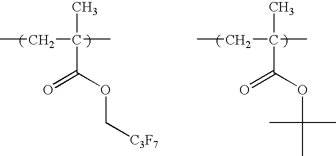 | |
| | (HR-2) |
| 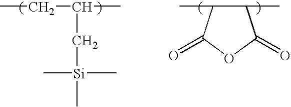 | |
| | (HR-3) |
| 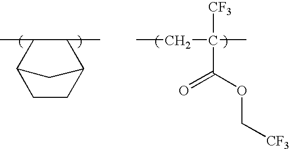 | |
| | (HR-4) |
| 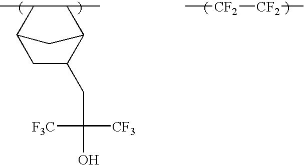 | |
| | (HR-5) |
| 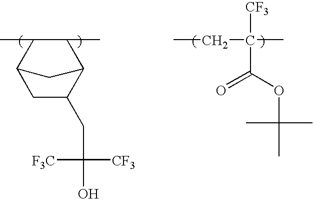 | |
| | (HR-6) |
| 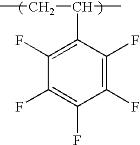 | |
| | (HR-7) |
| 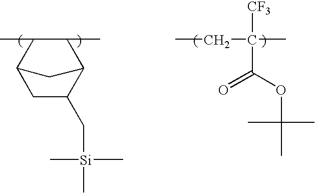 | |
| | (HR-8) |
| 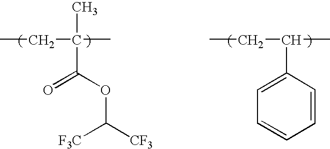 | |
| | (HR-9) |
| 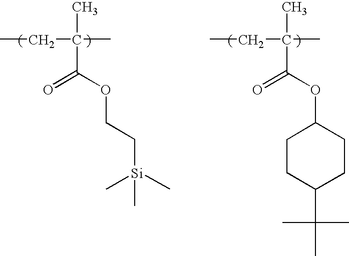 | |
| | (HR-10) |
| 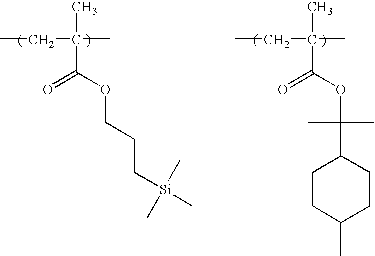 | |
| | (HR-11) |
| 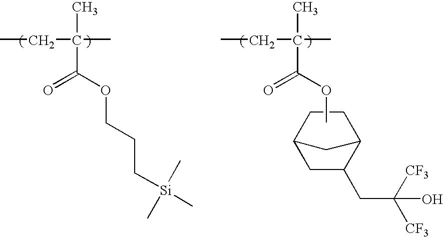 | |
| | (HR-12) |
| 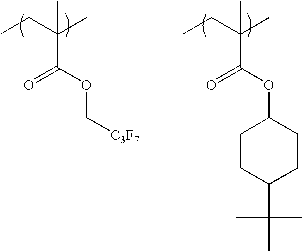 | |
| | (HR-13) |
| 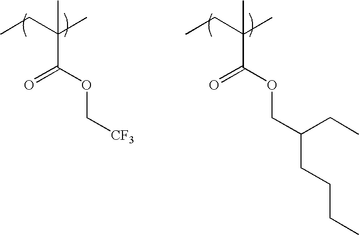 | |
| | (HR-14) |
| 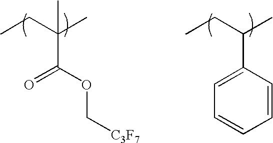 | |
| | (HR-15) |
| 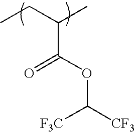 | |
| | (HR-16) |
| 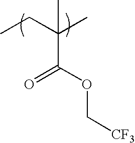 | |
| | (HR-17) |
| 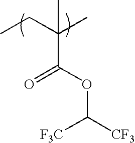 | |
| | (HR-18) |
| 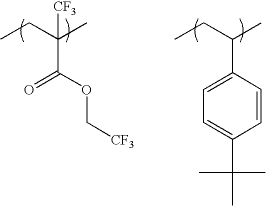 | |
| | (HR-19) |
| 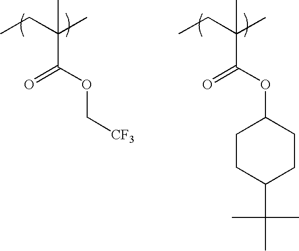 | |
| | (HR-20) |
| 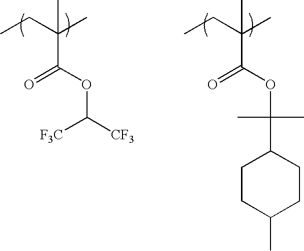 | |
| | (HR-21) |
| 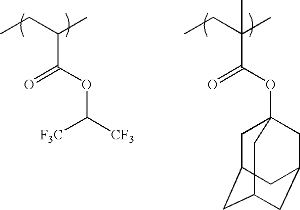 | |
| | (HR-22) |
| 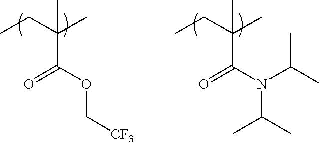 | |
| | (HR-23) |
| 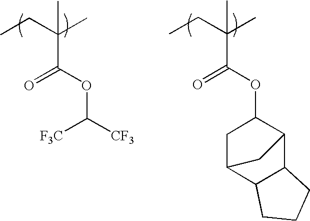 | |
| | (HR-24) |
| 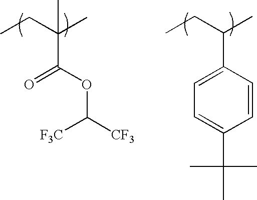 | |
| | (HR-25) |
| 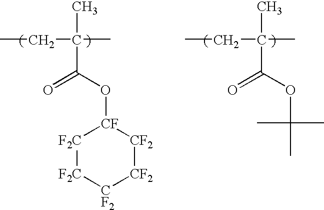 | |
| | (HR-26) |
| 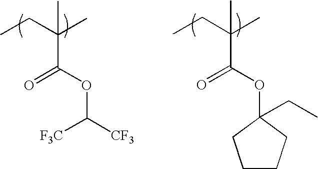 | |
| | (HR-27) |
| 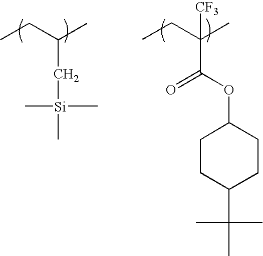 | |
| | (HR-28) |
| 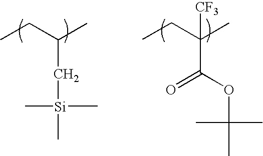 | |
| | (HR-29) |
| 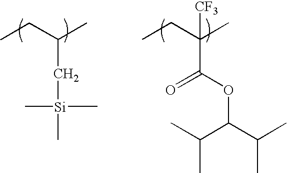 | |
| | (HR-30) |
| 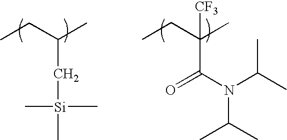 | |
| | (HR-31) |
| 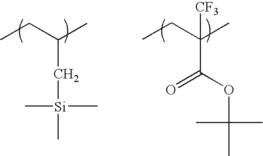 | |
| | (HR-32) |
| 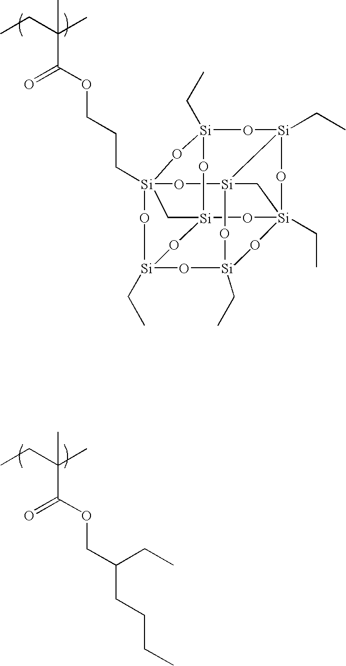 | |
| | (HR-33) |
| 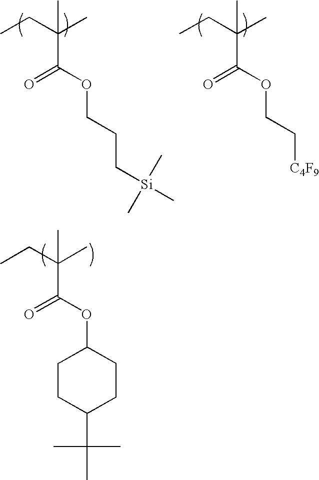 | |
| | (HR-34) |
| 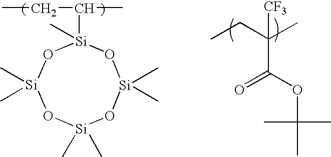 | |
| | (HR-35) |
| 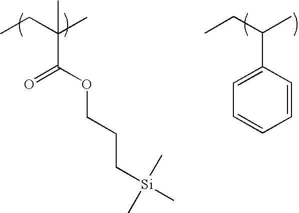 | |
| | (HR-36) |
| 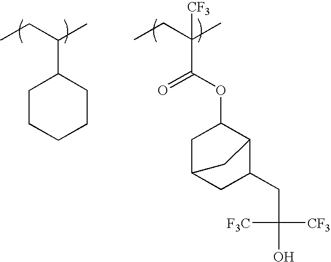 | |
| | (HR-37) |
| 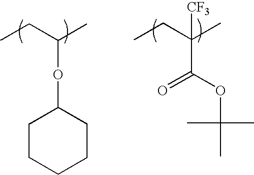 | |
| | (HR-38) |
| 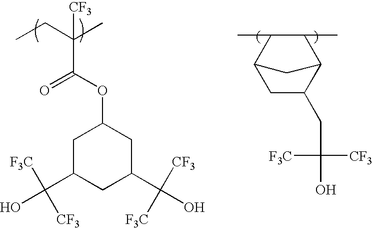 | |
| | (HR-39) |
| 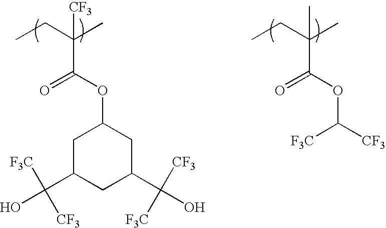 | |
| | (HR-40) |
| 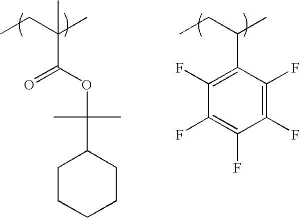 | |
| | (HR-41) |
| 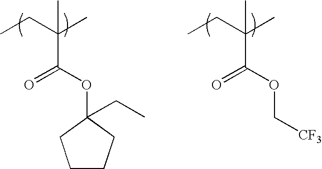 | |
| | (HR-42) |
| 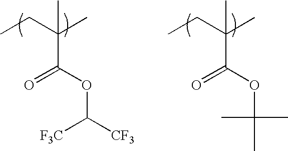 | |
| | (HR-43) |
| 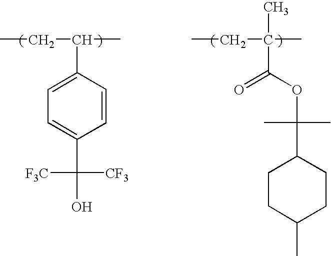 | |
| | (HR-44) |
| 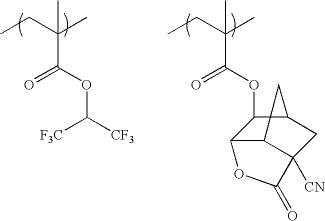 | |
| | (HR-45) |
| 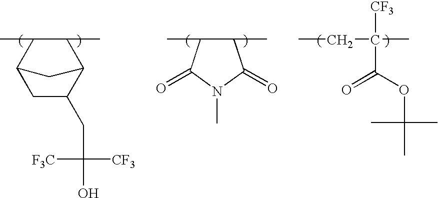 | |
| | (HR-46) |
| 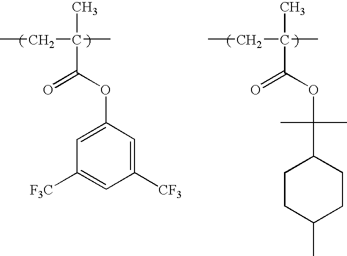 | |
| | (HR-47) |
| 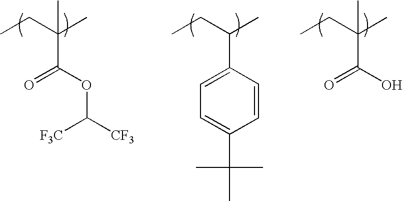 | |
| | (HR-48) |
| 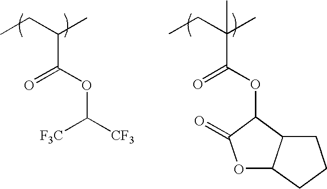 | |
| | (HR-49) |
| 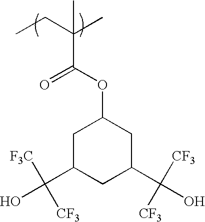 | |
| | (HR-50) |
| 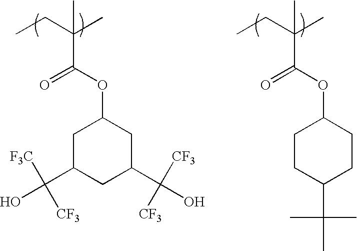 | |
| | (HR-51) |
| 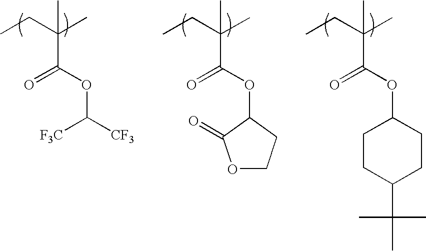 | |
| | (HR-52) |
| 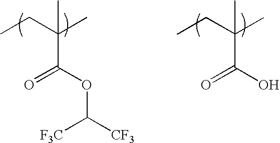 | |
| | (HR-53) |
| 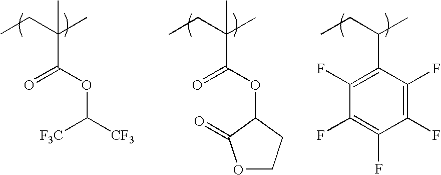 | |
| | (HR-54) |
| 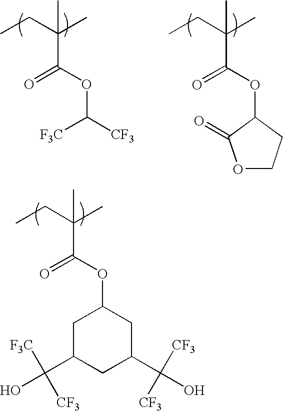 | |
| | (HR-55) |
| 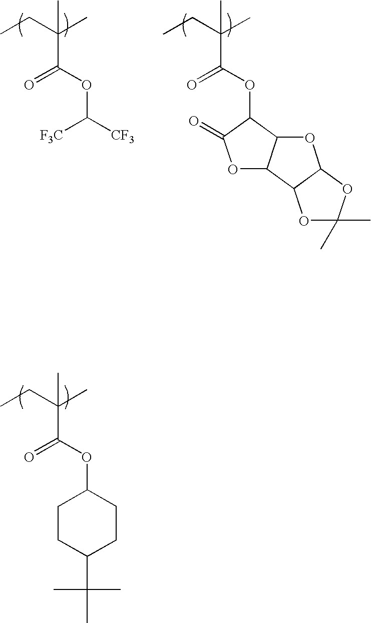 | |
| | (HR-56) |
| 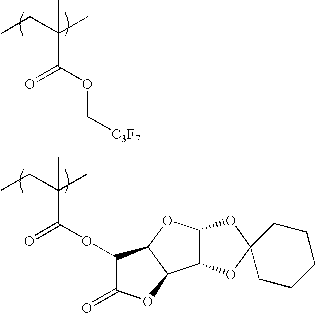 | |
| | (HR-57) |
| 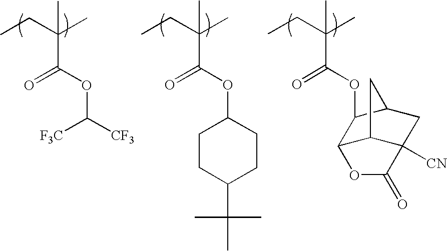 | |
| | (HR-58) |
| 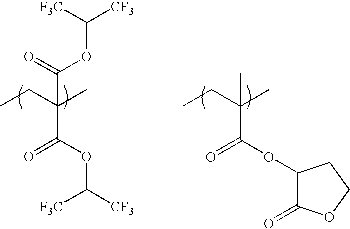 | |
| | (HR-59) |
| 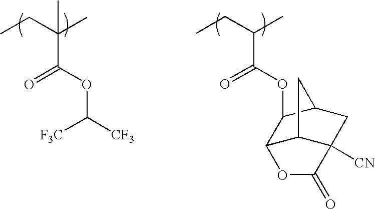 | |
| | (HR-60) |
| 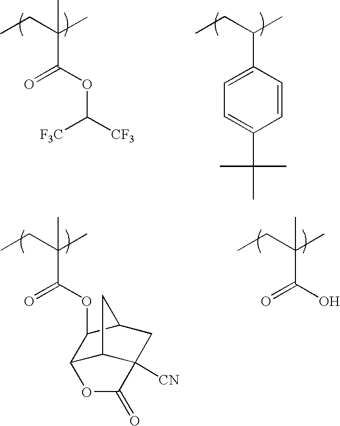 | |
| | (HR-61) |
| 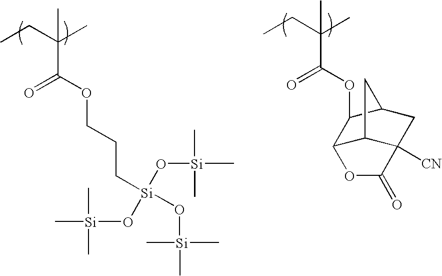 | |
| | (HR-62) |
| 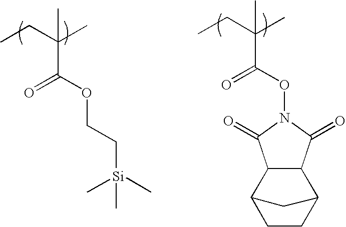 | |
| | (HR-63) |
| 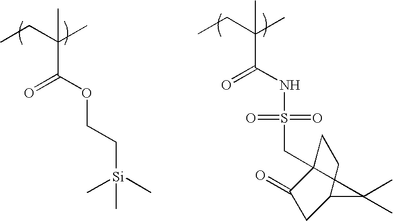 | |
| | (HR-64) |
| 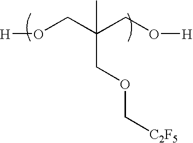 | |
| | (HR-65) |
| 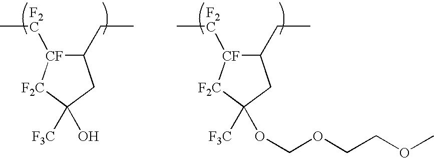 | |

| resin | composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

For the prevention of direct contact of a resist film with a liquid for liquid immersion, a film that is highly insoluble in the liquid for liquid immersion (hereinafter also referred to as a “top coat”) may be provided between the resist film from the positive photosensitive composition of the present invention and the liquid for liquid immersion. The functions to be fulfilled by the top coat are applicability to an upper layer portion of the resist, transparency in radiation of especially 193 nm and being highly insoluble in the liquid for liquid immersion. Preferably, the top coat does not mix with the resist and is uniformly applicable to an upper layer of the resist.

From the viewpoint of 193 nm transparency, the top coat preferably consists of a polymer not abundantly containing an aromatic moiety. As such, there can be mentioned, for example, a hydrocarbon polymer, an acrylic ester polymer, polymethacrylic acid, polyacrylic acid, polyvinyl ether, a siliconized polymer, a fluoropolymer or the like. The aforementioned hydrophobic resins (HR) also find appropriate application in the top coat. From the viewpoint of contamination of an optical lens by leaching of impurities from the top coat into the liquid for liquid immersion, it is preferred to reduce the amount of residual monomer components of the polymer contained in the top coat.

At the detachment of the top coat, use may be made of a developer, or a separate peeling agent may be used. The peeling agent preferably consists of a solvent having a lower permeation into the resist film. Detachability by an alkali developer is preferred from the viewpoint of simultaneous attainment of the detachment step with the development processing step for the resist film. The top coat is preferred to be acidic from the viewpoint of detachment with the use of an alkali developer. However, from the viewpoint of non-intermixability with the resist film, the top coat may be neutral or alkaline.

The less the difference in refractive index between the top coat and the liquid for liquid immersion, the higher the resolving power. In an ArF excimer laser (wavelength: 193 nm), when water is used as the liquid for liquid immersion, the top coat for ArF liquid immersion exposure preferably has a refractive index close to that of the liquid for liquid immersion. From the viewpoint of approximation of the refractive index to that of the liquid for liquid immersion, it is preferred for the top coat to contain a fluorine atom. From the viewpoint of transparency and refractive index, it is preferred to reduce the thickness of the film.

Preferably, the top coat does not mix with the resist film and also does not mix with the liquid for liquid immersion. From this viewpoint, when the liquid for liquid immersion is water, it is preferred for the solvent used in the top coat to be highly insoluble in the solvent used in the positive resist composition and be a non-water-soluble medium. When the liquid for liquid immersion is an organic solvent, the top coat may be soluble or insoluble in water. After the dry exposure or liquid immersion exposure, postbake is preferably performed and followed by development and rinse.

In the development step, an alkali developer is usually employed. As the alkali developer for the resist composition, use can be made of any of alkaline aqueous solutions of an inorganic alkali such as sodium hydroxide, potassium hydroxide, sodium carbonate, sodium silicate, sodium metasilicate or aqueous ammonia, a primary amine such as ethylamine or n-propylamine, a secondary amine such as diethylamine or di-n-butylamine, a tertiary amine such as triethylamine or methyldiethylamine, an alcoholamine such as dimethylethanolamine or triethanolamine, a quaternary ammonium salt such as tetramethylammonium hydroxide or tetraethylammonium hydroxide, a cycloamine such as pyrrole or piperidine, or the like.

Before the use of the above alkali developer, appropriate amounts of an alcohol and a surfactant may be added thereto.

The alkali concentration of the alkali developer is generally in the range of 0.1 to 20 mass %.

The pH value of the alkali developer is generally in the range of 10.0 to 15.0.

Pure water is usually employed as a rinse liquid. Before the use thereof, an appropriate amount of surfactant may be added thereto.

The development operation or rinse operation may be followed by the operation for removing any portion of developer or rinse liquid adhering onto the pattern by the use of a supercritical fluid.

Further, the rinse operation or operation with a supercritical fluid may be followed by the heating operation for removing any water remaining in the pattern.

<Chemical Treatment of First Resist Pattern>

The formation of a first resist pattern by use of the foregoing process is followed by a chemical treatment (freezing treatment) of the first resist pattern by use of the treating agent according to the present invention.

[Washing with Acid]

According to necessity, the step of washing the first resist pattern with a solution containing an acid other than the treating agent of the present invention can be employed as a prestep for the freezing treatment using the treating agent of the present invention. As specific examples of the acids that can be employed in the washing, there can be mentioned an inorganic acid, such as hydrochloric acid, sulfuric acid, nitric acid or phosphoric acid, and an organic acid, such as a carboxylic acid, a sulfonic acid, an imide acid (sulfonylimide acid) or a methide acid. Of these, an organic acid, such as a carboxylic acid, a sulfonic acid, an imide acid or a methide acid, is preferred.

As the carboxylic acid, there can be mentioned, for example, an alkyl carboxylic acid such as acetic acid or propionic acid, a fluoroalkyl carboxylic acid such as a perfluoroalkyl carboxylic acid having 1 to 8 carbon atoms, or an aromatic carboxylic acid such as benzoic acid or pentafluorobenzoic acid.

As the sulfonic acid, there can be mentioned, for example, an alkyl sulfonic acid such as butanesulfonic acid, hexanesulfonic acid or a perfluoroalkyl sulfonic acid having 1 to 8 carbon atoms, or an aromatic sulfonic acid such as p-toluenesulfonic acid or pentafluorobenzenesulfonic acid.

As the imide acid, there can be mentioned, for example, a disulfonylimide acid, such as a bis(alkylsulfonyl)imide acid having 1 to 8 carbon atoms, a bis(perfluoroalkylsulfonyl)imide acid having 1 to 8 carbon atoms, a 5 to 8-membered ring cyclodisulfonylimide acid or a 5 to 8-membered ring cyclodisulfonylimide acid having a fluoroalkylene chain.

As the methide acid, there can be mentioned, for example, a trisulfonylmethide acid, such as a tris(alkylsulfonyl)methide acid having 1 to 8 carbon atoms or a tris(fluoroalkylsulfonyl)methide acid having 1 to 8 carbon atoms.

Of these, a perfluoroalkyl carboxylic acid, a sulfonic acid, an imide acid and a methide acid are preferred. A perfluoroalkyl sulfonic acid, an aromatic sulfonic acid, an imide acid and a methide acid are more preferred.

The solvent of this solution is not limited as long as no portion of the resist pattern is dissolved therein but acids are dissolved therein. For example, there can be mentioned water or any of the solvents for use in the treating agent of the present invention. Preferred use is made of any of the solvents for use in the treating agent of the present invention.

The concentration of acid is in the range of 0.1 to 10 mol %, preferably 0.5 to 5 mol % and more preferably 0.5 to 3 mol %.

In a preferred method of treatment, the acid solution is puddled over the substrate having the first resist pattern formed thereon, and after a while the substrate is rotated to thereby shake off the acid solution. The resultant substrate is washed with a solvent.

The time during which the solution is puddled so as to allow the solution to be in contact with the resist pattern is to be 5 seconds or longer. Generally, the longer the time, the more favorable the treatment effect. However, from the viewpoint of throughput, the time is preferably 3 min or less, more preferably 2 min or less and most preferably 1 min or less.

With respect to the solvent for use in the washing of the substrate with a solvent in order to remove any excess acid from the substrate, it is preferred to employ the same solvent as used in the acid solution.

The washing method for any excess acid is preferably one in which while the substrate is rotated at a speed of 50 to 500 rpm, the solvent is spouted toward the center of the substrate at a flow rate of 0.5 to 5 ml/sec for 5 to 30 seconds and thereafter the substrate is rotated at a speed of 500 to 3000 rpm for 10 to 60 seconds to thereby shake off the solvent. The washing method is not limited to this.

[Chemical Treatment]

The method of chemically treating the first resist pattern by use of the treating agent of the present invention will be described below.

As the method for bringing the treating agent into contact with the resist pattern, there can be mentioned the method in which the resist pattern is immersed in the treating agent and the method in which the treating agent is applied onto the resist pattern.

In the employment of the immersion method, it is preferred to adopt the method in which the treating agent is puddled on the substrate having the first resist pattern formed thereon.

The time during which the treating agent is puddled on the substrate so as to allow the treating agent to be in contact with the resist pattern is to be 5 seconds or longer. Generally, the longer the time, the more favorable the treating effect. However, from the viewpoint of throughput, the time is preferably 3 minutes or less, more preferably 2 minutes or less and most preferably 1 minute or less.

The temperature within the treating apparatus and the temperature of the treating agent can be increased over room temperature in order to ensure progress of the reaction. However, from the viewpoint of safety, the temperature is preferably 50° C. or below.

With respect to the method of applying the treating agent on the resist pattern, spin coating is preferably employed. In the spin coating, preferably, the application of the treating agent is carried out by the method in which while the substrate is rotated at a speed of 50 to 500 rpm, the solvent is spouted toward the center of the substrate at a flow rate of 0.5 to 5 ml/sec for 0.5 to 5 seconds and thereafter the substrate is rotated at a speed of 500 to 3000 rpm for 10 to 60 seconds to thereby shake off any excess portion of the solvent.

In the present invention, in order to progress the reaction between the treating agent of the present invention and the resist pattern, the substrate is preferably heated either after the above immersion/coating or simultaneously with the immersion/coating.

In general, the heating temperature is preferably in the range of 40° C. to 200° C., more preferably 50° C. to 180° C., and most preferably 60° C. to 150° C. The heating time is preferably in the range of 10 to 300 seconds, more preferably 30 to 150 seconds. In the present invention, when the treating agent contains the above inactive polymer or oligomer, a film of the treating agent is formed on the substrate by the above process.

After the reaction between the treating agent and the resist pattern, preferably, the substrate is washed with a solvent in order to remove any excess portion of the treating agent from the substrate. As this solvent, it is preferred to employ pure water, the same solvent as used in the treating agent or the same solvent as used in the first resist. The washing method is preferably one in which first the solvent is puddled on the substrate and allowed to stand still; subsequently while the substrate is rotated at a speed of 50 to 500 rpm, the solvent is spouted toward the center of the substrate at a flow rate of 0.5 to 5 ml/sec for 5 to 30 seconds; and thereafter the substrate is rotated at a speed of 500 to 3000 rpm for 10 to 60 seconds to thereby shake off the solvent. The washing method is not limited to this.

Still further, it is preferred to add a heating step for removing any remaining portion of the washing solvent. The heating temperature is preferably in the range of 60° to 200° C., more preferably 70° to 170° C. and most preferably 80° to 150° C. The heating time is preferably in the range of 30 to 120 seconds, more preferably 40 to 100 seconds. The solvent removal may be carried out by blowing an inert gas, such as nitrogen gas, over the substrate in place of the heating.

<Formation of Second Resist Pattern>

In the present invention, the second resist composition for use is filtered and applied onto the substrate provided with the first resist pattern that has undergone the chemical treatment. The filtration is the same as in the first resist pattern.

The second resist composition is applied onto the first resist pattern having undergone the chemical treatment (freezing treatment) in the same manner as in the formation of the first resist pattern, thereby forming a resist film. In the subsequent steps for the formation of the second resist pattern including drying (prebake), exposure, postbake, development and rinse, the same procedure as described with respect to the method of forming the first resist pattern is applicable. Thus, a second resist pattern besides the first resist pattern can be formed.

### EXAMPLE

Now, the present invention will be described in greater detail with reference to Examples, which however in no way limit the scope of the present invention.

First, examples in which the low-molecular compound as the chemical species of the present invention was used will be shown below.

<Preparation of Freezing Treatment Agent>

Referring to Table 2 below, the freezing treatment agents (surface treating agents) were prepared by dissolving the relevant components in the solvents and passing the resultant solutions through a polyethylene filter of 0.1 μm pore size. In the Table 2, the parenthesized values indicate parts by mass.

TABLE 2

| | | | Inactive | |
|---|---|---|---|---|
| | | | poly- | |
| | | | mer/ | |
| Treat- | | | inactive | |
| ing | | | oligo- | |
| agent | Chemical species | Surfactant | mer | Solvent |
| F-01 | L-1 (5) | — | — | C1 (95) |
| F-02 | L-3 (5) | — | — | C1 (95) |
| F-03 | L-5 (5) | — | — | C1 (76)/C2 (19) |
| F-04 | L-7 (5) | — | — | C1 (76)/C2 (19) |
| F-05 | L-9 (5) | — | — | C1 (76)/C2 (19) |
| F-06 | L-11 (5) | S1 (0.01) | — | C1 (75.99)/C2 (19) |
| F-07 | L-12 (5) | S1 (0.01) | — | C1 (75.99)/C2 (19) |
| F-08 | B-3 (5) | S1 (0.01) | — | C1 (75.99)/C2 (19) |
| F-09 | B-5 (5) | S1 (0.01) | — | C1 (75.99)/C2 (19) |
| F-10 | B-8 (5) | S1 (0.01) | — | C1 (94.99) |
| F-11 | B-15 PTS salt* (5) | S1 (0.01) | — | C1 (94.99) |
| F-12 | C-3 PTS salt* (5) | S1 (0.01) | — | C1 (75.99)/C2 (19) |
| F-13 | C-5 PTS salt* (5) | S1 (0.01) | — | C1 (75.99)/C2 (19) |
| F-14 | D-4 (5) | S1 (0.01) | — | C1 (75.99)/C2 (19) |
| F-15 | F-4 (5) | S1 (0.01) | — | C1 (75.99)/C2 (19) |
| F-16 | C-5 PTS salt* (5) | S1 (0.01) | P1 | C1 (75.99)/C2 (19) |
| F-17 | C-5 PTS salt* (5) | S1 (0.01) | P2 | C1 (75.99)/C2 (19) |
| F-A | I-1 (1) | — | — | C1 (99) |

*PST salt: p-toluenesulfonic acid salt
(Chemical species)
I-1: tetraisocyanatosilane (Matsumoto Fine Chemical Co., Ltd., trade name: Orgatics SI-400)
(Surfactant)
S1: Surfron S-111N (produced by AGC Seimi Chemical Co., Ltd.)
(Solvent)
C1: water
C2: isopropanol
(Nitrogenous compound or its salt, and polymer or oligomer inactive to solvent)
P1: polyethylene glycol dimethyl ether (produced by Aldrich)
P2: polyethylene glycol (produced by Aldrich)

<Preparation of Resist Composition>

[Synthesis of Resin (1)]

In a nitrogen stream, 20 g of a 6:4 (mass ratio) mixed solvent of propylene glycol monomethyl ether acetate and propylene glycol monomethyl ether was placed in a three-necked flask and heated at 80° C. (solvent 1). Butyrolactone methacrylate, hydroxyadamantane methacrylate and 2-methyl-2-adamantyl methacrylate were added in a molar ratio of 50:10:40 to another 6:4 (mass ratio) mixed solvent of propylene glycol monomethyl ether acetate and propylene glycol monomethyl ether and dissolved therein, thereby obtaining a 22 mass % monomer solution (200 g). Further, an initiator V601 (produced by Wako Pure Chemical Industries, Ltd.) was added in an amount of 8 mol % based on the monomers. The thus obtained monomer solution was dropped into the solvent 1 over a period of 6 hours. After the completion of the dropping, reaction was continued at 80° C. for 2 hours. The reaction mixture was allowed to stand still to cool and was poured into a mixed solvent consisting of 1800 ml of hexane and 200 ml of ethyl acetate. The thus precipitated powder was collected by filtration and dried, thereby obtaining 37 g of resin (1).

As a result of GPC measurement using a polystyrene standard, it was found that the obtained resin (1) had a weight average molecular weight (Mw) of 8800 and a dispersity (Mw/Mn) of 1.8.

<Synthesis of Resins (2) to (9) and (PO-A)>

Resins (2) to (9) and (PO-A) were synthesized by the same synthetic method as employed for the resin (1).

With respect to each of the obtained resins (1) to (9) and (PO-A), the structures of the repeating units thereof are shown below, and the repeating unit ratio (corresponding to individual repeating units in order from the left), weight average molecular weight (Mw) and dispersity (Mw/Mn) thereof are given in Table 3. The Mw is determined by GPC and expressed in terms of polystyrene molecular weight.

TABLE 3
(1)

| | | |
|---|---|---|
| 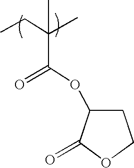 | 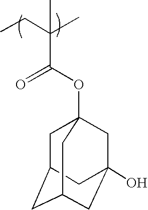 | 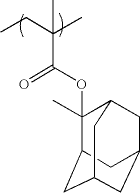 |

(2)

| | | |
|---|---|---|
| 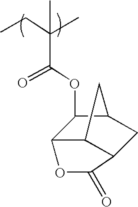 | 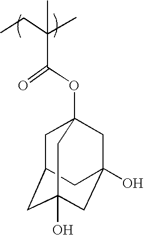 | 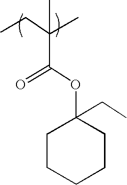 |

(3)

| | |
|---|---|
| 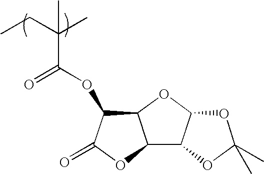 | 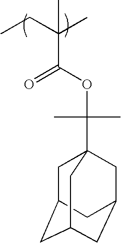 |

| | |
|---|---|
| 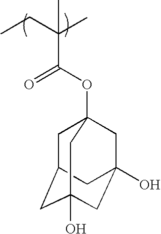 | 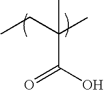 |

(4)

| | | |
|---|---|---|
| 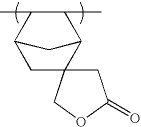 | 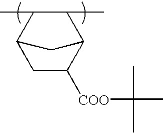 | 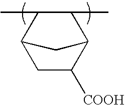 |

(5)

| | |
|---|---|
| 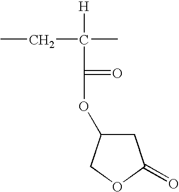 | 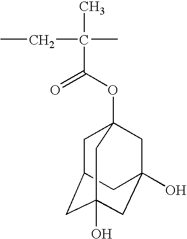 |
| 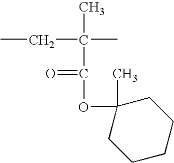 | 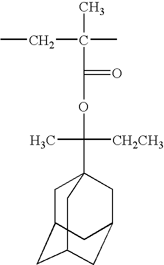 |

(6)

| | |
|---|---|
| 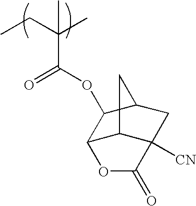 | 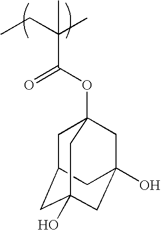 |
| 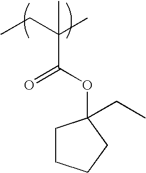 | 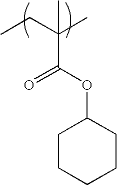 |

(7)

| | |
|---|---|
| 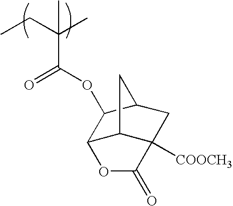 | 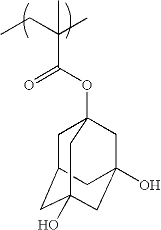 |

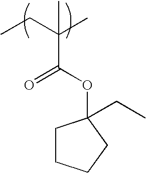

(8)

| | |
|---|---|
| 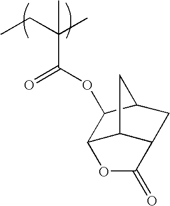 | 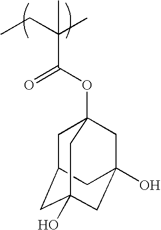 |
| 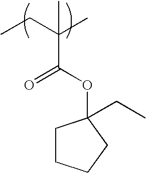 | 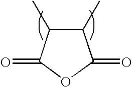 |

(9)

| | |
|---|---|
| 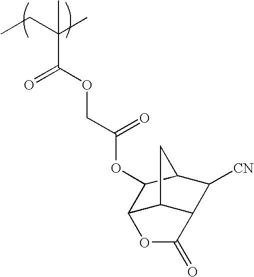 | 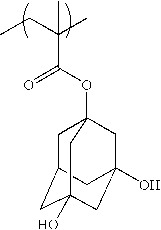 |

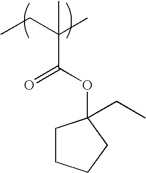

(PO-A)

| | |
|---|---|
| 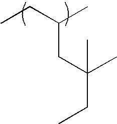 | 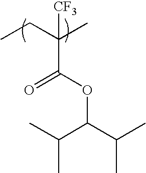 |

| | Composition ratio | | |
|---|---|---|---|
| Resin | (molar ratio) | Mw | Mw/Mn |
| (1) | 50/10/40 | 8800 | 1.8 |
| (2) | 40/22/38 | 12000 | 2.3 |
| (3) | 46/32/12/10 | 6500 | 2.1 |
| (4) | 18/69/13 | 11000 | 1.8 |
| (5) | 39/21/11/29 | 9600 | 1.7 |
| (6) | 40/10/40/10 | 10000 | 1.8 |
| (7) | 50/10/40 | 7600 | 1.7 |
| (8) | 40/10/40/10 | 12000 | 1.8 |
| (9) | 50/10/40 | 8400 | 1.7 |
| PO-A | 50/50 | 5000 | 1.4 |

<Preparation of Resist Composition>

Referring to Table 4 below, with respect to each of the resists, the individual components were dissolved in the solvent, thereby obtaining a solution of 3.2 mass % solid content. This solution was passed through a polyethylene filter of 0.1 μm pore size. Thus, the intended positive resist solutions were prepared.

TABLE 4

| | | (b)Acid | (c)Basic | | (e)Hydrophobic | |
|---|---|---|---|---|---|---|
| | (a)Resin | generator | compound | (d)Surfactant | resin | Solvent |
| Resist | (mass/g) | (mass/g) | (mass/g) | (mass/g) | (mass/g) | (mass ratio) |
| Ar-1 | Resin(1) | PO1 | TPI | W-3 | PO-A | A1/B1 |
| | (10) | (0.3) | (0.03) | (0.01) | (0.05) | (70/30) |
| Ar-2 | Resin(2) | PO1 | PEA | W-2 | PO-A | A1/A2 |
| | (10) | (0.2) | (0.03) | (0.02) | (0.05) | (40/60) |
| Ar-3 | Resin(3) | PO3 | PBI | W-1 | PO-A | A1/B2 |
| | (10) | (0.4) | (0.02) | (0.01) | (0.05) | (50/50) |
| Ar-4 | Resin(4) | PO1 | TPI | W-2 | PO-A | A1/A3 |
| | (10) | (0.2) | (0.03) | (0.02) | (0.05) | (60/40) |
| Ar-5 | Resin(5) | PO2 | DPA | W-1 | PO-A | B1/B2 |
| | (10) | (0.3) | (0.03) | (0.01) | (0.05) | (70/30) |
| Ar-6 | Resin(6) | PO2 | DPA | W-1 | PO-A | B1/B2 |
| | (10) | (0.3) | (0.03) | (0.01) | (0.05) | (70/30) |
| Ar-7 | Resin(7) | PO1 | DPA | W-1 | PO-A | A1/B1 |
| | (10) | (0.3) | (0.03) | (0.01) | (0.05) | (70/30) |
| Ar-8 | Resin(8) | PO1 | DPA | W-1 | PO-A | A1/B1 |
| | (10) | (0.3) | (0.03) | (0.01) | (0.05) | (70/30) |
| Ar-9 | Resin(9) | PO1 | DPA | W-1 | PO-A | A1/B1 |
| | (10) | (0.3) | (0.03) | (0.01) | (0.05) | (70/30) |

The particulars of the acid generators (b), basic compounds (c), surfactants (d) and solvents indicated in the Table 4 are as follows.

[(b) Acid Generator]

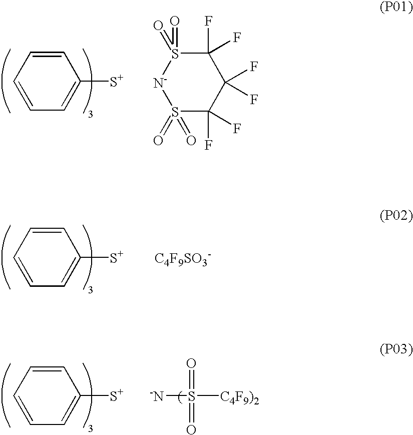

[(c) Basic Compound]

TPI: 2,4,5-triphenylimidazole,

PEA: N-phenyldiethanolamine,

DPA: 2,6-diisopropylphenyl alcohol, and

PBI: 2-phenylbenzimidazole.

[(d) Surfactant]

W-1: Megafac F176 (produced by Dainippon Ink & Chemicals, Inc.) (fluorinated),

W-2: Megafac R08 (produced by Dainippon Ink & Chemicals, Inc.) (fluorinated and siliconized), and

W-3: polysiloxane polymer KP-341 (produced by Shin-Etsu Chemical Co., Ltd.) (siliconized).

[Solvent]

A1: propylene glycol monomethyl ether acetate,

A2: γ-butyrolactone,

A3: cyclohexanone,

B1: propylene glycol monomethyl ether, and

B2: ethyl acetate.

The prepared treating agent solutions and positive resist solutions were used and evaluated in the following manner.

<Pattern Formation 1>

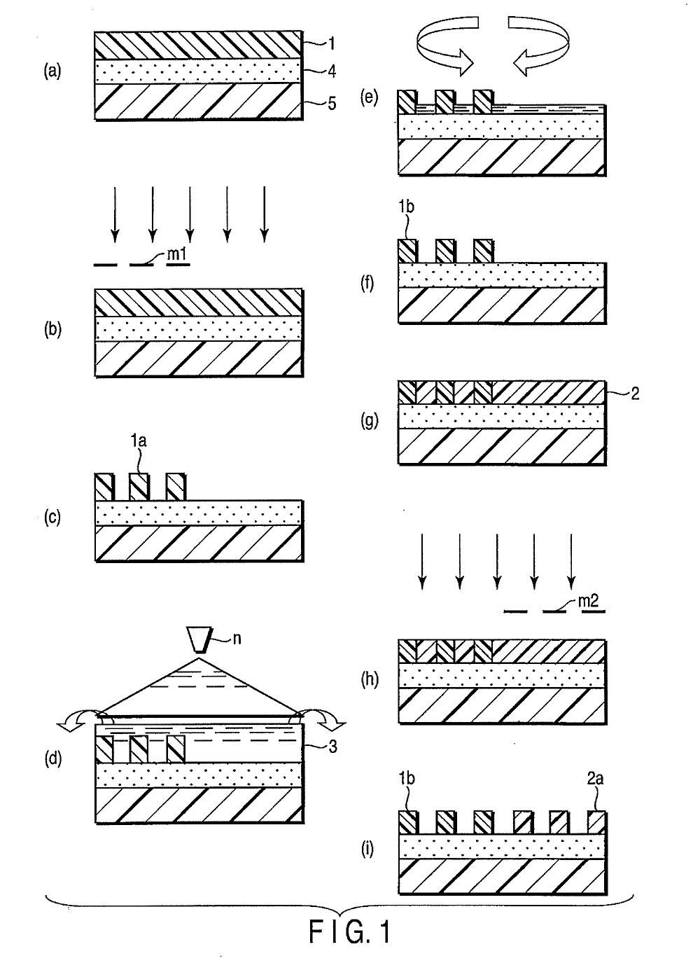

Referring to FIG. 1, a method of forming a pattern having undergone a freezing treatment (1) will be described below.

This method was applied when the treating agents (F-01 to F15 and F-A) containing no inactive polymer (oligomer) were used as the surface treating agent.

An organic antireflection film (ARC29A (produced by Nissan Chemical Industries, Ltd.)) was applied onto a silicon wafer 5 and baked at 205° C. for 60 seconds, thereby forming a 78 nm thick antireflection film 4. Each of the prepared first positive resist compositions was applied thereonto and baked at 110° C. for 60 seconds, thereby forming an 80 nm thick first resist film 1 (see FIG. 1(a)).

Subsequently, liquid immersion patterning exposure of the wafer furnished with the resist film 1 was performed through an exposure mask ml (line/space=1/1) with the use of an ArF excimer laser scanner (manufactured by ASML, TWINSCAN XT:1700Fi) (see FIG. 1(b)). Pure water was used as the liquid for liquid immersion. The intensity of exposure was optimized so as to obtain a desired line width. Thereafter, the exposed wafer was heated at 120° C. for 60 seconds, developed with an aqueous solution of tetramethylammonium hydroxide (2.38 mass %) for 30 seconds, rinsed with pure water, spin dried and heated at 90° C. for 90 seconds so as to remove any remaining water, thereby obtaining a first resist pattern 1a of 100 nm pitch and 50 nm line width (see FIG. 1(c)).

Next, while the substrate was rotated at a speed of 100 rpm, the surface treating agent (freezing agent) was spouted through a nozzle (n) toward the center of the substrate at a flow rate of 2 cc/sec for 5 seconds to thereby form a puddle. The substrate was allowed to stand still for 30 seconds to thereby bring the treating agent into contact with the resist pattern (see FIG. 1(d)). Thereafter, the substrate was rotated at a speed of 2000 rpm for 30 seconds to thereby shake off the treating agent (see FIG. 1(e)).

Further, in order to remove any excess portion of the treating agent, the same solvent as used in the treating agent (consisting of the solvent only, not containing any other components) was spouted toward the center of the substrate at a flow rate of 1 ml/sec for 10 seconds while the substrate was rotated at a speed of 300 rpm. Thereafter, the substrate was rotated at a speed of 2000 rpm for 30 sec to thereby shake off the solvent.

The resultant wafer was baked at 120° C. for 60 seconds so as to advance the reaction. Thereafter, the wafer was cooled to room temperature, and the same solvent as used in the treating agent (consisting of the solvent only, not containing any other components) was spouted toward the center of the substrate at a flow rate of 3 ml/sec for 20 seconds while the substrate was rotated at a speed of 300 rpm. Then, the substrate was rotated at a speed of 2000 rpm for 30 seconds to thereby shake off the solvent. In order to remove any portion of the solvent remaining on the substrate, the wafer was heated at 90° C. for 90 seconds, and cooled to room temperature (see FIG. 1(f)).

Furthermore, the second positive resist composition was applied onto the substrate furnished with the first resist pattern 1b that had undergone the chemical treatment, and baked at 110° C. for 60 seconds, thereby obtaining an 80 nm thick second resist film 2 (see FIG. 1(g)). The second resist composition was the same as the first resist composition.

Liquid immersion patterning exposure of the wafer furnished with the resist film 2 was performed through an exposure mask m2 (line/space=1/1) with the use of an ArF excimer laser scanner (manufactured by ASML, TWINSCAN XT:1700Fi) (see FIG. 1(h)). Pure water was used as the liquid for liquid immersion. The intensity of exposure was optimized so as to obtain a desired line width. Thereafter, the exposed wafer was heated at 120° C. for 60 seconds, developed with an aqueous solution of tetramethylammonium hydroxide (2.38 mass %) for 30 seconds, rinsed with pure water, spin dried and further heated at 90° C. for 90 seconds so as to remove any remaining water, thereby obtaining a second resist pattern 2a of 100 nm pitch and 50 nm line width (see FIG. 1(i)).

With respect to the obtained pattern, any changes of the first pattern line width and LWR were determined by the evaluation method to be described below. The results are summarized in Table 5.

<Pattern Formation 2>

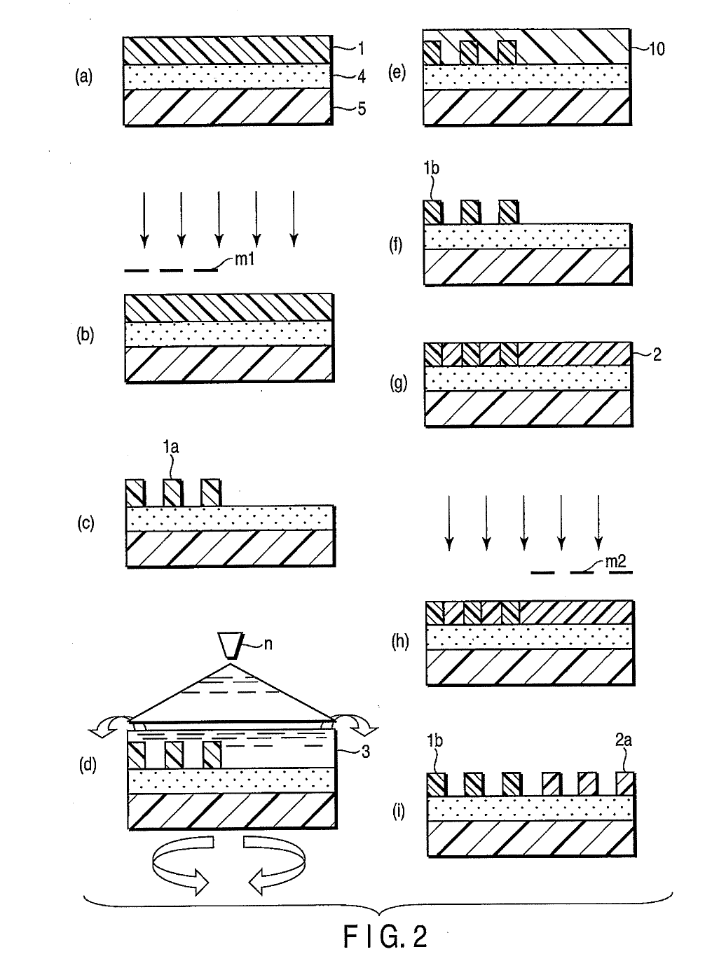

Referring to FIG. 2, another method of forming a pattern having undergone a freezing treatment (2) will be described below. This method was applied when the treating agents (F-16 and F-17) containing an inactive polymer (oligomer) were used as the surface treating agent.

A first resist pattern 1a was obtained by the method described above with respect to the <pattern formation 1>(see FIGS. 2(a) to (c)). Each of the surface treating agents (freezing agents) was applied onto the substrate (see FIG. 2(d)) and baked at 100° C. for 90 seconds so as to attain a reaction progress while forming a 150 nm thick surface treating agent film (see FIG. 2(e)).

Thereafter, in order to remove any excess portion of the treating agent, pure water was spouted through a nozzle (n) toward the center of the substrate at a flow rate of 2 cc/sec for 5 seconds to thereby form a puddle. The substrate was allowed to stand still for 30 seconds to thereby bring the pure water into contact with the surface treating agent film. Further, while rotating the substrate at a speed of 300 rpm, the same solvent as used in the treating agent (consisting of the solvent only, not containing any other components) was spouted toward the center of the substrate at a flow rate of 1 ml/sec for 10 seconds. Then, the substrate was rotated at a speed of 2000 rpm for 30 seconds to thereby shake off the solvent. In order to remove any portion of the solvent remaining on the substrate, the wafer was heated at 90° C. for 90 seconds, and cooled to room temperature (see FIG. 2(f)).

Furthermore, the second positive resist composition was applied onto the substrate furnished with the first resist pattern 1b that had undergone the chemical treatment, and baked at 110° C. for 60 seconds, thereby obtaining an 80 nm thick second resist film 2 (see FIG. 2(g)). The second resist composition was the same as the first resist composition.

Thereafter, the method described above with respect to the <pattern formation 1> was followed, thereby obtaining a second resist pattern 2a of 100 nm pitch and 50 nm line width (see FIG. 2(i)).

With respect to the obtained pattern, any changes of the first pattern line width and LWR were determined by the evaluation method given below. The results are summarized in Table 6.

<Line Width Change>

With respect to the resist pattern 1, the line width change was evaluated by the difference (y-x) between the line width (x) of the resist pattern 1 before the freezing treatment (pattern 1a in FIG. 1(c) and FIG. 2(c)) and the line width (y) of the resist pattern 1 after the formation of the second resist pattern (pattern 1b in FIG. 1(i) and FIG. 2(i)).

The line width was determined by observing the 50 nm resist pattern by use of a critical dimension scanning electron microscope (model S-9380II manufactured by Hitachi, Ltd.), conducting line width measurements at 50 equal-interval points within a 2 μm region in the longitudinal direction of the line pattern and calculating the average of the measurement values.

<LWR Change>

With respect to the resist pattern 1, the LWR change was evaluated by the difference (Ly−Lx) between the LWR (Lx) of the resist pattern 1 before the freezing treatment (pattern 1a in FIG. 1(c) and FIG. 2(c)) and the LWR (Ly) of the resist pattern 1 after the formation of the second resist pattern (pattern 1b in FIG. 1(i) and FIG. 2(i)).

The LWR was determined by observing the 50 nm resist pattern by use of a critical dimension scanning electron microscope (SEM, model S-9380II manufactured by Hitachi, Ltd.), conducting line width measurements at 50 equal-interval points within a 2 μm region in the longitudinal direction of the line pattern and calculating 3σ from the standard deviation thereof.

TABLE 5
(Pattern formation 1)

| | | | Treating | | |
|---|---|---|---|---|---|
| | No. | Resist | agent | y-x[nm] | Ly-Lx[nm] |
| Ex. | 1 | Ar-1 | F-01 | 11 | 0.3 |
| | 2 | Ar-1 | F-02 | 8 | 0.2 |
| | 3 | Ar-1 | F-03 | 9 | −0.2 |
| | 4 | Ar-1 | F-04 | 8 | 0.1 |
| | 5 | Ar-1 | F-05 | 7 | −0.3 |
| | 6 | Ar-1 | F-06 | 6 | 0.2 |
| | 7 | Ar-1 | F-07 | 5 | 0.2 |
| | 8 | Ar-1 | F-08 | 4 | 0.1 |
| | 9 | Ar-1 | F-09 | 4 | −0.1 |
| | 10 | Ar-1 | F-10 | 7 | −0.2 |
| | 11 | Ar-1 | F-11 | 6 | −0.2 |
| | 12 | Ar-1 | F-12 | 3 | 0.3 |
| | 13 | Ar-1 | F-13 | 2 | 0.1 |
| | 14 | Ar-1 | F-14 | 6 | 0.2 |
| | 15 | Ar-1 | F-15 | 7 | −0.1 |
| | 16 | Ar-2 | F-04 | 11 | 0.4 |
| | 17 | Ar-2 | F-06 | 9 | 0.4 |
| | 18 | Ar-2 | F-08 | 9 | 0.5 |
| | 19 | Ar-2 | F-07 | 7 | 0.4 |
| | 20 | Ar-2 | F-12 | 8 | 0.6 |
| | 21 | Ar-2 | F-13 | 6 | 0.5 |
| | 22 | Ar-3 | F-04 | 3 | 0.2 |
| | 23 | Ar-3 | F-06 | 2 | −0.1 |
| | 24 | Ar-3 | F-08 | 2 | −0.1 |
| | 25 | Ar-3 | F-07 | 2 | 0.1 |
| | 26 | Ar-3 | F-12 | 1 | 0.1 |
| | 27 | Ar-3 | F-13 | 1 | 0.2 |
| | 28 | Ar-4 | F-04 | 12 | 0.7 |
| | 29 | Ar-4 | F-06 | 9 | 0.6 |
| | 30 | Ar-4 | F-08 | 6 | 0.5 |
| | 31 | Ar-4 | F-07 | 5 | 0.4 |
| | 32 | Ar-4 | F-12 | 7 | 0.4 |
| | 33 | Ar-4 | F-13 | 6 | 0.5 |
| | 34 | Ar-5 | F-04 | 5 | 0.3 |
| | 35 | Ar-5 | F-06 | 11 | 0.3 |
| | 36 | Ar-5 | F-08 | 12 | 0.4 |
| | 37 | Ar-5 | F-07 | 8 | 0.2 |
| | 38 | Ar-5 | F-12 | 9 | 0.3 |
| | 39 | Ar-5 | F-13 | 8 | 0.3 |
| | 40 | Ar-6 | F-04 | 3 | 0.2 |
| | 41 | Ar-6 | F-06 | 1 | 0.1 |
| | 42 | Ar-6 | F-08 | 2 | 0.1 |
| | 43 | Ar-6 | F-12 | 1 | −0.1 |
| | 44 | Ar-6 | F-13 | 1 | 0.2 |
| | 45 | Ar-6 | F-13 | 3 | 0.1 |
| | 46 | Ar-6 | F-13 | 2 | −0.2 |
| | 47 | Ar-6 | F-14 | 3 | 0.3 |
| | 48 | Ar-6 | F-15 | 2 | 0.2 |
| | 53 | Ar-7 | F-06 | 2 | 0.3 |
| | 54 | Ar-8 | F-06 | 3 | 0.2 |
| | 55 | Ar-9 | F-06 | 2 | 0.2 |
| Comp. | 1 | Ar-1 | F-A | 31 | 4.8 |

TABLE 6
(Pattern formation 2)

| | | | Treating | | |
|---|---|---|---|---|---|
| | No. | Resist | agent | y-x[nm] | Ly-Lx[nm] |
| Ex. | 101 | Ar-1 | F-16 | 2 | 0.2 |
| | 102 | Ar-1 | F-17 | 2 | −0.1 |

Next, examples in which the polymer and/or oligomer as the chemical species of the present invention was used will be shown below.

<Preparation of Freezing Treatment Agent>

Referring to Table 7 below, the freezing treatment agents (surface treating agents) were prepared by dissolving the relevant components in the solvents and passing the resultant solutions through a polyethylene filter of 0.1 μm pore size. In the Table 7, the parenthesized values indicate parts by mass.

TABLE 7

| Treating | Chemical | | |
|---|---|---|---|
| agent | species | Surfactant | Solvent |
| F-101 | CH-01 (5) | — | C1 (95) |
| F-102 | CH-02 (5) | S1 (0.01) | C1 (94.99) |
| F-103 | CH-03 (5) | S2 (0.05) | C1 (74.95), |
| | | | C2 (20) |
| F-104 | CH-04 (5) | S2 (0.02) | C1 (84.98), |
| | | | C3 (10) |
| F-105 | CH-05 (5) | S3 (0.01) | C1 (94.99) |
| F-106 | CH-06 (5) | S1 (0.005) | C1 (94.995) |
| F-107 | CH-07 (5) | S3 (0.04) | C1 (94.96) |
| F-108 | CH-08 (5) | S3 (0.02) | C1 (94.98) |
| F-109 | CH-09 (5) | S1 (0.01) | C1 (94.99) |
| F-110 | CH-10 (5) | S2 (0.03) | C1 (94.97) |
| F-111 | CH-11 (5) | S1 (0.01) | C1 (94.99) |
| F-112 | CH-02 (5) | S1 (0.01) | C1 (44.99), |
| | | | C3 (50) |
| F-113 | CH-05 (2) | S1 (0.01) | C1 (97.99) |
| F-114 | CH-07 (8) | S1 (0.01) | C1 (40.99), |
| | | | C2 (41) |
| F-115 | I-1 (9.49), | S1 (0.01) | C1 (90) |
| | I-2 (0.5) | | |

(Chemical species)
CH-01: polyallylamine (Mw: 15,000, trade name PAA-15, produced by Nitto Boseki Co., Ltd.)
CH-02: polyallylamine (Mw: 5000, trade name PAA-05, produced by Nitto Boseki Co., Ltd.)
CH-03: polyallylamine (Mw: 3000, trade name PAA-03, produced by Nitto Boseki Co., Ltd.)
CH-04: polyallylamine (Mw: 1000, trade name PAA-01, produced by Nitto Boseki Co., Ltd.)
CH-05: polyallylamine (Mw: 500, produced by Nitto Boseki Co., Ltd.)
CH-06: (allylamine)-(N,N-dimethylallylamine) copolymer (copolymerization ratio 50:50, Mw: 1000, trade name PAA-1112, produced by Nitto Boseki Co., Ltd.)
CH-07: (allylamine)-(N-acetylallylamine) copolymer (copolymerization ratio 50:50, Mw: 15,000, trade name PAA-AC5050A, produced by Nitto Boseki Co., Ltd.)
CH-08: (allylamine)-(N-acetylallylamine) copolymer (copolymerization ratio 70:30, Mw: 1000)
CH-09: (allylamine)-(N-acetylallylamine) copolymer (copolymerization ratio 85:15, Mw: 1000)
CH-10: (allylamine)-(allylammonium p-toluenesulfonate) copolymer (copolymerization ratio 70:30, Mw: 15,000)
CH-11: (allylamine)-(allylammonium p-toluenesulfonate) copolymer (copolymerization ratio 50:50, Mw: 1000)
I-1: polyvinylpyrrolidone “PVP K30” (produced by BASF)
I-2: urea crosslinking agent “N-8314” (produced by Sanwa Chemical Co., Ltd.)

The above Mw is a weight average molecular weight in terms of polyethylene oxide as measured by GPC.

The above CH-08 and CH-09 were synthesized from polyallylamine produced by Nitto Boseki Co., Ltd. as a raw material in accordance with the method described in Examples 1 to 4 of JP-A-9-286816.

The above CH-10 and CH-11 were synthesized from polyallylamine produced by Nitto Boseki Co., Ltd. as a raw material by reacting the same with p-toluenesulfonic acid (produced by Tokyo Chemical Industry Co., Ltd.).

(Surfactant)

S1: “Surfron S-111N” (produced by AGC Seimi Chemical Co., Ltd.)

S2: “Acetylenol E100” (produced by Kawaken Fine Chemical Co., Ltd.)

S3: lauryldimethylamine oxide

(Solvent)

C1: water

C2: isopropanol

C3: ethanol

<Preparation of Resist Composition>

[Synthesis of Resin (1)]

In a nitrogen stream, 20 g of a 6:4 (mass ratio) mixed solvent of propylene glycol monomethyl ether acetate and propylene glycol monomethyl ether was placed in a three-necked flask and heated at 80° C. (solvent 1). Butyrolactone methacrylate, hydroxyadamantane methacrylate and 2-methyl-2-adamantyl methacrylate were added in a molar ratio of 50:10:40 to another 6:4 (mass ratio) mixed solvent of propylene glycol monomethyl ether acetate and propylene glycol monomethyl ether and dissolved therein, thereby obtaining a 22 mass % monomer solution (200 g). Further, an initiator V601 (produced by Wako Pure Chemical Industries, Ltd.) was added in an amount of 8 mol % based on the monomers. The thus obtained monomer solution was dropped into the solvent 1 over a period of 6 hours. After the completion of the dropping, reaction was continued at 80° C. for 2 hours. The reaction mixture was allowed to stand still to cool and was poured into a mixed solvent consisting of 1800 ml of hexane and 200 ml of ethyl acetate. The thus precipitated powder was collected by filtration and dried, thereby obtaining 37 g of resin (1).

As a result of GPC measurement using a polystyrene standard, it was found that the obtained resin (1) had a weight average molecular weight (Mw) of 6000 and a dispersity (Mw/Mn) of 1.6.

<Synthesis of Resins (2) to (7) and (PO-A)>

Resins (2) to (7) and (PO-A) were synthesized by the same synthetic method as employed for the resin (1).

With respect to each of the obtained resins (1) to (7) and (PO-A), the structures of the repeating units thereof are shown below, and the repeating unit ratio (corresponding to individual repeating units in order from the left), weight average molecular weight (Mw) and dispersity (Mw/Mn) thereof are given in Table 8.

TABLE 8
(1)

| | | |
|---|---|---|
| 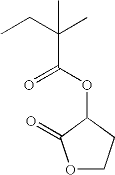 | 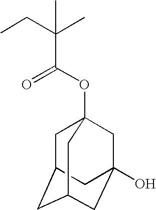 | 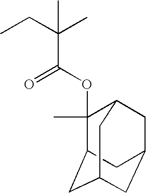 |

(2)

| | | |
|---|---|---|
| 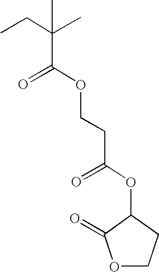 | 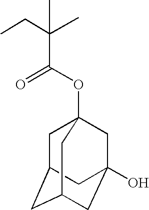 | 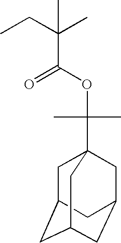 |

(3)

| | |
|---|---|
| 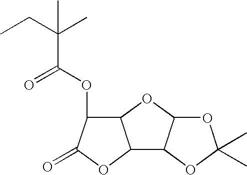 | 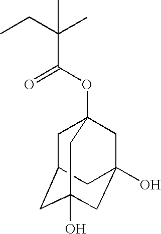 |

| | |
|---|---|
| 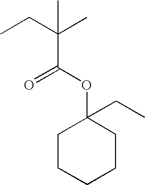 | 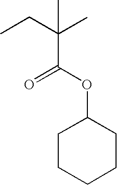 |

(4)

| | |
|---|---|
| 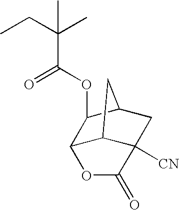 | 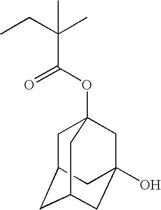 |
| 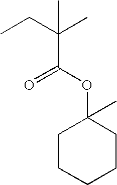 | 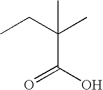 |

(5)

| | |
|---|---|
| 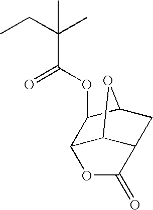 | 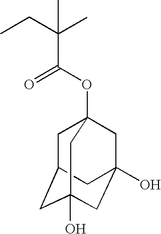 |
| 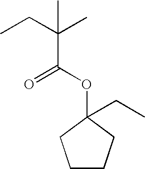 | 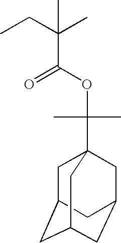 |

(6)

| | | |
|---|---|---|
| 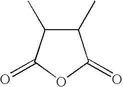 | 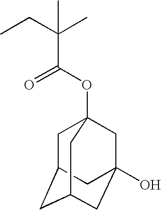 | 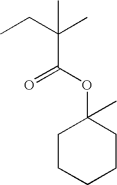 |

(7)

| | | |
|---|---|---|
| 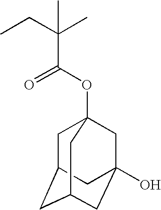 | 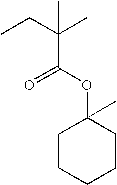 | 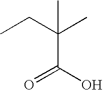 |

(PO-A)

| | |
|---|---|
| 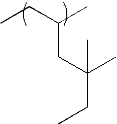 | 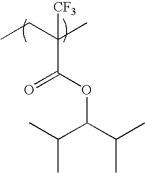 |

| | Composition ratio | | |
|---|---|---|---|
| Resin | (molar ratio) | Mw | Mw/Mn |
| (1) | 40/20/40 | 6000 | 1.6 |
| (2) | 50/20/30 | 12000 | 1.9 |
| (3) | 40/10/40/10 | 8000 | 1.7 |
| (4) | 40/15/40/5 | 11000 | 1.8 |
| (5) | 35/15/21/29 | 9600 | 1.7 |
| (6) | 30/30/40 | 9000 | 1.7 |
| (7) | 45/50/5 | 8500 | 1.6 |
| PO-A | 50/50 | 5000 | 1.4 |

<Preparation of Resist Composition>

Referring to Table 9 below, with respect to each of the resists, the individual components were dissolved in the solvent, thereby obtaining a solution of 3.2 mass % solid content. This solution was passed through a polyethylene filter of 0.1 μm pore size. Thus, the intended positive resist solutions were prepared.

TABLE 9

| | | (b) Acid | (c) Basic | | (e) Hydrophobic | |
|---|---|---|---|---|---|---|
| | (a) Resin | generator | compound | (d) Surfactant | resin | Solvent |
| Resist | (mass/g) | (mass/g) | (mass/g) | (mass/g) | (mass/g) | (mass ratio) |
| Ar-101 | Resin(1) | PO1 | TPI | W-3 | PO-A | A1/B1 |
| | (10) | (0.3) | (0.03) | (0.01) | (0.05) | (70/30) |
| Ar-102 | Resin(2) | PO1 | PEA | W-2 | PO-A | A1/A2 |
| | (10) | (0.2) | (0.03) | (0.02) | (0.05) | (40/60) |
| Ar-103 | Resin(3) | PO3 | PBI | W-1 | PO-A | A1/B2 |
| | (10) | (0.4) | (0.02) | (0.01) | (0.05) | (50/50) |
| Ar-104 | Resin(4) | PO1 | TPI | W-2 | PO-A | A1/A3 |
| | (10) | (0.2) | (0.03) | (0.02) | (0.05) | (60/40) |
| Ar-105 | Resin(5) | PO2 | DPA | W-1 | PO-A | B1/B2 |
| | (10) | (0.3) | (0.03) | (0.01) | (0.05) | (70/30) |
| Ar-106 | Resin(6) | PO1 | TPI | W-2 | PO-A | A1/A3 |
| | (10) | (0.2) | (0.03) | (0.02) | (0.05) | (60/40) |
| Ar-107 | Resin(7) | PO1 | TPI | W-2 | PO-A | A1/A3 |
| | (10) | (0.2) | (0.03) | (0.02) | (0.05) | (60/40) |

The particulars of the acid generators (b), basic compounds (c), surfactants (d) and solvents indicated in the Table 9 are as follows.

[(b) Acid Generator]

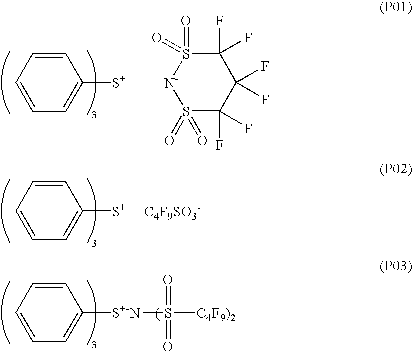

[(c) Basic Compound]

TPI: 2,4,5-triphenylimidazole,

PEA: N-phenyldiethanolamine,

DPA: 2,6-diisopropylphenyl alcohol, and

PBI: 2-phenylbenzimidazole.

[(d) Surfactant]

W-1: Megafac F176 (produced by Dainippon Ink & Chemicals, Inc.) (fluorinated),

W-2: Megafac R08 (produced by Dainippon Ink & Chemicals, Inc.) (fluorinated and siliconized), and

W-3: polysiloxane polymer KP-341 (produced by Shin-Etsu Chemical Co., Ltd.) (siliconized).

[Solvent]k

A1: propylene glycol monomethyl ether acetate,

A2: γ-butyrolactone,

A3: cyclohexanone,

B1: propylene glycol monomethyl ether, and

B2: ethyl acetate.

The prepared treating agent solutions and positive resist solutions were used and evaluated in the following manner.

<Pattern Formation>

Referring to FIG. 2, a method of forming a pattern having undergone a freezing treatment will be described below.

An organic antireflection film (ARC29A (produced by Nissan Chemical Industries, Ltd.)) was applied onto a silicon wafer 5 and baked at 205° C. for 60 seconds, thereby forming a 78 nm thick antireflection film 4. Each of the prepared first positive resist compositions was applied thereonto and baked at 110° C. for 60 seconds, thereby forming an 80 nm thick first resist film 1 (see FIG. 2(a)).

Subsequently, liquid immersion patterning exposure of the wafer furnished with the resist film 1 was performed through an exposure mask ml (line/space=1/1) with the use of an ArF excimer laser scanner (manufactured by ASML, TWINSCAN XT:1700Fi) (see FIG. 2(b)). Pure water was used as the liquid for liquid immersion. The intensity of exposure was optimized so as to obtain a desired line width. Thereafter, the exposed wafer was heated at 120° C. for 60 seconds, developed with an aqueous solution of tetramethylammonium hydroxide (2.38 mass %) for 30 seconds, rinsed with pure water, spin dried and heated at 90° C. for 90 seconds so as to remove any remaining water, thereby obtaining a first resist pattern 1a of 100 nm pitch and 50 nm line width (see FIG. 2(c)).

Subsequently, the substrate was spin coated with each surface treating agent (freezing agent) while ensuring a desired film thickness by regulation of the rotating speed (see FIG. 2(d)). The coated substrate was baked under the conditions indicated in Table 5 so that reaction was advanced while forming a surface treating agent film (10) with the thickness indicated in Table 5 (see FIG. 2(e)). Thereafter, in order to remove any excess portion of the treating agent, pure water was spouted toward the center of the substrate at a flow rate of 2 cc/sec for 5 seconds through a nozzle (n) to thereby form a puddle. The substrate was allowed to stand still for 30 seconds to thereby bring the pure water into contact with the surface treating agent film (10). Further, while rotating the substrate at a speed of 300 rpm, the same solvent as used in the treating agent (consisting of the solvent only, not containing any other components) was spouted toward the center of the substrate at a flow rate of 1 ml/sec for 10 seconds. Thereafter, the substrate was rotated at a speed of 2000 rpm for 30 seconds to thereby shake off the solvent. The resultant substrate was heated at 90° C. for 90 seconds in order to remove any portion of the solvent remaining on the substrate, and cooled to room temperature (see FIG. 2(f)).

Furthermore, the second positive resist composition was applied onto the substrate furnished with the first resist pattern 1b that had undergone the chemical treatment, and baked at 110° C. for 60 seconds, thereby obtaining an 80 nm thick second resist film 2 (see FIG. 2(g)). The second resist composition was the same as the first resist composition.

Liquid immersion patterning exposure of the wafer furnished with the resist film 2 was performed through an exposure mask m2 (line/space=1/1) with the use of an ArF excimer laser scanner (manufactured by ASML, TWINSCAN XT:1700Fi) (see FIG. 2(h)). Pure water was used as the liquid for liquid immersion. The intensity of exposure was optimized so as to obtain a desired line width. Thereafter, the exposed wafer was heated at 120° C. for 60 seconds, developed with an aqueous solution of tetramethylammonium hydroxide (2.38 mass %) for 30 seconds, rinsed with pure water, spin dried and further heated at 90° C. for 90 seconds so as to remove any remaining water, thereby obtaining a second resist pattern 2a of 100 nm pitch and 50 nm line width (see FIG. 2(i)).

With respect to the obtained pattern, any changes of the first pattern line width and LWR were determined by the evaluation method to be described below. The results are summarized in Table 10.

<Line Width Change>

With respect to the resist pattern 1, the line width change was evaluated by the difference (y−x) between the line width (x) of the resist pattern 1 before the freezing treatment (pattern 1a in FIG. 2(c)) and the line width (y) of the resist pattern 1 after the formation of the second resist pattern (pattern 1b in FIG. 2(i)).

The line width was determined by observing the 50 nm resist pattern by use of a critical dimension scanning electron microscope (model S-9380II manufactured by Hitachi, Ltd.), conducting line width measurements at 50 equal-interval points within a 2 μm region in the longitudinal direction of the line pattern and calculating the average of the measurement values.

<LWR Change>

With respect to the resist pattern 1, the LWR change was evaluated by the difference (Ly−Lx) between the LWR (Lx) of the resist pattern 1 before the freezing treatment (pattern 1a in FIG. 2(c)) and the LWR (Ly) of the resist pattern 1 after the formation of the second resist pattern (pattern 1b in FIG. 2(i)).

The LWR was determined by observing the 50 nm resist pattern by use of a critical dimension scanning electron microscope (SEM, model S-9380II manufactured by Hitachi, Ltd.), conducting line width measurements at 50 equal-interval points within a 2 μm region in the longitudinal direction of the line pattern and calculating 3σ from the standard deviation thereof.

TABLE 10

| | | | | Thickness of | | | |
|---|---|---|---|---|---|---|---|
| | | | Treating | treating agent | Baking condition of | y − x | Ly − Lx |
| | | Resist | agent | film | treating agent | [nm] | [nm] |
| Ex. | 56 | Ar-101 | F-101 | 150 nm | 100° C./60 sec | 12.2 | 0.2 |
| | 57 | Ar-102 | F-102 | 150 nm | 100° C./60 sec | 10.6 | −0.1 |
| | 58 | Ar-103 | F-103 | 150 nm | 100° C./60 sec | 8.3 | 0.1 |
| | 59 | Ar-104 | F-104 | 150 nm | 100° C./60 sec | 5.5 | 0.0 |
| | 60 | Ar-105 | F-105 | 150 nm | 100° C./60 sec | 5.6 | 0.3 |
| | 61 | Ar-102 | F-106 | 150 nm | 100° C./60 sec | 3.1 | 0.1 |
| | 62 | Ar-105 | F-107 | 150 nm | 100° C./60 sec | 8.4 | −0.2 |
| | 63 | Ar-104 | F-108 | 150 nm | 100° C./60 sec | 2.1 | 0.3 |
| | 64 | Ar-101 | F-109 | 150 nm | 100° C./60 sec | 1.6 | 0.4 |
| | 65 | Ar-102 | F-110 | 150 nm | 100° C./60 sec | 8.4 | 0.3 |
| | 66 | Ar-101 | F-111 | 150 nm | 100° C./60 sec | 4.3 | 0.0 |
| | 67 | Ar-103 | F-112 | 150 nm | 100° C./60 sec | 8.9 | 0.3 |
| | 68 | Ar-104 | F-113 | 80 nm | 100° C./60 sec | 2.2 | −0.3 |
| | 69 | Ar-105 | F-114 | 250 nm | 100° C./60 sec | 3.1 | 0.1 |
| | 70 | Ar-103 | F-104 | 150 nm | 60° C./60 sec | 2.0 | −0.1 |
| | 71 | Ar-104 | F-108 | 150 nm | 80° C./60 sec | 3.3 | −0.1 |
| | 72 | Ar-101 | F-112 | 150 nm | 110° C./60 sec | 6.0 | 0.3 |
| | 73 | Ar-104 | F-109 | 150 nm | 70° C./60 sec | 1.8 | 0.2 |
| | 74 | Ar-103 | F-114 | 150 nm | 120° C./60 sec | 7.4 | 0.4 |
| | 75 | Ar-102 | F-107 | 150 nm | 80° C./60 sec | 8.3 | −0.5 |
| | 76 | Ar-105 | F-104 | 150 nm | 90° C./60 sec | 3.2 | 0.3 |
| | 77 | Ar-103 | F-105 | 150 nm | 110° C./60 sec | 1.1 | 0.1 |
| | 78 | Ar-105 | F-111 | 150 nm | 130° C./60 sec | 3.0 | 0.3 |
| | 79 | Ar-101 | F-102 | 150 nm | 70° C./60 sec | 11.0 | 0.2 |
| | 80 | Ar-106 | F-104 | 150 nm | 100° C./60 sec | 2.6 | 2.3 |
| | 81 | Ar-107 | F-104 | 150 nm | 100° C./60 sec | 25.8 | 7.5 |
| Comp. | 2 | Ar-105 | F-115 | 250 nm | 100° C./60 sec | 35.8 | 9.8 |

From the foregoing results, it is apparent that in the double patterning technique, the present invention provides a freezing process in which any changes of the line width and LWR of the first resist pattern by the freezing treatment and by the formation of the second resist pattern can be suppressed.

What is claimed is:

1. A surface treating agent for resist pattern formation comprising a compound having two or more nucleophilic functional groups in each of the molecules thereof, or its salt, and a solvent.

2. The surface treating agent for resist pattern formation according to claim 1, wherein the nucleophilic functional groups are connected to an optionally substituted alkylene group, an optionally substituted cycloalkylene group or an optionally substituted aromatic group.

3. The surface treating agent for resist pattern formation according to claim 2, wherein the compound having two or more nucleophilic functional groups is any of the compounds of general formula (I) below: 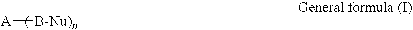
wherein A represents a single bond or an n-valent connecting group; B represents a single bond, an alkylene group, a cycloalkylene group or an aromatic group, the alkylene group, cycloalkylene group or aromatic group optionally having a substituent; Nu represents a nucleophilic functional group; n is an integer of 2 to 8; and two or more B's and Nu's may be identical to or different from each other, provided that in no event A and B simultaneously represent single bonds.

4. The surface treating agent for resist pattern formation according to claim 2, wherein at least one of the nucleophilic functional groups is any one selected from among a primary amino group, a secondary amino group, a hydroxyl group, a thiol group and —(C═O)CH₂(C═O)—.

5. The surface treating agent for resist pattern formation according to claim 2, wherein the solvent is water, an alcoholic solvent or a mixture containing water and an alcoholic solvent.

6. The surface treating agent for resist pattern formation according to claim 2, wherein a surfactant is further contained.

7. The surface treating agent for resist pattern formation according to claim 1, wherein the compound having two or more nucleophilic functional groups is a polymer and/or oligomer.

8. The surface treating agent for resist pattern formation according to claim 7, wherein the polymer and/or oligomer having nucleophilic functional groups has a weight average molecular weight of 500 or greater.

9. The surface treating agent for resist pattern formation according to claim 8, wherein the weight average molecular weight is in the range of 500 to 5000.

10. The surface treating agent for resist pattern formation according to claim 7, wherein at least one of the nucleophilic functional groups is any one selected from among a primary or secondary amino group, a hydroxyl group or its conjugate base, a thiol or its conjugate base, a conjugate base of carboxyl group and a conjugate base of —(C═O)CH₂(C═O)—.

11. The surface treating agent for resist pattern formation according to claim 10, wherein the polymer and/or oligomer further has at least one of the groups of formulae (3), (4) and (5) below: 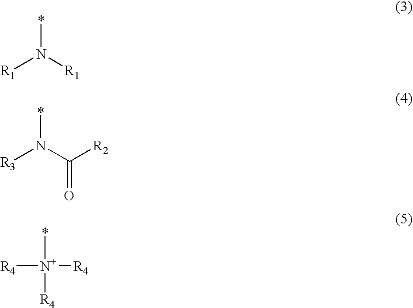
in the formulae (3), (4) and (5),
each of R₁s independently represents an optionally substituted alkyl group or an optionally substituted cycloalkyl group, provided that the two R₁s may be bonded to each other to thereby form a ring,
R₂ represents an alkyl group, a cycloalkyl group, an aromatic group, an alkoxy group or an alkenyl group, in which a substituent may be introduced,
R₃ represents a hydrogen atom, an optionally substituted alkyl group, an optionally substituted cycloalkyl group or an optionally substituted alkenyl group, provided that R₂ and R₃ may be bonded to each other to thereby form a ring,
each of R₄s independently represents a hydrogen atom, an optionally substituted alkyl group or an optionally substituted cycloalkyl group, provided that two or more R₄s may be bonded to each other to thereby form a ring, and
* represents a site of linkage with a polymer and/or oligomer residue.

12. The surface treating agent for resist pattern formation according to claim 7, wherein the solvent is water, an alcoholic solvent or a mixture of water and alcoholic solvent.

13. The surface treating agent for resist pattern formation according to claim 7, wherein a surfactant is further contained.

14. The surface treating agent for resist pattern formation according to claim 1, wherein a polymer or oligomer being inactive to both of the compound having nucleophilic functional groups or its salt and the solvent is further contained.

15. The surface treating agent for resist pattern formation according to claim 1, which, when the resist pattern consists of a first resist pattern obtained by exposing a first resist film and developing the exposed film, and a second resist pattern obtained by exposing a second resist film provided on the first resist pattern and developing the exposed film, is a surface treating agent for the first resist pattern formation.

16. The surface treating agent for resist pattern formation according to claim 1, which is substantially free from changing a line width of resist pattern.

17. A resist composition for use in the formation of a pattern whose surface is treated with the surface treating agent for resist pattern formation according to claim 1, which resist composition comprises a resin with a cyclic unit so that at the surface treatment, the cyclic unit and the nucleophilic functional groups contained in the surface treating agent are bonded to each other through a chemical reaction.

18. The resist composition according to claim 17, wherein the cyclic unit is a lactone unit or a cyclic acid anhydride unit.

19. The resist composition according to claim 18, wherein the lactone unit is a lactone unit having an electron withdrawing group or a sugar lactone unit.

20. A method of treating the surface of a resist pattern, comprising the steps of applying a surface treating agent, which comprises a compound having two or more nucleophilic functional groups in each of the molecules thereof, or its salt and a solvent, onto a resist pattern formed by use of the resist composition according to claim 17 to thereby form a surface treating agent film and cause the resin contained in the resist pattern to react with the surface treating agent and removing any unreacted portion of the surface treating agent.

21. The surface treating method according to claim 20, wherein the step of causing the resin contained in the resist pattern to react with the surface treating agent includes an operation of baking the resist pattern after the formation of the surface treating agent film.

22. The surface treating method according to claim 20, wherein the resist pattern suffers substantially no change of its line width.

23. A method of treating the surface of a resist pattern, comprising the steps of immersing a resist pattern formed by use of the resist composition according to claim 17 in a surface treating agent, which comprises a compound having two or more nucleophilic functional groups in each of the molecules thereof, or its salt and a solvent, to thereby cause the resin contained in the resist pattern to react with the surface treating agent and removing any unreacted portion of the surface treating agent.

24. The surface treating method according to claim 23, wherein the step of causing the resin contained in the resist pattern to react with the surface treating agent includes an operation of baking the resist pattern after the immersion of the resist pattern in the surface treating agent.

25. The surface treating method according to claim 23, wherein the resist pattern suffers substantially no change of its line width.

26. A method of forming a pattern, comprising the steps of applying the resist composition according to claim 17 onto a substrate to thereby form a first resist film, exposing the first resist film and developing the exposed film so that a first resist pattern is obtained; treating the surface of the thus obtained first resist pattern in accordance with the surface treating method according to claim 20; and applying a second resist composition onto the first resist pattern after the surface treatment to thereby form a second resist film, exposing the second resist film and developing the exposed film so that a second resist pattern is obtained.
